(19) United States
(12) Patent Application Publication
(10) Pub. No.: US 2025/0218499 A1
(43) Pub. Date: Jul. 3, 2025

(54) Integrated Circuit Chip Including Arrays Of Multi-Threaded Dynamic Random Access Memory Unit Cells

(71) Applicant: Atomera Incorporated, Los Gatos, CA (US)

(72) Inventor: Richard S. Roy, Lago Vista, TX (US)

(73) Assignee: Atomera Incorporated, Los Gatos, CA (US)

(21) Appl. No.: 19/002,251

(22) Filed: Dec. 26, 2024

Related U.S. Application Data
(63) Continuation-in-part of application No. 18/399,579, filed on Dec. 28, 2023.
(60) Provisional application No. 63/685,629, filed on Aug. 21, 2024.
(60) Provisional application No. 63/696,485, filed on Sep. 19, 2024.
(60) Provisional application No. 63/706,219, filed on Oct. 11, 2024.

(51) Int. Cl. G11C 11/4091; G11C 5/06; G11C 11/408; G11C 11/4097; H01L 25/07; H10B 80/00

(52) U.S. Cl. CPC G11C 11/4091; G11C 5/063; G11C 11/4085; G11C 11/4097; H01L 25/074; H10B 80/00; H01L 2225/06541

(57) ABSTRACT

An integrated circuit chip comprising an array of unit cells, each including a plurality of memory strips, each including a plurality of independently accessible DRAM sub-arrays arranged in a row and a corresponding pair of primary single-ended sense amplifier circuits coupled to each of the DRAM sub-arrays. The DRAM sub-arrays of the plurality of memory strips are further arranged in a plurality of columns. Each unit cell further includes a plurality of global bit line sets, each coupled to the primary single-ended sense amplifier circuits of a corresponding column of DRAM sub-arrays, a multiplexer circuit coupled to each of the global bit line sets, wherein the multiplexer circuit selectively couples one of the global bit line sets to a set of global input/output lines, a secondary sense amplifier circuit coupled to the set of global input/output lines, and plural through silicon vias coupled to the secondary sense amplifier circuit.

### PRIORITY APPLICATIONS

This application is a continuation-in-part of U.S. patent application Ser. No. 18/399,579 entitled “Dynamic Random Access Memory System Including Single-Ended Sense Amplifiers And Methods For Operating Same”, filed Dec. 28, 2023, by Richard S. Roy, and claims priority to U.S. Provisional Patent Application 63/685,629 entitled “Multi-Threaded Dynamic Random Access Memory Systems And Methods Of Operating Same”, also filed by Richard S. Roy on Aug. 21, 2024, and claims priority to U.S. Provisional Patent Application 63/696,485 entitled “Interconnect Structure For An Array Of Multi-Threaded Dynamic Random Access Memory Systems”, also filed by Richard S. Roy on Sep. 19, 2024, and claims priority to U.S. Provisional Patent Application 63/708,219 entitled “Single-Ended Sense Amplifier Structures And Methods For Operating Same”, also filed by Richard S. Roy on Oct. 16, 2024.

### FIELD OF THE INVENTION

The present invention relates to dynamic random access memory (DRAM) systems. More specifically, the present invention relates to a DRAM system that includes an integrated circuit chip having an array of independently accessible DRAM unit cells.

### BACKGROUND

DRAM has been used in many system configurations to provide data storage for applications such as machine learning. As these applications become more complicated, it becomes more difficult to provide DRAM systems capable of handling all of the access requirements of these applications (e.g., random access bandwidth, latency, power, random access ability, memory capacity and density, refresh). JEDEC standard No. 238A describes specifications for a high bandwidth memory (HBM3) DRAM, which is coupled to a host computer die with a distributed interface. The HBM3 DRAM uses a wide-interface architecture in an attempt to achieve high-speed, low power operation. However, there is a need to have an improved DRAM system that exhibits an increased random access bandwidth, reduced access latency, reduced operating/standby power, improved random access capability, increased memory capacity capabilities, higher memory density, and an improved refresh scheme. Current HBM architectures focus on extending the current paradigm by increasing the data bandwidth for large data block accesses (with a significant power penalty for the analog circuits required to achieve data rates approaching 10 Gb/sec/pin) with very low ability to apply random (or nearly random) addresses at a high rate. It would therefore be desirable to have an improved DRAM system capable of overcoming the above-described deficiencies of conventional DRAM systems.

### SUMMARY

Accordingly, the present invention focuses on increasing the number of Sustained Independent Transactions per second (SIT/s), which requires a much higher rate of nearly independent addresses to be applied to a stack of DRAM chips coupled by through silicon via (TSV) structures, while improving the power per transaction significantly. Additional features include significant improvements in power per transaction, latency, and data bandwidth, with little or no penalty in terms of area overhead.

In accordance with one embodiment, the present invention includes an integrated circuit chip for use in a multi-threaded dynamic random access memory (MTDRAM) system, wherein the integrated circuit chip includes a plurality of independent DRAM unit cells arranged in an array. Each of the unit cells comprises a plurality of DRAM memory strips, wherein each DRAM memory strip includes a plurality of independently accessible DRAM sub-arrays arranged in a row, and a plurality of primary single-ended sense amplifier circuits, wherein each of the DRAM sub-arrays is coupled to a corresponding pair of the primary single-ended sense amplifier circuits. In one embodiment, primary single-ended sense amplifier circuits are shared by adjacent DRAM memory strips. Each of the DRAM sub-arrays includes an array of DRAM bit cells arranged in rows and columns. In addition, the DRAM sub-arrays of the plurality of DRAM memory strips are arranged in a first plurality of columns of DRAM sub-arrays.

Each of the unit cells further includes a first plurality of global bit line sets, wherein each of the first plurality of global bit line sets is coupled to a corresponding one of the first plurality of DRAM sub-array columns through the primary single-ended sense amplifier circuits coupled to the DRAM sub-arrays in the corresponding one of the first plurality DRAM sub-array columns.

Each of the unit cells further includes a first multiplexer circuit coupled to each of the first plurality of global bit line sets, wherein the first multiplexer circuit selectively couples one of the first plurality of global bit line sets to a first set of global input/output lines. In a particular embodiment, the global bit lines of each of the first plurality of global bit line sets are evenly distributed across the first multiplexer circuit.

Each of the unit cells further includes a first secondary sense amplifier circuit coupled to the first set of global input/output lines, and a first set of through silicon vias coupled to the first secondary sense amplifier circuit.

This configuration advantageously enables the efficient layout of a large number of independent DRAM unit cells (e.g., 2048 or more) on the integrated circuit chip, thereby providing a large data access bandwidth to the integrated circuit chip. The use of single-ended sense amplifier circuits within the unit cells advantageously reduces power consumption associated with accesses to the integrated circuit chip. The use of through silicon vias enables stacked configuration of the integrated circuit chip with similar integrated circuit chips, further increasing DRAM memory capacity.

In accordance with another embodiment, the DRAM sub-arrays of the plurality of DRAM memory strips are further arranged in a second plurality of columns of DRAM sub-arrays, wherein each of the unit cells further comprises a second plurality of global bit line sets, wherein each of the second plurality of global bit line sets is coupled to a corresponding one of the second plurality of DRAM sub-array columns through the primary single-ended sense amplifier circuits coupled to the DRAM sub-arrays in the corresponding one of the second plurality of DRAM sub-array columns.

Each of the unit cells further comprises a second multiplexer circuit coupled to each of the second plurality of global bit line sets, wherein the second multiplexer circuit selectively couples one of the second plurality of global bit line sets to a second set of global input/output lines, a second secondary sense amplifier circuit coupled to the second set of global input/output lines, and a second set of through silicon vias coupled to the second secondary sense amplifier circuit. This configuration advantageously provides two sets of through silicon vias for transferring data to/from each unit cell, further increasing the data access bandwidth of each unit cell. In another embodiment, each of the unit cells further comprises a third set of through silicon vias for receiving access instructions to the unit cell.

In another embodiment, a first column of unit cells and an adjacent second column of unit cells are oriented such that the through silicon vias of the first and second columns of unit cells are located immediately adjacent to one another, advantageously consolidating the locations of the through silicon vias on the integrated circuit chip.

In another embodiment, the first secondary sense amplifier circuit comprises a plurality of write single-ended sense amplifiers, each coupled to a corresponding one of the global input/output lines of the first set of global input/output lines, and a plurality of read single-ended sense amplifiers, each coupled to a corresponding one of the global input/output lines of the first set of global input/output lines. In addition, each of the through silicon vias in the first set of through silicon vias is coupled to a corresponding pair of the plurality of write single-ended sense amplifiers and a corresponding pair of the plurality of read single-ended sense amplifiers. Each of the plurality of read single-ended sense amplifiers is controlled to simultaneously sample data on a corresponding one of the global input/output lines of the first set of global input/output lines, wherein one half of the plurality of read single-ended sense amplifiers are controlled to simultaneously provide the data sampled on the corresponding one of the global input/output lines of the first set of global input/output lines to the first set of through silicon vias during a first time period, and the other half of the plurality of read single-ended sense amplifiers are controlled to simultaneously provide the data sampled on the corresponding one of the global input/output lines of the first set of global input/output lines to the first set of through silicon vias during a second time period.

In addition, one half of the plurality of write single-ended sense amplifiers are controlled to sample a first set of data on the first set of through silicon vias during a first time period and hold the first set of data during a second time period, and a second half of the plurality of write single-ended sense amplifiers are controlled to sample a second set of data on the first set of through silicon vias during the second time period. The plurality of write single-ended sense amplifiers are further controlled to simultaneously provide the first and second sets of data on the first set of global input/output lines during a third time period.

In this embodiment, the data transfer frequency on the first set of through silicon vias is advantageously twice the data transfer frequency on the first set of global input/output lines.

In another embodiment, each of the DRAM memory strips includes a plurality of main word lines, each extending through all of the plurality of DRAM sub-arrays of the DRAM memory strip. Each of the DRAM memory strips further includes a main word line driver that activates one of the corresponding plurality of main word lines when the DRAM memory strip is accessed. Each of the DRAM sub-arrays includes a dedicated plurality of sub-word lines, each coupled to a corresponding one of the rows of DRAM cells of the array of DRAM cells. Each of the plurality of DRAM sub-arrays includes a plurality of sub-word line driver circuits (SWD_{0,0}-SWD_{7,0}), each coupled to a corresponding one of the dedicated plurality of sub-word lines. Each of the main word lines is coupled to a corresponding plurality of the sub-word line driver circuits within each DRAM sub-array. For example, each main word line may be coupled to eight sub-word line driver circuits in one embodiment. In one embodiment, each of the DRAM sub-arrays receives a corresponding sub-array enable signal, wherein each of the sub-word line driver circuits in a DRAM sub-array is coupled to receive the corresponding sub-array enable signal. Advantageously, only the DRAM sub-arrays being accessed are enabled, resulting in significant power savings.

In another embodiment, each of the primary single-ended sense amplifier circuits is only coupled to half of the plurality of columns of DRAM bit cells in a corresponding DRAM sub-array. This advantageously enables the area efficient layout of four DRAM bit cells within the width of a single primary single-ended sense amplifier.

In another embodiment, an access instruction to the unit cell comprises a unit cell address for selecting the unit cell, a strip address for selecting one of the plurality of DRAM memory strips, a first DRAM sub-array column address for selecting one of the first plurality of columns of DRAM sub-arrays, and a second DRAM sub-array column address for selecting one of the second plurality of columns of DRAM sub-arrays. In another embodiment, the access instruction to the unit cell further comprises a main word line address for selecting one of the main word lines of the selected DRAM memory strip. In another embodiment, the access instruction to the unit cell further comprises a first sub-word line address for selecting one of the plurality of sub-word lines of a selected DRAM sub-array in the first plurality of columns of DRAM sub-arrays, and a second sub-word line address for selecting one of the plurality of sub-word lines of a selected DRAM sub-array in the second plurality of columns of DRAM sub-arrays. This embodiment advantageously provides the flexibility to select different sub-word lines in two different DRAM sub-arrays within a selected DRAM memory strip of the unit cell during a single access.

In another embodiment, each row of DRAM memory strips extends from a first edge of the unit cell to an opposing second edge of unit cell, wherein the through silicon vias of the unit cell are sparsely populated near the first and second edges of the unit cell, enabling a plurality of metal lines to pass between the through silicon vias of the first, second and third sets of through silicon vias near the first and second edges of the unit cell.

In another embodiment, each of the DRAM memory strips further comprises a sub-array decoder circuit that selectively enables up to one of the DRAM sub-arrays of the DRAM memory strip included in the first plurality of DRAM sub-array columns, and up to one of the DRAM sub-arrays of the DRAM memory strip included in the second plurality of DRAM sub-array columns.

Another embodiment of the present invention includes a multi-threaded dynamic random access memory (MTDRAM) processor system that includes: a first integrated circuit chip comprising at least 2048 processor blocks arranged in a first array, and a second integrated circuit chip comprising at least 2048 independent DRAM unit cells arranged in a second array, wherein each of the at least 2048 processor blocks is coupled to a corresponding one of the at least 2048 independent DRAM unit cells of the second array of DRAM unit cells by through silicon via (TSV) structures.

The present invention will be more fully understood in view of the following description and drawings.

### BRIEF DESCRIPTION OF THE DRAWINGS

FIG. 1 is a diagram illustrating a multi-threaded dynamic random access memory (MTDRAM) system, in accordance with one embodiment of the present invention.

FIG. 2 is a top view of an MTDRAM chip of FIG. 1, illustrating the layout of 2048 included MTDRAM unit cells in accordance with one embodiment of the present invention.

FIG. 3 is a top view illustrating two horizontally adjacent MTDRAM unit cells on the MTDRAM chip of FIG. 2, including the through-silicon vias (TSVs) associated with these unit cells, in accordance with one embodiment of the present invention.

FIG. 4 is a side view of two adjacent MTDRAM unit stacks, which include the MTDRAM unit cells of FIG. 3, in accordance with one embodiment of the present invention.

FIG. 5 is a top view of the 2048 unit stacks included in the MTDRAM system of FIG. 1 in accordance with one embodiment of the present embodiment.

FIG. 6 is a block diagram of an MTDRAM unit cell in accordance with one embodiment of the present invention.

FIG. 7 is a block diagram illustrating the first eight rows of an MTDRAM sub-array included in the uppermost MTDRAM strip of FIG. 6, along with a corresponding main word line driver, corresponding sub-word line drivers and a corresponding pair of primary sense amplifier sub-circuits, in accordance with one embodiment of the present invention.

FIG. 8 is a diagram illustrating the manner in which a primary sense amplifier driver circuit controls accesses to single-ended sense amplifiers within a primary sense amplifier sub-circuit in accordance with one embodiment of the present invention.

FIG. 9 is a block diagram illustrating connections between bit lines, single-ended sense amplifiers and a corresponding global bit line within the MTDRAM unit cell of FIG. 6 in accordance with one embodiment of the present invention.

FIG. 10 is a diagram illustrating the MTDRAM sub-array of FIG. 7, along with Y-decoder logic used to selectively route data from the primary sense amplifier sub-circuits to a set of global bit lines in accordance with one embodiment of the present invention.

FIG. 11A is a waveform diagram illustrating signals involved in a read access to the MTDRAM sub-array of FIG. 7 in accordance with one embodiment of the present invention.

FIG. 11B is a waveform diagram illustrating signals involved in a write access to the MTDRAM sub-array of FIG. 7 in accordance with one embodiment of the present invention.

FIG. 12 is a diagram illustrating the data channels of the MTDRAM unit cell of FIG. 6 in accordance with one embodiment of the present invention.

FIG. 13 is a diagram illustrating the manner in which data on global bit lines associated with a first data channel of an MTDRAM unit cell are routed to a multiplexer section in accordance with one embodiment of the present invention.

FIG. 14 is a diagram illustrating the manner in which the global bit lines of FIG. 10 are distributed to the multiplexer section and the manner in which the multiplexer section routes data on the global bit lines to global input/output (I/O) lines in accordance with one embodiment of the present invention.

FIG. 15 is a diagram of a secondary sense amplifier that transfers read values from the global I/O lines of FIG. 14 onto the TSVs of a first data channel of the MTDRAM unit cell, and transfers write data values from the first data channel of the MTDRAM unit cell to the global I/O lines of FIG. 14, in accordance with one embodiment of the present invention.

FIG. 16 is a circuit diagram of an even read secondary sense amplifier circuit of the secondary sense amplifier of FIG. 15, which is used to receive and transmit read data values received on an even global I/O line in accordance with one embodiment of the present invention.

FIG. 17 is a circuit diagram of an odd read secondary sense amplifier circuit of the secondary sense amplifier of FIG. 15, which is used to receive and transmit read data values received on an odd global I/O line in accordance with one embodiment of the present invention.

FIG. 18 is a waveform diagram illustrating the operation of the even read secondary sense amplifier circuit of FIG. 15 and the odd read secondary sense amplifier circuit of FIG. 16, in accordance with one embodiment of the present invention.

FIG. 19 is a circuit diagram of an even write secondary sense amplifier circuit of the secondary sense amplifier of FIG. 15, which is used to receive and transmit write data values received on an even data line of the first data channel in accordance with one embodiment of the present invention.

FIG. 20 is a circuit diagram of an odd write secondary sense amplifier circuit of the secondary sense amplifier of FIG. 15, which is used to receive and transmit write data values received on an odd data line of the first data channel in accordance with one embodiment of the present invention.

FIG. 21 is a waveform diagram illustrating the operation of the even write secondary sense amplifier circuit of FIG. 19 and the odd write secondary sense amplifier circuit of FIG. 20, in accordance with one embodiment of the present invention.

FIG. 22 is a block diagram illustrating the format of an instruction used to access an MTDRAM unit stack in accordance with one embodiment of the present invention.

FIG. 23 is a diagram illustrating a main word line decoder circuit associated with an MTDRAM strip of an MTDRAM unit cell in accordance with one embodiment of the present invention.

FIG. 24 is a diagram illustrating a sub-array decoder circuit associated with an MTDRAM strip of an MTDRAM unit cell in accordance with one embodiment of the present invention.

FIG. 25 is a diagram illustrating the layout of the TSVs required to service an MTDRAM unit stack having four MTDRAM unit cells in accordance with one embodiment of the present invention.

FIG. 26 is a block diagram of an arrayed processor system, which includes an 8×8 array of MTDRAM processor systems in accordance with one embodiment of the present invention.

FIG. 27 is a top view of the layout of 2048 processor blocks included on an ASIC controller chip of one of the MTDRAM processor systems of FIG. 26 in accordance with one embodiment of the present invention.

FIG. 28 is a block diagram generally illustrating horizontal communication paths of a first row of processor blocks on the ASIC controller chip of FIG. 27 in accordance with one embodiment of the present invention.

FIG. 29 is a block diagram that generally illustrates horizontal transport controllers included in a stacked flash memory system and three horizontally adjacent MTDRAM processor systems of the arrayed processor system of FIG. 26 in accordance with one embodiment of the present invention.

FIG. 30 is a block diagram illustrating the general routing of the horizontal communication paths associated with the horizontal transport controllers of FIG. 29 within a silicon substrate interconnect structure in accordance with one embodiment of the present invention.

FIG. 31 is a block diagram of a processor block included on the ASIC controller chip of FIG. 27 in accordance with one embodiment of the present invention.

FIG. 32 is a block diagram of the first seventeen vertically adjacent processor blocks included in the first column of processor blocks in the ASIC controller chip of FIG. 27 in accordance with one embodiment of the present invention.

FIG. 33 is a block diagram illustrating the vertical routing of data between a communication management chip, a first column of processor blocks in a first MTDRAM processor system and a first column of processor blocks in a second, vertically adjacent, MTDRAM processor system of the arrayed processor system of FIG. 26, in accordance with one embodiment of the present invention.

FIG. 34 is a block diagram of an expanded arrayed processor system in accordance with one embodiment of the present invention.

FIG. 35 is a circuit diagram of single-ended sense amplifiers of a primary sense amplifier circuit, in accordance with an alternate embodiment of the present invention.

FIG. 36 is a waveform diagram illustrating signals associated with read accesses to bit cells coupled to the single-ended sense amplifiers of FIG. 35 in accordance with one embodiment of the present invention.

FIG. 37 is a waveform diagram illustrating signals associated with read accesses to bit cells coupled to single-ended sense amplifiers including MST transistors in accordance with a first alternate embodiment of the present invention.

FIG. 38 is a circuit diagram of single-ended MST sense amplifiers including kick capacitors in accordance with a second alternate embodiment of the present invention.

FIG. 39 is a waveform diagram illustrating signals associated with read accesses to bit cells coupled to the single-ended sense amplifiers of FIG. 38 in accordance with the second alternate embodiment of the present invention.

FIG. 40 is a circuit diagram of single-ended MST sense amplifiers including a grounded reference voltage and a negative logic ‘0’ bit cell voltage in accordance with a third alternate embodiment of the present invention.

FIG. 41 is a waveform diagram illustrating signals associated with read accesses to bit cells coupled to the single-ended sense amplifiers of FIG. 40 in accordance with the third alternate embodiment of the present invention.

FIG. 42 is a circuit diagram of single-ended MST sense amplifiers including a grounded reference voltage, a negative logic ‘0’ bit cell voltage and kick capacitors in accordance with a fourth alternate embodiment of the present invention.

FIG. 43 is a waveform diagram illustrating signals associated with read accesses to bit cells coupled to the single-ended sense amplifiers of FIG. 42 in accordance with the fourth alternate embodiment of the present invention.

### DETAILED DESCRIPTION

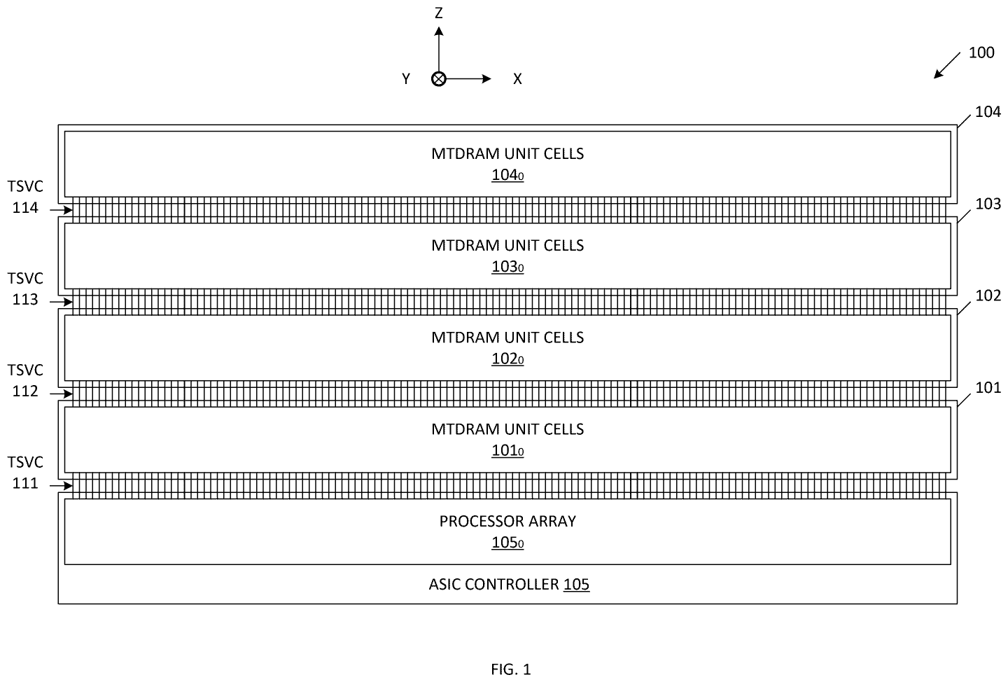

FIG. 1 is block diagram illustrating a multi-threaded dynamic random access memory (MTDRAM) processor system 100, in accordance with one embodiment of the present invention. MTDRAM processor system 100 includes four MTDRAM chips 101-104 and an ASIC controller chip 105, which are connected in a stack as illustrated. Each of the MTDRAM chips 101-104 includes a corresponding plurality of MTDRAM unit cells 101₀-104₀ and a plurality of through silicon vias (TSVs) (not shown in FIG. 1), which are described in more detail below. The TSVs of MTDRAM chip 101 are connected to a processor array 105₀ of ASIC controller chip 105 with a first plurality of TSV connectors (TSVC) 111. The TSVs of MTDRAM chip 101 also connected to the TSVs of MTDRAM chip 102 using a second plurality of TSV connectors 112. Similarly, the TSVs of MTDRAM chip 102 are also connected to the TSVs of MTDRAM chip 103 using a third plurality of TSV connectors 113, and the TSVs of MTDRAM chip 103 also connected to the TSVs of MTDRAM chip 104 using a fourth plurality of TSV connectors 114. In this manner, MTDRAM chips 101-104 are connected in a stacked configuration.

In the first embodiment described herein, each of the MTDRAM chips 101-104 includes 2048 independent MTDRAM unit cells, each having a storage capacity of 18 Mbits, such that each of the MTDRAM chips 101-104 has a storage capacity of 32 Gbits. In accordance with the following description, it is understood that the MTDRAM chips can be modified to include other numbers of MTDRAM unit cells having other capacities in other embodiments. FIG. 1 also illustrates X, Y and Z axes, which are consistently used throughout the drawings to more clearly define the MTDRAM system 100.

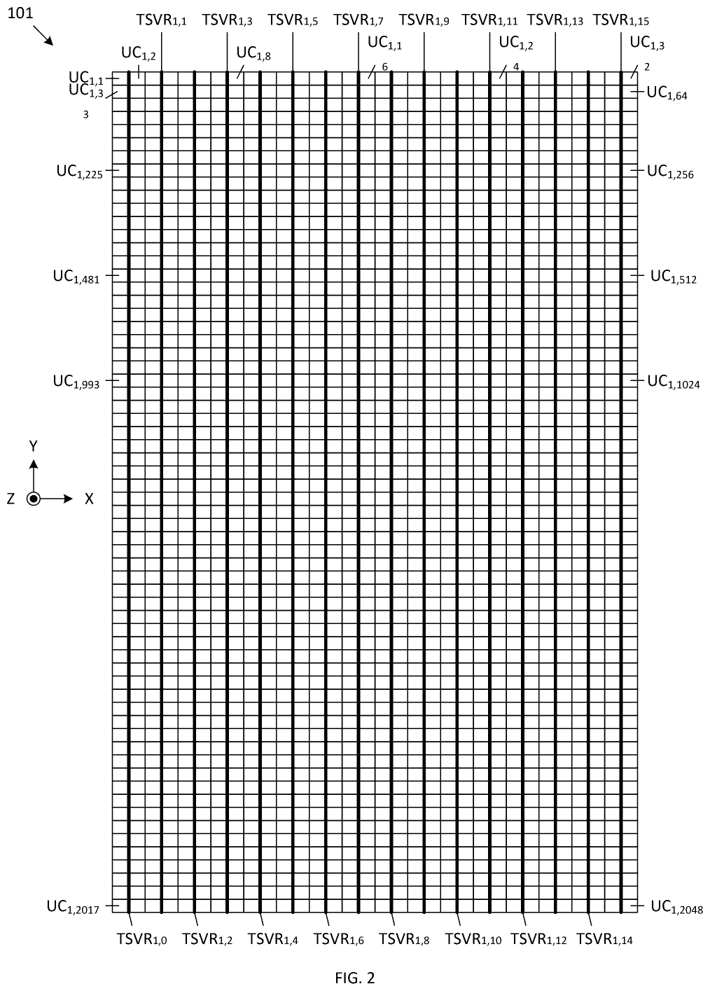

FIG. 2 is a top view of MTDRAM chip 101, illustrating the layout of the 2048 included MTDRAM unit cells UC_{1,1} to UC_{1,2048} (wherein unit cells UC_{1,1}, UC_{1,8}, UC_{1,16}, UC_{1,24}, UC_{1,32}, UC_{1,33}, UC_{1,64}, UC_{1,225}, UC_{1,256}, UC_{1,481}, UC_{1,512}, UC_{1,993}, UC_{1,1024}, UC_{1,2017} and UC_{1,2048} are specifically labeled, thereby illustrating the numbering convention of the MTDRAM unit cells). The 2048 MTDRAM unit cells UC_{1,1} to UC_{1,2048} are organized into 32 columns and 64 rows of unit cells, wherein each row of MTDRAM unit cells extends along the X-axis width of the MTDRAM chip 101, as illustrated, and each column of MTDRAM unit cells extends along the Y-axis height of the MTDRAM chip 101.

Main TSV regions TSVR_{1,0} to TSVR_{1,15} are centrally located between columns of unit cells, as illustrated. More specifically, the main TSV region TSVR_{1,0} is located between the first pair of MTDRAM unit cell columns (i.e., between the first column of MTDRAM unit cells and the second column of MTDRAM unit cells). The main TSV region TSVR_{1,1} is located between the second pair of MTDRAM unit cell columns (i.e., between the third column of MTDRAM unit cells and the fourth column of MTDRAM unit cells). This pattern is repeated for the entire MTDRAM chip 101. Each of the main TSV regions TSVR_{1,0} to TSVR_{1,15} extends along the Y-axis height of the MTDRAM chip 101.

As described in more detail below, each of the MTDRAM unit cells UC_{1,1} to UC_{1,2048} has a dedicated set of TSVs within an adjacent one of the main TSV regions TSVR_{1,0} to TSVR_{1,15}, wherein this dedicated set of TSVs is used to carry data, address and control information to/from the corresponding MTDRAM unit cell. Although the main TSV regions are located adjacent to the unit cells in FIG. 2, it is understood that other TSVs (not shown in FIG. 2) may extend through other locations within the unit cells (including unused areas of the unit cells that do not include circuitry required by the MTDRAM array structure). The TSVs included in the main TSV regions TSVR_{1,0} to TSVR_{1,15} (as well as the other TSVs not located in the main TSV regions) are coupled to the TSV connectors 111 and 112 in the manner illustrated by FIG. 1.

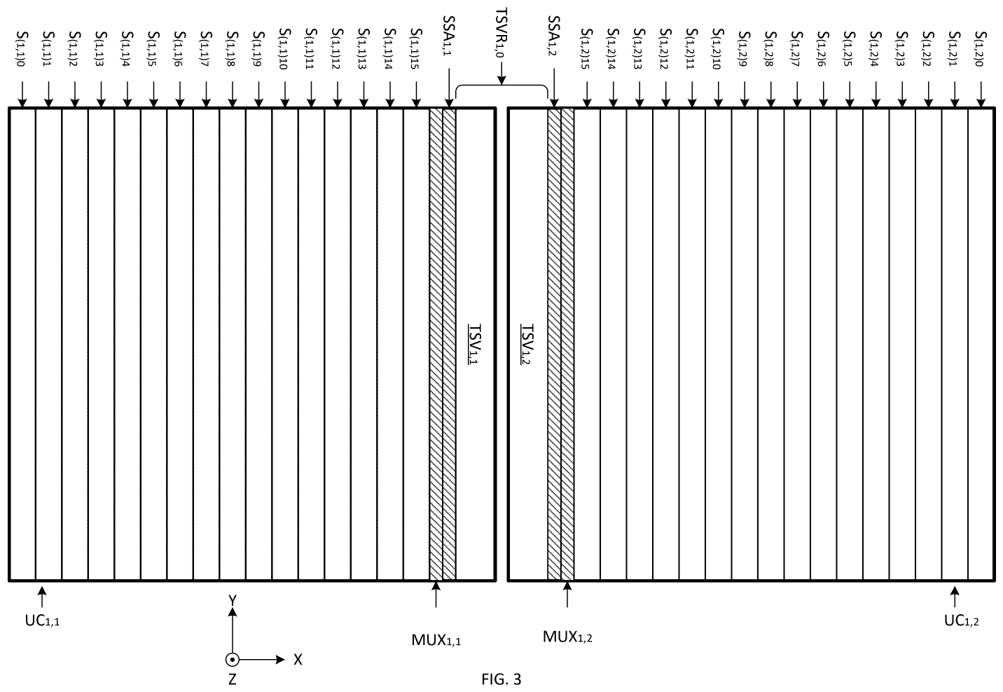

FIG. 3 is a top view illustrating the horizontally adjacent MTDRAM unit cells UC_{1,1} and UC_{1,2} of FIG. 2, along with the corresponding portion of main TSV region TSVR_{1,0} located between these unit cells, in accordance with one embodiment of the present invention.

Each of the MTDRAM unit cells UC_{1,1} to UC_{1,2048} includes sixteen 1.125 Mbit MTDRAM strips, wherein each of these strips extends vertically along the height of the unit cell (along the Y-axis). The sixteen MTDRAM strips of each unit cell are laid out in parallel along the Y-axis. As illustrated by FIG. 3, MTDRAM unit cell UC_{1,1} includes sixteen MTDRAM strips S_{(1,1)0} to S_{(1,1)15}, and MTDRAM unit cell UC_{1,2} includes sixteen MTDRAM strips S_{(1,2)0} to S_{(1,2)15.}

Each of the MTDRAM unit cells UC_{1,1} to UC_{1,2048} also includes a multiplexer and a secondary sense amplifier circuit located between the sixteen MTDRAM strips of the unit cell and the corresponding main TSV region. For example, unit cell UC_{1,1} includes multiplexer MUX_{1,1} and secondary sense amplifier circuit SSA_{1,1}, which are located between MTDRAM strips S_{(1,1)0} to S_{(1,1)15} and main TSV region TSVR_{1,0}. Similarly, unit cell UC_{1,2} includes multiplexer MUX_{1,2} and secondary sense amplifier circuit SSA_{1,2}, which are located between MTDRAM strips S_{(1,2)0} to S_{(1,2)15} and main TSV region TSVR_{1,0}.

Each of the MTDRAM unit cells UC_{1,1} to UC_{1,2048} also includes a dedicated set of TSVs within its corresponding main TSV region. For example, unit cell UC_{1,1} includes a dedicated TSV set TSV_{1,1} within the corresponding main TSV region TSVR_{1,0}, and unit cell UC_{1,2} includes a dedicated TSV set TSV_{1,2} within the corresponding main TSV region TSVR_{1,0}.

In the manner illustrated by FIG. 3, the horizontally adjacent MTDRAM unit cells UC_{1,1} and UC_{1,2} are laid out as mirror images of one another on MTDRAM chip 101. In the described embodiments, each pair of horizontally adjacent MTDRAM unit cells separated by a main TSV region have the same configuration as MTDRAM unit cells UC_{1,1} and UC_{1,2}.

Although the unit cells UC_{1,1}-UC_{1,2048} have the same logical configuration in the described embodiment, it is understood that in other embodiments, different unit cells on MTDRAM chip 101 can have different logical configurations. For example, in other embodiments, different unit cells can have different numbers of MTDRAM strips, different numbers of MTDRAM bit cells, different data word widths, different numbers of data channels, etc., in a manner that would be apparent to one of ordinary skill.

The configuration and operation of the MTDRAM strips S_{(1,1)0}-S_{(1,1)15}, multiplexer MUX_{1,1} and secondary sense amplifier circuit SSA_{1,1} (along with the signals transmitted on the corresponding TSV set TSV_{1,1}) is described in more detail below.

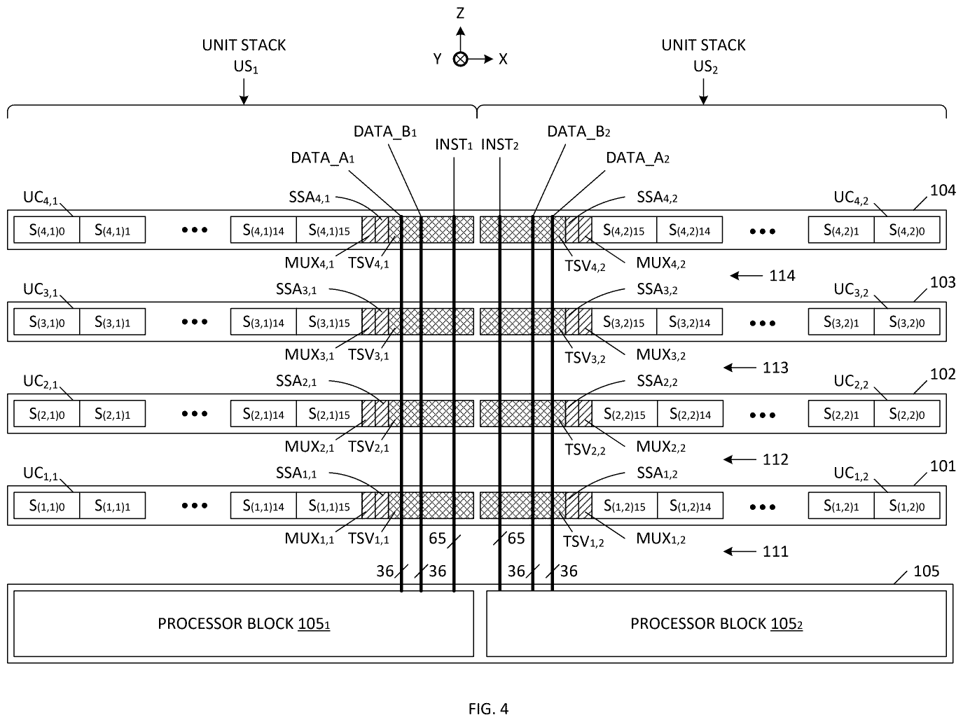

The MTDRAM chips 102, 103 and 104 have the same layout illustrated for MTDRAM chip 101 in FIG. 2, wherein the 2048 unit cells UC_{1,1}-UC_{1,2048} of MTDRAM chip 101 are re-numbered as unit cells UC_{2,1}-UC_{2,2048} in MTDRAM chip 102, unit cells UC_{3,1}-UC_{3,2048} in MTDRAM chip 103, and unit cells UC_{4,1}-UC_{4,2048} in MTDRAM chip 104. Similarly, the main TSV regions TSVR_{1,0}-TSVR_{1,15} of MTDRAM chip 101 are re-numbered as main TSV regions TSVR_{2,0}-TSVR_{2,15} in MTDRAM chip 102, main TSV regions TSVR_{3,0}-TSVR_{3,15} in MTDRAM chip 103, and main TSV regions TSVR_{4,0}-TSVR_{4,15} in MTDRAM chip 104. The unit cells UC_{1,x}, UC_{2,x}, UC_{3,x} and UC_{4,x} (x=1 to 2048) of MTDRAM chips 101-104 are vertically aligned along the Z-axis. Similarly, the main TSV regions TSVR_{y,0}-TSVR_{y,15} (y=1 to 4) are vertically aligned along the Z-axis. This configuration enables vertically aligned MTDRAM unit cells to be connected to form MTDRAM unit stacks, as shown in more detail in FIG. 4.

FIG. 4 is a side view of two adjacent MTDRAM unit stacks US₁ and US₂ in accordance with one embodiment of the present invention. Unit stack US₁ includes four vertically aligned MTDRAM unit cells UC_{1,1}, UC_{2,1}, UC_{3,1} and UC_{4,1} in MTDRAM chips 101, 102, 103 and 104, respectively. The unit cells UC_{1,1} UC_{2,1} UC_{3,1} UC_{4,1} are connected to one another (and processor block 1051) via TSVs in corresponding TSV sets TSV_{1,1}, TSV_{2,1}, TSV_{3,1} and TSV_{4,1}, respectively, and the TSV connectors 111-114 (FIG. 1). More specifically, unit stack US₁ includes an instruction bus INST₁ and two independent 36-bit data buses DATA_A₁ and DATA_B₁, which are constructed using TSVs in TSV regions TSV_{1,1} TSV_{2,1}, TSV_{3,1} and TSV_{4,1} and TSV connectors 111-114.

The sixteen strips within each unit cell UC_{x,1} are labeled as strips S_{(x,1)0} to S_{(x,1)15}, wherein x=1 to 4. The multiplexer within each unit cell UC_{x,1} is labeled as MUX_{x,1}, wherein x=1 to 4, and the secondary sense amplifier circuit within each unit cell UC_{x,1} is labeled as SSA_{x,1}, wherein x=1 to 4.

Similarly, independent unit stack US₂ includes four vertically aligned MTDRAM unit cells UC_{1,2}, UC_{2,2}, UC_{3,2} and UC_{4,2} in MTDRAM chips 101, 102, 103 and 104, respectively. The unit cells UC_{1,2} UC_{2,2} UC_{3,2} UC_{4,2} are connected to one another (and corresponding processor block 1052) via TSVs in corresponding TSV sets TSV_{1,2}, TSV_{2,2}, TSV_{3,2} and TSV_{4,2}, respectively, and the TSV connectors 111-114 (FIG. 1). More specifically, unit stack US₂ includes an instruction bus INST₂ and two independent 36-bit data buses DATA_A₂ and DATA_B₂, which are constructed using TSVs in TSV regions TSV_{1,2} TSV_{2,2}, TSV_{3,2} and TSV_{4,2} and TSV connectors 111-114.

The sixteen strips within each unit cell UC_{x,2} are labeled as strips S_{(x,2)0} to S_{(x,2)15}, wherein x=1 to 4. The multiplexer within each unit cell UC_{x,2} is labeled as MUX_{x,2}, wherein x=1 to 4, and the secondary sense amplifier within each unit cell UC_{x,2} is labeled as SSA_{x,2}, wherein x=1 to 4.

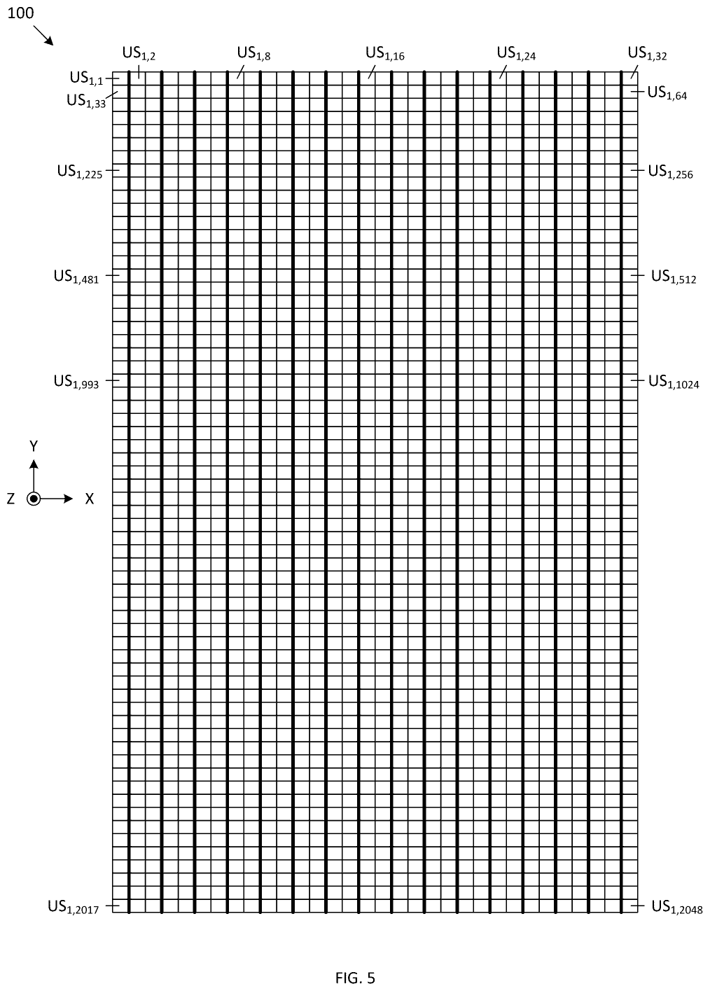

Although FIG. 4 illustrates two unit stacks US₁ and US₂, it is understood that a total of 2048 independent unit stacks, each identical to unit stack US₁ (or US₂), are formed from the unit cells of MTDRAM chips 101-104. More specifically each unit stack USₓ includes the four unit cells UC_{1,x}, UC_{2,x}, UC_{3,x} and UC_{4,x} (x=1 to 2048) of MTDRAM chips 101, 102, 103 and 104. FIG. 5 is a top view of the 2048 unit stacks US₁-US₂₀₄₈ of MTDRAM system 100 in accordance with the present embodiment (wherein unit stacks US_{1,1}, US_{1,8}, US_{1,16}, US_{1,24}, US_{1,32}, US_{1,33}, US_{1,64}, US_{1,225}, US_{1,256}, US_{1,481}, US_{1,512}, US_{1,993}, US_{1,1024}, US_{1,2017} and US_{1,2048} are specifically labeled to illustrate the numbering system).

MTDRAM unit cell UC_{1,1} will now be described in more detail. It is understood that each of the other unit cells UC_{2,1}, UC_{3,1} and UC_{4,1} of unit stack US₁ can be accessed in the same manner as unit cell UC_{1,1} in response to an instruction provided on instruction bus INST₁. As described in more detail below, each of the four unit cells of unit stack US₁ can be individually addressed by instructions provided on instruction bus INST₁.

As described in more detail below, processor array 105₀ can simultaneously access up to two nearly random address locations within each of the unit stacks US₁-US₂₀₄₈. Processor array 105₀ includes a plurality of processor blocks 105₁-105₂₀₄₈, which are coupled to corresponding unit stacks US₁-US₂₀₄₈, respectively. The following access patterns can be implemented within unit stack US₁. In general, an instruction transmitted on instruction bus INST₁ can be used to simultaneously access up to two data values in the same MTDRAM strip of unit stack US₁ (subject to access limitations imposed by the MTDRAM configuration, which are described in more detail below). Data is routed from/to the unit stack US₁ on two independent 36-bit data channels DATA_A₁ and DATA_B₁. The following access patterns are generally allowable.

Processor block 105₁ can access one data value in any one of the strips S_{(1,1)0}-S_{(1,1)15}, S_{(2,1)0}-S_{(2,1)15}, S_{(3,1)0}-S_{(3,1)15} or S_{(4,1)0}-S_{(4,1)15}, in any one of the unit cells UC_{1,1}, UC_{2,1}, UC_{3,1} or UC_{4,1} of unit stack US₁. For example, processor block 105₁ can access any data value in MTDRAM strip S_{(1,1)14} of unit cell UC_{1,1} in response to a single instruction on instruction bus INST₁ (subject to access limitations imposed by the MTDRAM configuration).

Processor block 105₁ can also simultaneously access two data values in any one of the strips in any one of the unit cells of unit stack US₁. As described in more detail below, a first half of each MTDRAM strip is designated to store data associated with the first data channel DATA_A₁, and a second half of each MTDRAM strip is designated to store data associated with the second data channel DATA_B₁. Processor block 105₁ can simultaneously access a first data value in the first half of MTDRAM strip S_{(1,1)14} on the first data channel DATA_A₁, and a second data value in the second half of MTDRAM strip S_{(1,1)14} on the second data channel DATA_B₁ in response to a single instruction on instruction bus INST₁ (subject to access limitations imposed by the MTDRAM configuration). A specific addressing scheme used to access unit stack US₁ is described in more detail below.

Note that each of the unit stacks US₁-US₂₀₄₈ can be simultaneously and independently accessed in the same manner described above for unit stack US₁. Thus, processor array 105₀ has the address bandwidth to simultaneously access data from up to 4096 nearly random address locations within the unit stacks US₁-US₂₀₄₈.

As mentioned above, the configuration of the MTDRAM unit cells imposes some access limitations. The configuration (and limitations) of the unit cells will now be described in more detail.

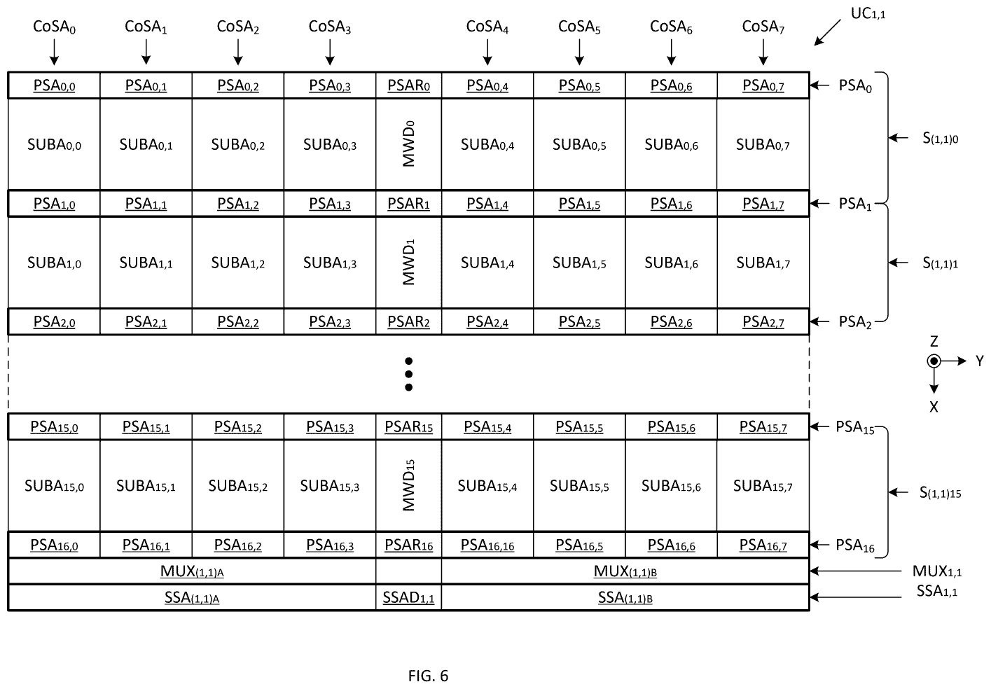

FIG. 6 is a block diagram of MTDRAM unit cell UC_{1,1} in accordance with one embodiment of the present invention. Although FIG. 6 specifically illustrates MTDRAM strips S_{(1,1)0}, S_{(1,1)1} and S_{(1,1)15} of unit cell UC_{1,1}, it is understood that the remaining MTDRAM strips S_{(1,1)2} to S_{(1,1)14} of unit cell UC_{1,1} have the same configuration. Note that the layout of the MTDRAM strips of FIG. 6 are rotated 90 degrees clockwise with respect to the orientation illustrated by FIGS. 2 and 3. This rotation is specified by the X-Y-Z axis representation in these figures.

Each MTDRAM strip S_{(1,1)x} includes eight corresponding sub-arrays SUBA_{x,0}-SUBA_{x,7} (wherein x=0 to 15 for strips S_{(1,1)0} to S_{(1,0)15}, respectively). Each of the MTDRAM strips S_{(1,1)0} to S_{(1,1)15} extends across the height of the unit cell UC_{1,1} along the Y-axis. The sub-arrays of the MTDRAM strips S_{(1,1)0} to S_{(1,1)15} are arranged in eight sub-array columns CoSA₀ to CoSA₇, which extend along the X-axis, as illustrated, wherein each sub-array column CoSA_{y} includes sub-arrays SUBA_{0,y}-SUBA_{15,y} (wherein y=0 to 7 for sub-array columns CoSA₀ to CoSA₇, respectively). As described in more detail below, sub-array columns CoSA₀-CoSA₃ are dedicated to data channel DATA_A₁ of unit stack US₁ and sub-array columns CoSA₄-CoSA₇ are dedicated to data channel DATA_B₁ of unit stack US₁ in the described embodiments. It is understood that in other embodiments, the sub-array columns CoSA₀-CoSA₇ can be dedicated to data channels DATA_A₁ and DATA_B₁ in different manners.

Each MTDRAM strip S_{(1,1)x} also includes a centrally located main word line driver circuit MWDₓ (wherein x=0 to 15 for strips S_{(1,1)0} to S_{(1,1)15}, respectively). As described in more detail below, each main word line driver circuit is configured to drive an addressed main word line in the corresponding strip.

Each MTDRAM strip S_{(1,1)x} also includes a pair of corresponding primary sense amplifier circuits PSAₓ and PSA₍ₓ₊₁₎ (wherein x=0 to 15). For example, MTDRAM strip S_{(1,1)0} includes primary sense amplifier circuits PSA₀ and PSA₁. Each primary sense amplifier circuit PSAₓ is subdivided into eight corresponding primary sense amplifier sub-circuits PSA_{x,0}-PSA_{x,7} (wherein x=0 to 15 for strips S_{(1,1)0} to S_{(1,1)15}, respectively). For example, primary sense amplifier circuit PSA₁ is subdivided into eight corresponding primary sense amplifier sub-circuits PSA_{1,0}-PSA_{1,7}. Each primary sense amplifier sub-circuit is coupled to one (or two) adjacent MTDRAM sub-arrays, as illustrated. For example, primary sense amplifier sub-circuits PSA_{0,0} to PSA_{0,7} of primary sense amplifier circuit PSA₀ are coupled to adjacent MTDRAM sub-arrays SUBA_{0,0} to SUBA_{0,7}, respectively. Similarly, primary sense amplifier sub-circuits PSA_{1,0} to PSA_{1,7} of primary sense amplifier circuit PSA₁ are coupled to adjacent MTDRAM sub-arrays SUBA_{0,0} to SUBA_{0,7}, respectively, and adjacent MTDRAM sub-arrays SUBA_{1,0} to SUBA_{1,7}, respectively.

Vertically adjacent sub-arrays (along the X-axis) share primary sense amplifier sub-circuits. For example, an access to sub-array SUBA_{0,0} requires the activation of primary sense amplifier sub-circuits PSA_{0,0} and PSA_{1,0}. Similarly, an access to vertically adjacent sub-array SUBA_{1,0} requires activation of primary sense amplifier sub-circuits PSA_{1,0} and PSA_{2,0}. Thus, sub-arrays SUBA_{0,0} and SUBA_{1,0} ‘share’ primary sense amplifier sub-circuit PSA_{1,0}. The time required to cycle (reset) each primary sense amplifier sub-circuit after activation (i.e., Row Cycle time) is about 32 nanoseconds (ns) in the described embodiment. Thus, after accessing sub-array SUB_{0,0}, a subsequent access to sub-array SUBA_{0,0} and/or sub-array SUBA_{1,0} must not occur for 32 ns (i.e., until shared primary sense amplifier sub-circuit PSA_{1,0} has been reset). This is one limitation to implementing entirely random accesses within unit cell UC_{1,1}. Although the Row Cycle time is listed as about 32 ns, it is understood that the Row Cycle time may be shorter, based on testing of the associated circuitry.

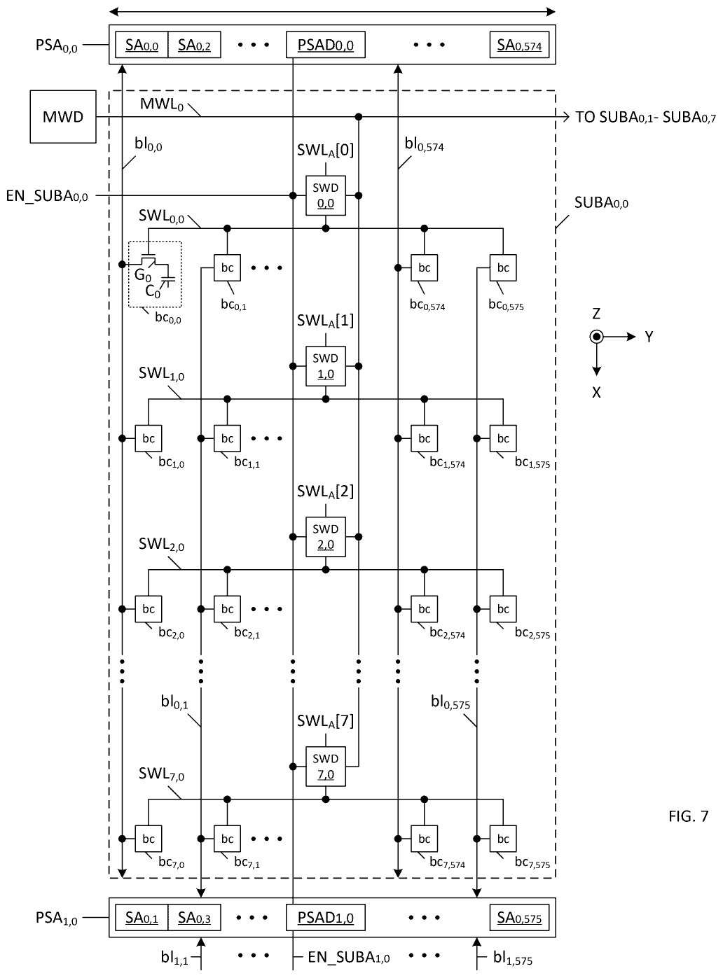

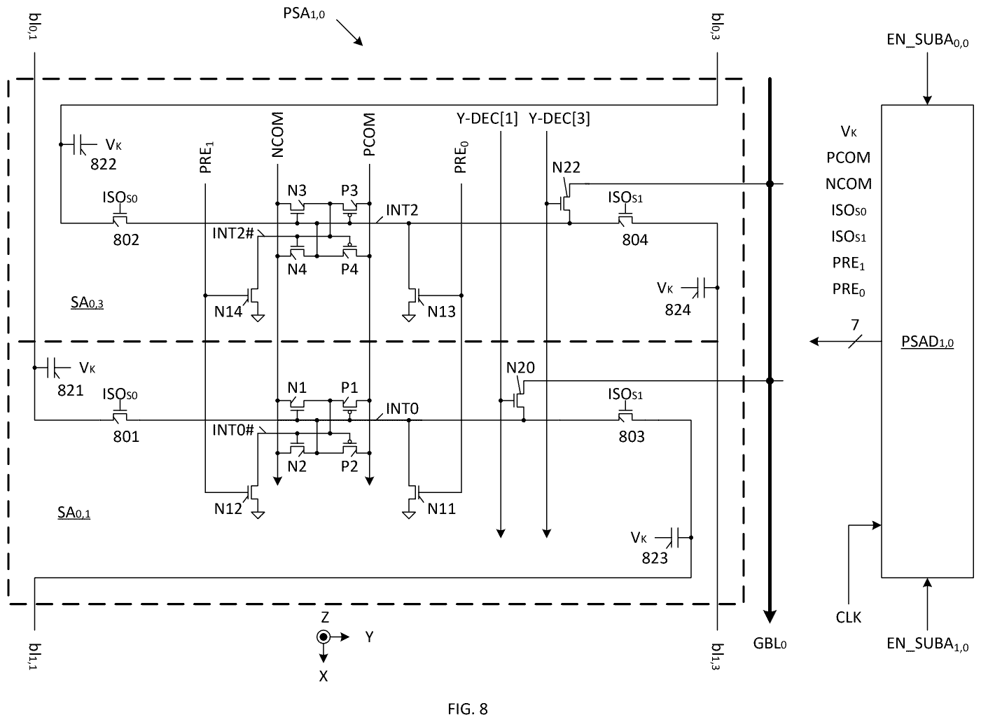

Each primary sense amplifier sub-circuit (e.g., PSA_{0,0}) includes a plurality (288) of single-ended sense amplifiers and a corresponding primary sense amplifier driver circuit (e.g., PSAD_{0,0}), which are described in more detail below in connection with FIGS. 7-8. Each primary sense amplifier driver circuit generates signals for controlling the plurality of single-ended sense amplifiers in the corresponding primary sense amplifier sub-circuit.

Each primary sense amplifier circuit PSA₀-PSA₁₆ also includes a corresponding centrally located region PSAR₀-PSAR₁₆, respectively. Although the primary sense amplifier driver circuits (e.g., PSAD_{0,0}) are located within a corresponding primary sense amplifier sub-circuit (e.g., PSA_{0,0}) in the described embodiments, it is understood that some (or all) portions of these primary sense amplifier driver circuits can be located within the centrally located regions PSAR₀-PSAR₁₆ in other embodiments. In an alternate embodiment, the primary sense amplifier driver circuits are located on the ASIC controller chip 105, and TSVs carry the required control signals from the primary sense amplifier driver circuits on the ASIC controller chip 105 to the primary sense amplifier sub-circuits PSA_{0,0} to PSA_{16,7}. However, it is understood this embodiment undesirably requires substantially more TSVs within the unit cell UC_{1,1}.

As described above in connection with FIGS. 3-4, MTDRAM unit cell UC_{1,1} also includes multiplexer MUX_{1,1} and secondary sense amplifier circuit SSA_{1,1}. Multiplexer MUX_{1,1} includes a first multiplexer circuit MUX_{(1,1)A} associated with the sub-array columns CoSA₀-CoSA₃ dedicated to data channel DATA_A₁, and a second multiplexer circuit MUX_{(1,1)B} associated with the sub-array columns CoSA₄-CoSA₇ dedicated to data channel DATA_B₁.

Secondary sense amplifier circuit SSA_{1,1} includes a first 72-bit secondary sense amplifier section SSA_{(1,1)A}, which is coupled to first multiplexer circuit MUX_{(1,1)A}, and is dedicated to data channel DATA_A₁. Secondary sense amplifier circuit SSA_{1,1} also includes a second 72-bit secondary sense amplifier section SSA_{(1,1)B}, which is coupled to second multiplexer circuit MUX_{(1,1)B}, and is dedicated to data channel DATA_B₁. Secondary sense amplifier circuit SSA_{1,1} also includes a centrally located secondary sense amplifier driver circuit SSAD_{1,1} that generates signals for controlling the secondary sense amplifier sections SSA_{(1,1)A} and SSA_{(1,1)B}. The operation and control of multiplexer MUX_{1,1} and secondary sense amplifier circuit SSA_{1,1} is described in more detail below.

FIG. 7 is a diagram illustrating the first eight rows of sub-array SUBA_{0,0}, a corresponding main word line driver MWD (included in main word line driver circuit MWD₀), and the corresponding primary sense amplifier sub-circuits PSA_{0,0} and PSA_{1,0}.

In the embodiments described herein, each of the MTDRAM sub-arrays includes 256 rows and 576 columns of MTDRAM bit cells. Although other numbers of rows/columns are possible in other embodiments, the selected number of rows and columns provides advantages with the configuration of unit cell UC_{1,1}, which will become apparent in view of the following description.

As illustrated by FIG. 7, the first eight rows of sub-array SUBA_{0,0} include a single main word line MWL₀ and eight associated sub-word lines SWL_{0,0} to SWL_{7,0}. Each of the sub-word lines SWL_{0,0}, to SWL_{7,0} is coupled to a corresponding row of 576 corresponding MTDRAM bit cells within the sub-array SUBA_{0,0}. For example, sub-word line SWL_{0,0} is coupled to MTDRAM bit cells bc_{0,0} to bc_{0,575}, as illustrated. Bit cell bc_{0,0} is illustrated to show the configuration of the corresponding bit cell pass gate transistor G₀ and bit cell capacitor C₀. In the described embodiments, all bit cells have the same construction.

The 576 data bits associated with each sub-word line correspond with eight 72-bit values. In various embodiments, these 72-bit values may include: eight 8-bit data values and an 8-bit error correction code (ECC) value, eight 8-bit data values and an 8-bit packet header value, or two separate 36-bit data values.

Sub-word lines SWL_{0,0} to SWL_{7,0} are selectively driven by sub-word line driver circuits SWD_{0,0} to SWD_{7,0}, respectively. At most, only one of the eight sub-word line driver circuits SWD_{0,0} to SWD_{7,0} is activated for an access to sub-array SUBA_{0,0}. Each of the sub-word line driver circuits SWD_{0,0} to SWD_{7,0} is centrally located within the sub-array SUBA_{0,0} (along the Y-axis), wherein the sub-word line driver circuits SWD_{0,0} to SWD_{7,0} are vertically aligned in a column (along the X-axis), as illustrated by FIG. 7.

Each of the sub-word line driver circuits SWD_{0,0} to SWD_{7,0} is coupled to receive the signal on the corresponding main word line MWL₀. To access the data associated with one of the sub-word lines SWL_{0,0} to SWL_{7,0}, the main word line MWL₀ is activated, along with the corresponding sub-word line driver circuit associated with the accessed sub-word line.

Each of the sub-word line driver circuits SWD_{0,0} to SWD_{7,0} is also coupled to receive a sub-array enable signal EN_SUBA_{0,0}, which is applied to each of the sub-word line driver circuits in sub-array SUBA_{0,0}. Sub-word line driver circuits SWD_{0,0} to SWD_{7,0} are further coupled to receive sub-word line address signals SWL_{A}[0] to SWL_{A}[7], respectively. Each sub-word line driver circuit SWD_{x,0} (x=0 to 7) is configured to activate a sub-word line voltage on the corresponding sub-word line SWL_{x,0} in response to receiving an activated main word line signal MWL₀, an activated sub-word line address signal SWL_{A}[x] and an activated sub-array enable signal EN_SUBA_{0,0}. One specific manner in which the sub-word line driver circuits SWD_{0,0} to SWD_{7,0} operate is described in more detail in commonly owned, co-pending U.S. patent application Ser. No. 18/399,579, which is hereby incorporated by reference in its entirety.

The illustrated circuitry associated with the first eight rows of sub-array SUBA_{0,0} is repeated along the X-axis (32 times), such that the entire sub-array SUBA_{0,0} includes 32 main word lines, 256 sub-word line driver circuits and 256 sub-word lines. Thus, each of the main word lines is coupled to a corresponding set of eight sub-word line driver circuits (similar to sub-word line driver circuits SWD_{0,0} to SWD_{7,0}). Each set of eight sub-word line driver circuits is coupled to receive the eight corresponding sub-word line address signals SWL_{A}[0] to SWL_{A}[7](in the same order illustrated by FIG. 7). Each of the 256 sub-word line driver circuits in sub-array SUBA_{0,0} is further coupled to receive the same sub-array enable signal EN_SUBA_{0,0}. As described in more detail below, each of the sub-arrays of a unit stack is independently enabled by a corresponding sub-array enable signal.

Each of the 32 main word lines associated with the sub-array SUBA_{0,0} extends along the Y-axis to each of the sub-arrays included in the same strip S_{(1,1)0} (i.e., each of the main word lines extends along the Y-axis height of the unit cell UC_{1,1}). For example, the main word line MWL₀ extends to each of the sub-arrays SUBA_{0,1} to SUBA_{0,7} of MTDRAM strip S_{(1,1)0}. In the embodiments described herein, an access to unit cell UC_{1,1} results in the activation of a single one of the 512 main word lines within the unit cell. As described in more detail below, this activated main word line is specified by a 12-bit main word line address value MWL[11:0] and a 16-bit strip address value STRIP[15:0] on the instruction bus INST₁.

In the embodiments described herein, the sub-arrays SUBA_{x,0}-SUBA_{x,3} (x=0 to 15) located to the left-side of the centrally located main word line driver circuits MWD₀-MWD₁₅ (FIG. 6) are coupled to receive a first sub-word line address value SWL_{A}[7:0], which is associated with the first data channel DATA_A₁. The sub-arrays SUBA_{x,4}-SUBA_{x,7} (x=0 to 15) located to the right-side of the centrally located main word line driver circuits MWD₀-MWD₁₅ (FIG. 6) are coupled to receive a second sub-word line address value SWL_{B}[7:0], which is associated with the second data channel DATA_B₁.

Thus, to access unit cell UC_{1,1}, a single main word line (e.g., MWL₀) is activated within one of the strips (e.g., strip S_{(1,1)0}), a first word sub-word line (defined by SWL_{A}[7:0]) associated with the activated main word line is activated within a left-side sub-array within the selected strip (e.g., SUBA_{0,0}), and a second sub-word line (defined by SWL_{B}[7:0]) associated with the activated main word line is activated within a right-side sub-array within the selected strip (e.g., SUBA_{4,0}), wherein the first sub-word line and second sub-word line can have different (or the same) addresses. Providing independent sub word line address values SWL_{A}[7:0] and SWL_{B}[7:0] advantageously provides flexibility in addressing the unit cell UC_{1,1}. In an alternate embodiment, a single sub-word line address value is used to access the unit cell UC_{1,1}, thereby reducing the number of TSVs required in the instruction bus INST₁ by 8.

Using a single main word line address value and a single strip address value for both data channels DATA_A₁ and DATA_B₁ provides limitations to random address accessing within the unit stack US₁. In alternate embodiments, independent main word line addresses (and/or independent strip addresses) are provided for the left-side sub-arrays and the right-side sub-arrays of the unit stack, thereby reducing or eliminating the above-described random access limitations. It is understood that additional TSVs would be required to route the independent main word line addresses (and/or independent strip addresses) in such embodiments.

As described above, an access to an MTDRAM strip requires the activation of a main word line that extends along the entire length of the MTDRAM strip. Prior to performing a subsequent access to a different sub-array column (CoSA) within the same strip, the previously activated main word line must be pre-charged to its initial (deactivated) state. This main word line pre-charge operation limits the access rate to the MTDRAM strip. In accordance with one embodiment, the main word line pre-charge operation requires 4 ns (while accesses may occur at a rate of 1 GHz, or at a period of 1 ns). In this case, once a strip is accessed, a new address within the same strip cannot be accessed again for 4 ns. The required main word line pre-charge operation is a further limitation to random accessing of the unit stack US₁.

Each column of bit cells in sub-array SUBA_{0,0} is coupled to a corresponding bit line. More specifically, all 256 bit cells located in the same column as bit cell bc_{0,x} are coupled to bit line bl_{0,x} (wherein x=0 to 575). Bit lines bl_{0,y} (wherein y represents even values from 0 and 575) are coupled to corresponding single-ended sense amplifiers in primary sense amplifier sub-circuit PSA_{0,0}. More specifically, the ‘even’ bit lines bl_{0,0}, bl_{0,2}, . . . bl_{0,574} of sub-array SUBA_{0,0} are coupled to corresponding single-ended sense amplifiers SA_{0,0}, SA_{0,2}, . . . SA_{0,574}, respectively, in primary sense amplifier sub-circuit PSA_{0,0}.

Bit lines bl_{0,z} (wherein z represents odd values from 0 and 575) are coupled to corresponding single-ended sense amplifiers in primary sense amplifier sub-circuit PSA_{1,0}. More specifically, the ‘odd’ bit lines bl_{0,1}, bl_{0,3}, . . . bl_{0,575} of sub-array SUBA_{0,0} are coupled to corresponding single-ended sense amplifiers SA_{0,1}, SA_{0,3}, . . . SA_{0,575}, respectively, in primary sense amplifier sub-circuit PSA_{1,0}.

The ‘odd’ bit lines bl_{1,1}, bl_{0,3}, . . . bl_{1,575} of vertically adjacent sub-array SUBA_{1,0} are also coupled to corresponding single-ended sense amplifiers SA_{0,1}, SA_{0,3}, . . . SA_{0,575}, respectively, in primary sense amplifier sub-circuit PSA_{1,0} (thereby allowing the primary sense amplifier sub-circuit PSA_{1,0} to be shared by sub-arrays SUBA_{0,0} and SUBA_{1,0}).

Primary sense amplifier driver circuits PSAD_{0,0} and PSAD_{1,0} are centrally located within primary sense amplifier sub-circuits PSA_{0,0} and PSA_{1,0}, respectively, as illustrated in FIG. 7. These driver circuits PSAD_{0,0} and PSAD_{1,0} are vertically aligned with the sub-word line driver circuits SWD_{0,0} to SWD_{7,0} along the X-axis, advantageously simplifying the layout of associated sub-array column CoSA₀. Primary sense amplifier driver circuits PSAD_{0,0} and PSAD_{1,0} are coupled to receive the sub-array enable signal EN_SUBA_{0,0}, which is activated when sub-array SUBA_{0,0} is accessed. Primary sense amplifier driver circuit PSAD_{1,0} is also coupled to receive the sub-array enable signal EN_SUBA_{1,0}, which is activated when sub-array SUBA_{1,0} is accessed.

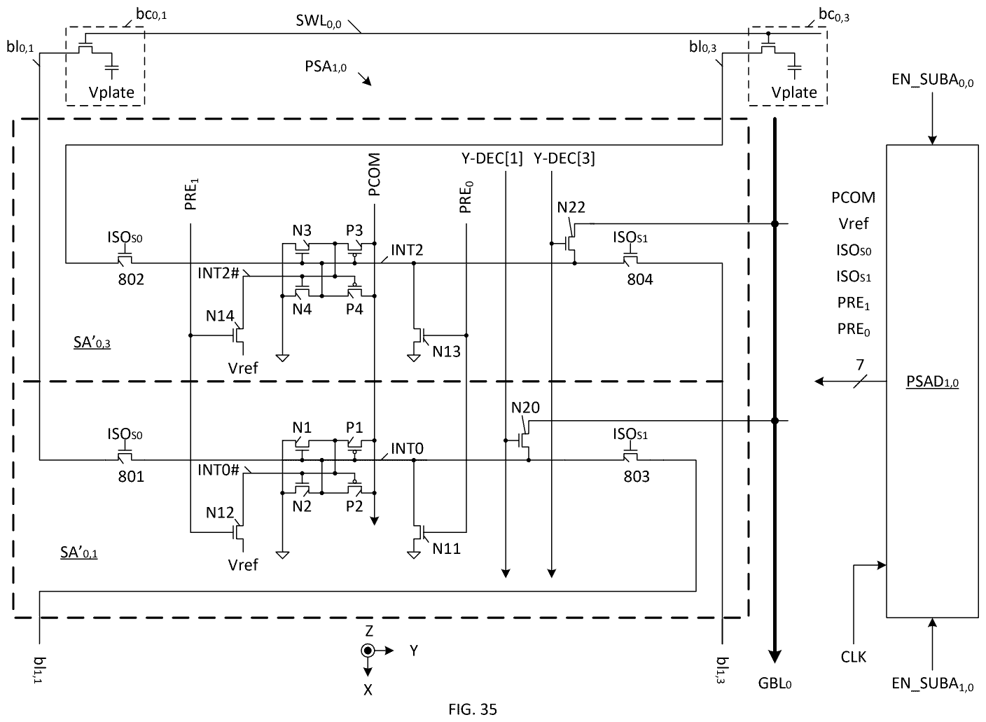

FIG. 8 is a diagram illustrating the manner in which the primary sense amplifier driver circuit PSAD_{1,0} controls accesses to single-ended sense amplifiers SA_{0,1} and SA_{0,3} within primary sense amplifier sub-circuit PSA_{1,0} in accordance with one embodiment of the present invention. It is understood that the control signals generated by primary sense amplifier driver circuit PSAD_{1,0} are provided to all of the single-ended sense amplifiers of primary sense amplifier sub-circuit PSA_{1,0} in parallel. It is also understood that the single-ended sense amplifiers SA_{0,1} and SA_{0,3} (along with any of the other single-ended sense amplifiers included in the unit cell UC_{1,1}) can be replaced with any of the single-ended sense amplifiers described below in connection with FIGS. 35 to 41 in alternate embodiments of the present invention.

Single-ended sense amplifier SA_{0,1} includes p-channel transistors P1-P2, n-channel transistors N1-N2, N11-N12 and N20, internal sense amplifier nodes INT0 and INT0 #, thick oxide, high voltage NMOS transistors 801 and 803, and bit line voltage kick capacitors 821 and 823, which are connected as illustrated. Similarly, single-ended sense amplifier SA_{0,3} includes p-channel transistors P3-P4, n-channel transistors N3-N4, N13-N14 and N22, internal sense amplifier nodes INT2 and INT2 #, thick oxide, high voltage NMOS transistors 802 and 804, and bit line voltage kick capacitors 822 and 824, which are connected as illustrated.

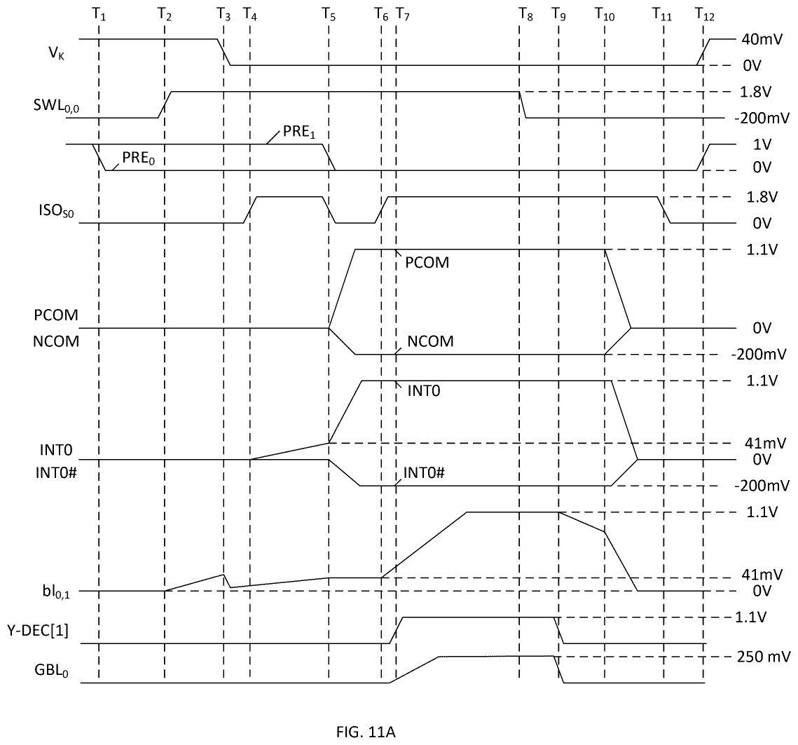

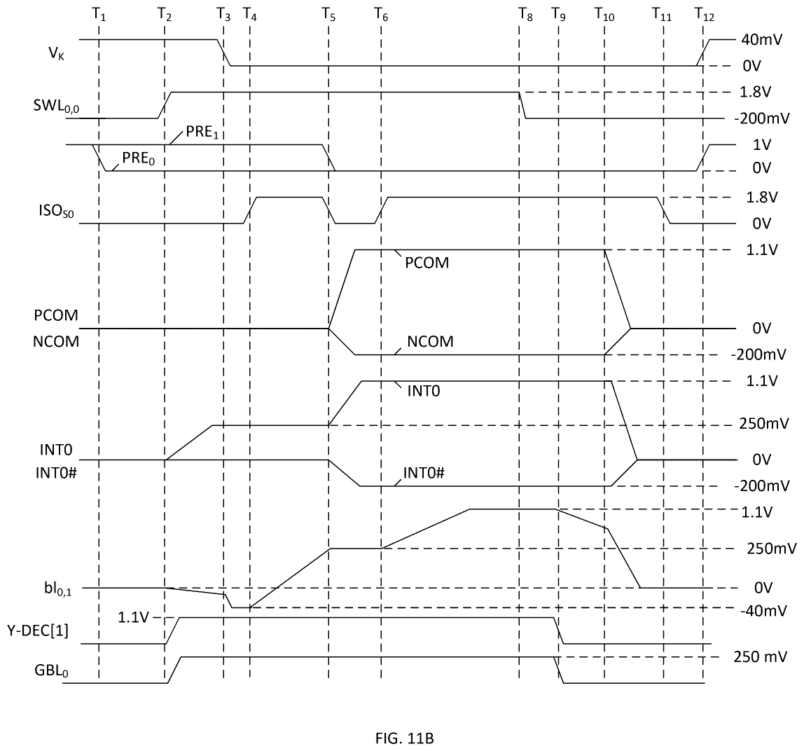

Single-ended sense amplifiers SA_{0,1} and SA_{0,3} operate in response to control signals provided by primary sense amplifier driver circuit PSAD_{1,0}, including kick control signal Vk (which is provided to capacitors 821-824, as illustrated), PCOM and NCOM (which are provided to latch circuits formed by transistors P1-P4 and N1-N4, as illustrated), ISO_{S0} and ISO_{S1} (which are isolation signals provided to transistors 801-802 and 803-804, as illustrated), and pre-charge signals PRE₀ and PRE₁, which are provided to transistors N11-N14 as illustrated). The specific timing of the above-described control signals and the corresponding operation of the single-ended sense amplifiers SA_{0,1} and SA_{0,3} is described in detail in U.S. patent application Ser. No. 18/399,579, which is hereby incorporated by reference in its entirety. The operation and control of the single-ended sense amplifiers SA_{0,1} and SA_{0,3} in response to the above-described control signals is also described in more detail below in connection with FIGS. 11A and 11B. In one embodiment, primary sense amplifier driver circuit PSAD_{1,0} generates the timing of the above-described control signals in response to a clock signal (CLK) provided on a TSV of the instruction bus INST₁. Advantageously, only the enabled primary sense amplifier driver circuits are activated to generate the required control signals, resulting in significant power savings within unit cell UC_{1,1}.

As described above, single-ended sense amplifier SA_{0,1} is coupled to ‘odd’ bit line bl_{0,1} of sub-array SUBA_{0,0}, and ‘odd’ bit line bl_{1,1} of sub-array SUBA_{1,0}. Similarly, single-ended sense amplifier SA_{0,3} is coupled to ‘odd’ bit line bl_{0,3} of sub-array SUBA_{0,0}, and ‘odd’ bit line bl_{1,3} of sub-array SUBA_{1,0}.

If the sub-array enable signal EN_SUBA_{0,0} is activated (indicating an access to sub-array SUBA_{0,0}), then primary sense amplifier driver circuit PSAD_{1,0} enables generation of the control signals ISO_{S0}, Vk, PCOM, NCOM, PRE₀ and PRE₁, such that the bit lines bl_{0,1} and bl_{0,3} of sub-array SUBA_{0,0} are effectively coupled to single-ended sense amplifiers SA_{0,1} and SA_{0,3}, respectively. During this access, primary sense amplifier driver circuit PSAD_{1,0} deactivates the isolation control signal ISO_{S1}, effectively de-coupling the bit lines bl_{1,1} and bl_{1,3} of sub-array SUBA_{1,0} from the single-ended sense amplifiers SA_{0,1} and SA_{0,3}, respectively. Note that each of the single-ended sense amplifiers SA_{0,1} and SA_{0,3} latches a data bit entirely in response to the signal developed on a single bit line.

Conversely, if the sub-array enable signal EN_SUBA_{1,0} is activated (indicating an access to sub-array SUBA_{1,0}), then primary sense amplifier driver circuit PSAD_{1,0} enables generation of the control signals ISO_{S1}, Vk, PCOM, NCOM, PRE₀ and PRE₁, such that the bit lines bl_{1,1} and bl_{1,3} of sub-array SUBA_{1,0} are effectively coupled to single-ended sense amplifiers SA_{0,1} and SA_{0,3}, respectively. During this access, primary sense amplifier driver circuit PSAD_{1,0} deactivates the isolation control signal ISO_{S0}, effectively de-coupling the bit lines bl_{0,1} and bl_{0,3} of sub-array SUBA_{0,0} from the single-ended sense amplifiers SA_{0,1} and SA_{0,3}, respectively.

In the manner described above, only primary sense amplifier sub-circuits associated with accessed sub-arrays are activated during an access to unit cell UC_{1,1}, advantageously resulting in significant power savings.

In an alternate embodiment, primary sense amplifier driver PSAD_{1,0} generates a first kick control voltage (e.g., V_{K1}), which is activated and applied to kick transistors 821 and 822 when the EN_SUBA_{0,0} signal is activated, and a second kick control voltage (e.g., V_{K2}), which is activated and applied to kick transistors 823 and 824 when the EN_SUBA_{1,0} signal is activated, thereby resulting in further power savings within unit cell UC_{1,1}. Note that this embodiment requires additional decoding circuitry within primary sense amplifier driver circuit PSAD_{1,0}.

In the described examples, the data transfer rate between the sub-arrays and the primary sense amplifier sub-circuits is 1 GHz. However, it is understood that higher data transfer rates can be implemented in other embodiments, based on real silicon performance capability for a given silicon technology. Other considerations may require slower data transfer rates in other embodiments.

Returning now to FIG. 7, a read access to sub-array SUBA_{0,0} results in 288 data bits being transferred from the bit cells associated with an addressed sub-word line to primary sense amplifier sub-circuit PSA_{0,0}, and also results in 288 data bits being transferred from the bit cells associated with the addressed sub-word line to primary sense amplifier sub-circuit PSA_{1,0}. As described above, each of these data bits is latched into a single-ended sense amplifier. Although the present example describes a read access to sub-array SUBA_{0,0}, (i.e., through data channel DATA_A₁) it is understood that a simultaneous (parallel) read access may be performed to one of the right-side sub-arrays SUBA_{0,4} to SUBA_{0,7} (i.e., through data channel DATA_B₁). Moreover, although the present example describes a read access, it is understood that write accesses are similarly performed within the unit cell UC_{1,1}.

Data stored in the primary sense amplifier circuits is selectively routed to global bit lines (GBLs), which extend along the X-axis through the unit cell UC_{1,1}. The global bit lines extend from the primary sense amplifier circuits to the multiplexer circuit MUX_{1,1} in a manner described in more detail below.

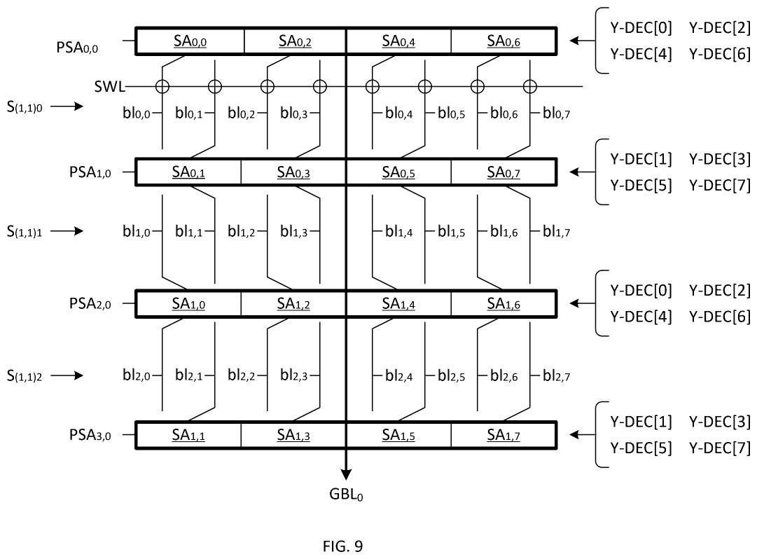

FIG. 9 is a block diagram illustrating the first eight bit line-to-primary sense amplifier connections in the first three strips S_{(1,1)0}-S_{(1,1)2} of unit cell UC_{1,1}, along with the associated global bit line GBL₀. In the first strip S_{(1,1)0}, the even bit lines bl_{0,0}, bl_{0,2}, bl_{0,4} and bl_{0,6} are coupled to corresponding single-ended sense amplifiers SA_{0,0}, SA_{0,2}, SA_{0,4} and SA_{0,6} in primary sense amplifier sub-circuit PSA_{0,0}. The odd bit lines bl_{0,1}, bl_{0,3}, bl_{0,5} and bl_{0,7} of the first strip S_{(1,1)0} are coupled to corresponding single-ended sense amplifiers SA_{0,1}, SA_{0,3}, SA_{0,5} and SA_{0,7} in primary sense amplifier sub-circuit PSA_{1,0}.

In the second strip S_{(1,1)1}, the odd bit lines bl_{1,1}, bl_{1,3}, bl_{1,5} and bl_{1,7} are coupled to corresponding single-ended sense amplifiers SA_{0,1}, SA_{0,3}, SA_{0,5} and SA_{0,7} in primary sense amplifier sub-circuit PSA_{1,0}. The even bit lines bl_{1,0}, bl_{1,2}, bl_{1,4} and bl_{1,6} of the second strip S_{(1,1)1} are coupled to corresponding single-ended sense amplifiers SA_{1,0}, SA_{1,2}, SA_{1,4} and SA_{1,6} in primary sense amplifier sub-circuit PSA_{2,0}.

In the third strip S_{(1,1)2}, the even bit lines bl_{2,0}, bl_{2,2}, bl_{2,4} and bl_{2,6} are coupled to corresponding single-ended sense amplifiers SA_{1,0}, SA_{1,2}, SA_{1,4} and SA_{1,6} in primary sense amplifier sub-circuit PSA_{2,0}. The odd bit lines bl_{2,1}, bl_{2,3}, bl_{2,5} and bl_{2,7} of the third strip S_{(1,1)2} are coupled to corresponding single-ended sense amplifiers SA_{1,1}, SA_{1,3}, SA_{1,5} and SA_{1,7} in primary sense amplifier sub-circuit PSA_{2,0}.

As described in more detail below, the routing of data between the single-ended sense amplifiers of unit cell UC_{1,1} and corresponding global bit lines is controlled by Y-address signals Y-DEC[7:0]. In general, the Y-address signals Y-DEC[0], Y-DEC[2], Y-DEC[4] and Y-DEC[6] control output routing from primary sense amplifier circuits PSA₀, PSA₂, PSA₄, PSA₆, PSA₈, PSA₁₀, PSA₁₂, PSA₁₄ and PSA₁₆ and the Y-address signals Y-DEC[1], Y-DEC[3], Y-DEC[5] and Y-DEC[7] control output routing from primary sense amplifier circuits PSA₁, PSA₃, PSA₅, PSA₇, PSA₉, PSA₁₁, PSA₁₃ and PSA₁₅.

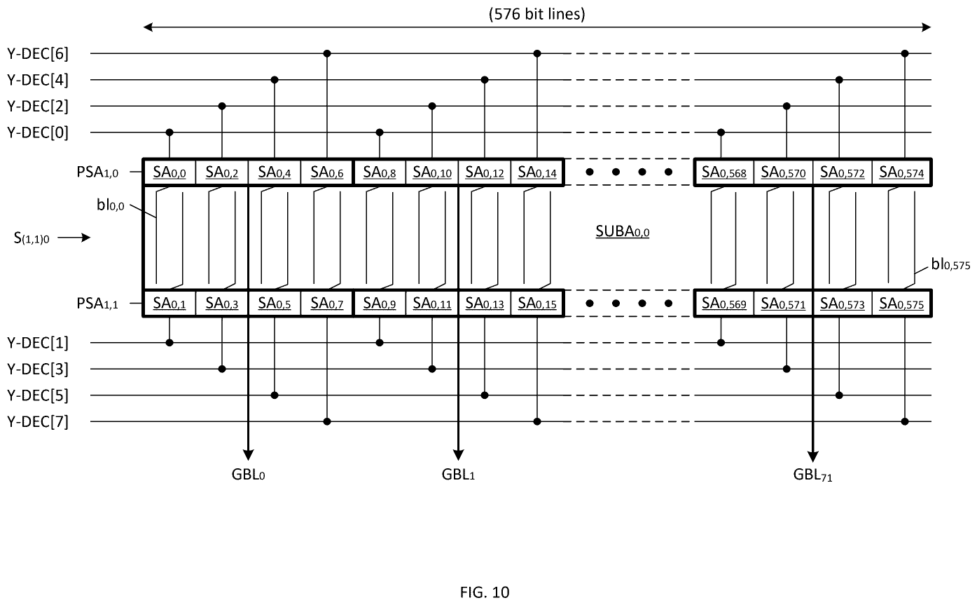

FIG. 10 is a block diagram illustrating MTDRAM sub-array SUBA_{0,0} the corresponding primary sense amplifier sub-circuits PSA_{1,0} and PSA_{1,1} and the corresponding global bit lines GBL₀-GBL₇₁ in accordance with one embodiment of the present invention. The global bit lines GBL₀-GBL₇₁ are shared by all of the sub-arrays in sub-array column CoSA₀. FIG. 10 illustrates the manner in which the Y-address signals Y-DEC[7:0] route data from the single-ended sense amplifiers of primary sense amplifier sub-circuits PSA_{0,0} and PSA_{1,0} to global bit lines GBL₀-GBL₇₁ in accordance with one embodiment of the present invention.

As described above, a read access to a row of sub-array SUBA_{0,0} results in 288 data bits being transferred to primary sense amplifier sub-circuit PSA_{1,0} on the even bit lines of sub-array SUBA_{0,0}, and 288 data bits being transferred to primary sense amplifier sub-circuit PSA_{1,1} on the odd bit lines of sub-array SUBA_{0,0}. As illustrated in FIG. 10, primary sense amplifier sub-circuit PSA_{1,0} includes 288 single-ended sense amplifiers SA_{0,Y} (wherein Y=even numbers from 0 to 574) and primary sense amplifier sub-circuit PSA_{1,1} includes 288 single-ended sense amplifiers SA_{0,Z} (wherein Z=odd numbers from 1 to 575), which store data read from a row of bit cells in sub-array SUBA_{0,0}.

Column select circuitry within primary sense amplifier sub-circuits PSA_{1,0} and PSA_{1,1} is controlled to selectively route a 72-bit data value onto global bit lines GBL₀-GBL₇₁ in response to a pre-decoded Y-address value Y-DEC[0:7] provided on the instruction bus INST₁.

As illustrated by FIG. 10, each global bit line GBL is coupled to eight corresponding single-ended sense amplifiers in primary sense amplifier sub-circuits PSA_{1,0} and PSA_{1,1}. For example, global bit line GBL₀ is coupled to four single-ended sense amplifiers SA_{0,0}, SA_{0,2}, SA_{0,4} and SA_{0,6} in primary sense amplifier sub-circuit PSA_{1,0} and four single-ended sense amplifiers SA_{0,1}, SA_{0,3}, SA_{0,5} and SA_{0,7} in primary sense amplifier sub-circuit PSA_{1,1}. Each of these eight single-ended sense amplifiers SA_{0,0}-SA_{0,7} is coupled to the global bit line GBL₀ by a corresponding transistor, which is controlled by the Y-address values Y-DEC[0] to Y-DEC[7], respectively. Note that FIG. 8 illustrates exemplary transistors N20 and N22, which couple the single-ended sense amplifiers SA_{0,1} and SA_{0,3} to global bit line GBL₀ in response to the Y-address values Y-DEC[1] and Y-DEC[3], respectively. Thus, if the Y-address value Y-DEC[1] is activated (and the Y-address values Y-DEC[0] and Y-DEC[2:7] are deactivated), then the data value stored in single-ended sense amplifier SA_{0,1} is transmitted onto global bit line GBL₀ (through turned on transistor N20).

The above-described pattern is repeated for successive sets of eight single-ended sense amplifiers, as illustrated, whereby a 72-bit data value is transmitted onto global bit lines GBL₀-GBL₇₁. It is noted that a burst read access of up to eight 72-bit data values can be performed for data stored in primary sense amplifier sub-circuits PSA_{1,0} and PSA_{1,1} by changing (e.g., incrementing) the Y-address value Y-DEC[0:7] over successive cycles, without reactivating the primary sense amplifier sub-circuits PSA_{1,0} and PSA_{1,1}. As described in more detail below, the Y-address value Y-DEC[0:7] is controlled by the processor block 105₁ (via instruction bus INST₁).

Note that global bit lines GBL₀-GBL₇₁ are shared by all of the sub-arrays in sub-array column CoSA₀. As described in more detail below, each of the eight sub-array columns CoSA₀-CoSA₇ of unit cell UC_{1,1} has a corresponding set of 72 global bit lines. In the embodiments described herein, all of the primary sense amplifiers of a unit stack share the same Y-address value Y-DEC[0:7].

As illustrated by FIGS. 9 and 10, when sub-array SUBA_{1,0} of strip S_{(1,1)1} is accessed, single-ended sense amplifiers in primary sense amplifier sub-circuit PSA_{1,0} are selectively coupled to global bit lines GBL₀-GBL₇₁ in response to the Y-address signals Y-DEC[1], Y-DEC[3], Y-DEC[5] and Y-DEC[7], and single-ended sense amplifiers in primary sense amplifier sub-circuit PSA_{2,0} are selectively coupled to global bit lines GBL₀-GBL₇₁ in response to the Y-address signals Y-DEC[0], Y-DEC[2], Y-DEC[4] and Y-DEC[6]. Using this pattern, each of the primary sense amplifier circuits PSA₀-PSA₁₆ only needs to receive four Y-address signals, advantageously reducing routing congestion within the unit cell UC_{1,1}.

The timing of Y-address value Y-DEC[0:7](and the timing of the read/write signals on the global bit lines) is different during read accesses and write accesses.

FIG. 11A is a waveform diagram illustrating the control signals used to read a (logic high) data value from bit cell bc_{0,1} of sub-array SUBA_{0,0} into single-ended sense amplifier SA_{0,1}, and then transfer this data value from the single-ended sense amplifier SA_{0,1} to global bit line GBL₀, in accordance with one embodiment. In general, the pre-charge signals PRE₀ and PRE₁ are activated (high) to pre-charge the single-ended sense amplifier SA_{0,1} prior to time T1. At time T1, the pre-charge control voltage PRE₀ is driven to GND, thereby turning off n-channel transistors N11 and N13, such that the internal sense amplifier nodes INT0 and INT2 are no longer actively pulled to GND through transistors N11 and N13.

At time T2, the sub-word line SWL_{0,0}, is driven high by the corresponding sub-word line driver circuit SWD_{0,0} (in response to the MWL₀, SWL_{A}[0] and EN_SUBA_{0,0} signals), thereby enabling the bit cell bc_{0,1} to provide positive charge onto corresponding bit line bl_{0,1}. At time T3, the kick voltage VK is activated low, thereby further developing the signal on the bit line bl_{0,1}. At time T4, the ISO_{S0} signal is activated, thereby coupling the bit line bl_{0,1} to internal node INT₀ of single-ended sense amplifier SA_{0,1}. At time T5, the pre-charge signal PRE₁ and the ISO_{S0} signal are deactivated, and the PCOM and NCOM voltages are activated, effectively enabling the single-ended sense amplifier SA_{0,1} to latch a logic high data value (i.e., a full read voltage is developed across the internal nodes INT0 and INT0 # of single-ended sense amplifier SA_{0,1}). At time T6, the ISO_{S0} signal is re-activated, such that the read voltage developed on internal node INT0 is driven onto bit line bl_{0,1} to refresh the bit cell bc_{0,0}. Shortly after time T6 (i.e., at time T7), the Y-address signal associated with bit line bl_{0,1} (i.e., Y-DEC[1]) is activated high (e.g., 1.1V), thereby coupling the internal node INT0 to global bit line GBL₀. Under these conditions, the voltage on global bit line GBL₀ is driven to a logic high voltage of about 250 mV (due to the capacitance of the global bit line structure, which is described in more detail below). Note that a read data voltage of about −200 mV is provided on the global bit line GBL₀ when a logic low data value is read from bit cell bc_{0,1}. The operation of the single-ended sense amplifier SA_{0,1} is described in more detail in U.S. patent application Ser. No. 18/399,579, which is hereby incorporated by reference in its entirety. Note that the Y-DEC[1] and GBL₀ signals are deactivated around time T9.

FIG. 11B is a waveform diagram illustrating the control signals used to write a logic high data value from global bit line GBL₀ into single-ended sense amplifier SA_{0,1}, and then transfer this data value from the single-ended sense amplifier SA_{0,1} onto bit line bl_{0,1} and into bit cell bc_{0,1} in accordance with one embodiment. Processing proceeds in a similar manner as the read access of FIG. 11A between time T1 to T5, with exceptions noted below. In the illustrated embodiment, bit cell bc_{0,1} stores a logic low data value, such that the voltage on bit line bl_{0,1} is initially pulled down below 0V when the sub-word line SWL_{0,0} is activated at time T2. Also at time T2, a write driver circuit within the secondary sense amplifier circuit SSA_{1,1} (described in more detail below), drives a logic high write data value (250 mV) onto global bit line GBL₀. Also at time T2, the Y-address signal associated with bit line bl_{0,1} (i.e., Y-DEC[1]) is activated high (e.g., 1.1V), thereby coupling the internal node INT0 to global bit line GBL₀. Under these conditions, the internal node INT0 is driven to a voltage of 250 mV. At time T3, the activated kick voltage Vk drives the voltage on bit line bl_{0,1} down to −40 mV. The ISO_{S0} signal is activated between time T4 and T5, whereby the 250 mV voltage on the internal node INT0 is applied to bit line bl_{0,1}. Advantageously, the single-ended sense amplifier SA_{0,1} is not activated until time T5 (i.e., PCOM and NCOM do not transition until time T5). As a result, the write driver circuit does not need to flip the state of the single-ended sense amplifier SA_{0,1} (i.e., the write driver circuit only needs to overcome the relatively small voltage (−40 mV) initially developed on the bit line bl_{0,1} at time T4).

At time T5, the pre-charge signal PRE₁ and the ISO_{S0} signal are deactivated, and the PCOM and NCOM voltages are activated, effectively enabling the single-ended sense amplifier SA_{0,1} to latch a logic high write data value (i.e., a full write voltage is developed across the internal nodes INT0 and INT0 # of single-ended sense amplifier SA_{0,1}). At time T6, the ISO_{S0} signal is re-activated, such that the write voltage developed on internal node INT0 is driven onto bit line bl_{0,1} to write bit cell bc_{0,1}. Signal processing proceeds in the manner illustrated by FIG. 11B to complete the write access. Note that the write driver circuit drives a voltage of −200 mV on the global bit line GBL₀ to write a logic low data value to bit cell bc_{0,1}. Note that the Y-DEC[1] and GBL₀ signals are deactivated around time T9.

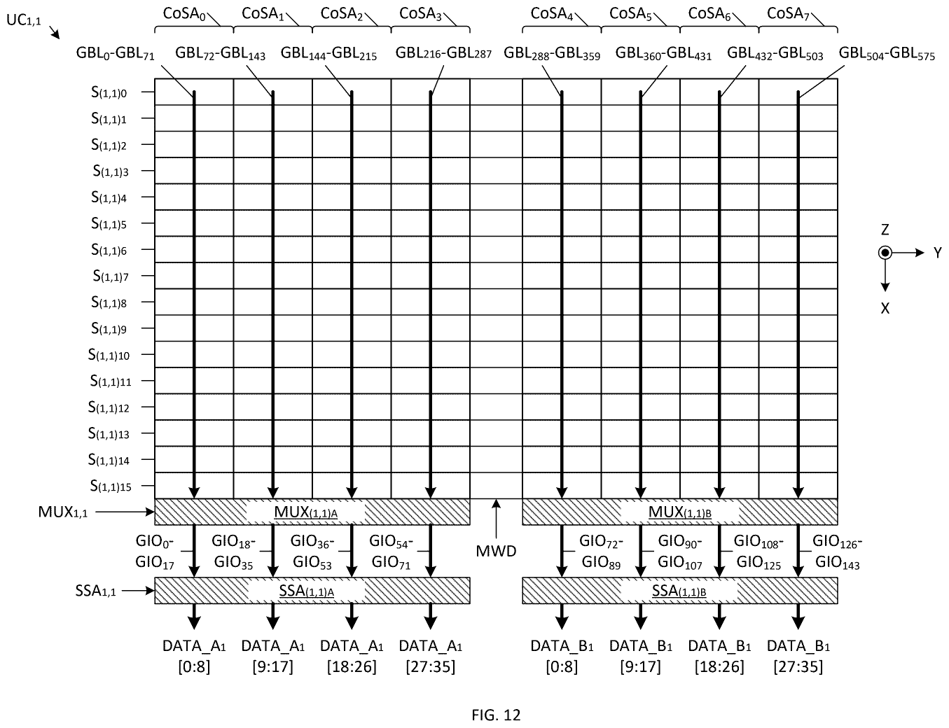

FIG. 12 is a diagram illustrating the data channels of unit cell UC_{1,1} in accordance with one embodiment of the invention. As described above in connection with FIG. 10, each of the sub-array columns CoSA₀-CoSA₇ includes a set of 72 global bit lines, which extend in parallel along the X-axis through strips S_{(1,1)0}-S_{(1,1)15}. More specifically, sub-array columns CoSA₀, CoSA₁, CoSA₂, CoSA₃, CoSA₄, CoSA₅, CoSA₆ and CoSA₇ include 72-bit global bit line sets GBL₀-GBL₇₁, GBL₇₂-GBL₁₄₃, GBL₁₄₄-GBL₂₁₅, GBL₂₁₆-GBL₂₈₇, GBL₂₈₈-GBL₃₅₉, GBL₃₆₀-GBL₄₃₁, GBL₄₃₂-GBL₅₀₃ and GBL₅₀₄-GBL₅₇₅, respectively, as illustrated. These global bit lines GBL₀-GBL₅₇₅ are coupled to multiplexer MUX_{1,1}. More specifically, global bit lines GBL₀-GBL₂₈₇ (which are associated with the left-side sub-arrays) are coupled to a first multiplexer section MUX_{(1,1)A} of multiplexer MUX_{1,1}, which is dedicated to data channel DATA_A₁ of unit stack US₁. Similarly, global bit lines GBL₂₈₈-GBL₅₇₅ (which are associated with the right-side sub-arrays) are coupled to a second multiplexer section MUX_{(1,1)B} of multiplexer MUX_{1,1}, which is dedicated to data channel DATA_B₁ of unit stack US₁.

If there is a read access to unit cell UC_{1,1} on data channel DATA_A₁, multiplexer section MUX_{(1,1)A} is controlled to route a 72-bit data value from one of the 72-bit global bit line sets GBL₀-GBL₇₁, GBL₇₂-GBL₁₄₃, GBL₁₄₄-GBL₂₁₅ or GBL₂₁₆-GBL₂₈₇ on global input/output (I/O) lines GIO₀-GIO₇₁.

Similarly, if there is a read access to unit cell UC_{1,1} on data channel DATA_B₁, multiplexer section MUX_{(1,1)B} is controlled to route a 72-bit data value from one of the 72-bit global bit line sets GBL₂₈₈-GBL₃₅₉, GBL₃₆₀-GBL₄₃₁, GBL₄₃₂-GBL₅₀₃ or GBL₅₀₄-GBL₅₇₅ on global I/O lines GIO₇₂-GIO₁₄₃.

Global I/O lines GIO₀-GIO₁₄₃ are coupled to secondary sense amplifier circuit SSA_{1,1}. More specifically, global input/output lines GIO₀-GIO₇₁ are coupled to a first secondary sense amplifier section SSA_{(1,1)A} of secondary sense amplifier circuit SSA_{1,1}, which is dedicated to data channel DATA_A₁ of unit stack US₁. Similarly, global input/output lines GIO₇₂-GIO₁₄₃ are coupled to a second secondary sense amplifier section SSA_{(1,1)B} of secondary sense amplifier circuit SSA_{1,1}, which is dedicated to data channel DATA_B₁ of unit stack US₁.

If there is a read access to unit cell UC_{1,1} on data channel DATA_A₁, secondary sense amplifier section SSA_{(1,1)A} is controlled to route a 72-bit data value received from multiplexer section MUX_{(1,1)A} to data channel DATA_A₁ as two 36-bit data values. As described in more detail below, the secondary sense amplifier section SSA_{(1,1)A} routes these two 36-bit data values at twice the frequency (2 GHz) that the 72-bit data values are read from the sub-arrays (1 GHz). The 36-bit data values routed by the secondary sense amplifier section SSA_{(1,1)A} are labeled DATA_A₁[0:35] in FIG. 12.

Similarly, if there is a read access to unit cell UC_{1,1} on data channel DATA_B₁, secondary sense amplifier section SSA_{(1,1)B} is controlled to amplify and route a 72-bit data value received from multiplexer section MUX_{(1,1)B} to data channel DATA_B₁ as two 36-bit data values in the same manner that multiplexer section MUX_{(1,1)A} amplifies and routes 72-bit data values to data channel DATA_A₁. The 36-bit data values routed by the secondary sense amplifier section SSA_{(1,1)B} are labeled DATA_B₁[0:35] in FIG. 12.

It is understood that the secondary sense amplifier section SSA_{(1,1)A} drives the output data values DATA_A₁[0:35] onto 36 corresponding TSVs in TSV set TSV_{1,1} (and the secondary sense amplifier section SSA_{(1,1)B} similarly drives the output data values DATA_B₁[0:35] onto 36 corresponding TSVs in TSV set TSV_{1,1}).

Note that in other embodiments, the secondary sense amplifier sections SSA_{(1,1)A} and SSA_{(1,1)B} can route the received 72-bit data values in other manners. For example, in an alternate embodiment, secondary sense amplifier sections SSA_{(1,1)A} and SSA_{(1,1)B} may be configured to route the 72-bit data values received from multiplexer sections MUX_{(1,1)A} and MUX_{(1,1)B} to data channels DATA_A₁ and DATA_B₁ as four 18-bit data values a frequency of 4 GHz. In this embodiment, the number of TSVs required to implement the corresponding unit stack US₁ is advantageously reduced (by 36).

Further note that the read data paths described above are reversed for write operations (wherein secondary sense amplifier sections SSA_{(1,1)A} and SSA_{(1,1)B} include write driver circuits, which are described in more detail below).

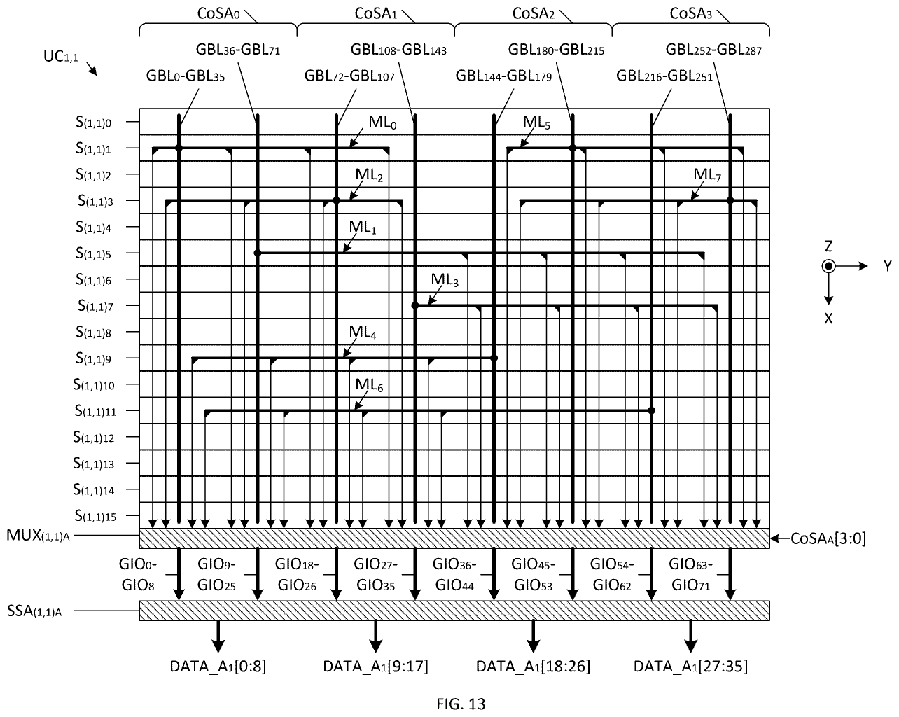

FIG. 13 is a diagram illustrating the manner in which the signals on the global bit lines GBL₀-GBL₂₈₇ are routed to the multiplexer section MUX_{(1,1)A} in accordance with one embodiment of the present invention. It is understood that the signals on global bit lines GBL₂₈₈-GBL₅₇₅ are routed to the multiplexer section MUX_{(1,1)B} in the same manner.

In general, the global bit lines GBL₀-GBL₂₈₇ extend in parallel along the X-axis width of the strips S_{(1,1)0}-S_{(1,1)15}, as illustrated. The signals of each set of 72 global bit lines are distributed horizontally along the X-Axis width of the multiplexer MUX_{(1,1)A}, in eight 9-bit groups. In one embodiment, horizontal metal lines (along the Y-axis) are used to distribute the signals from the global bit lines.

For example, a set of 36 metal lines ML₀ distribute the signals on global bit lines GBL₀-GBL₃₅ along the Y-axis, as illustrated. Nine of these 36 metal lines ML₀ distribute global bit lines GBL₀-GBLs to the left (in the negative direction along the Y-axis), and 27 of these 36 metal lines distribute global bit lines GBL₉-GBL₃₅ to the right (in the positive direction along the Y-axis). Thus, the required layout height of the metal lines ML₀ along the X-axis is only 27 metal lines high.

Similarly, a set of 36 metal lines ML₁ distribute the signals on global bit lines GBL₃₆-GBL₇₁ along the Y-axis, as illustrated. All 36 of these metal lines ML₁ distribute global bit lines GBL₃₆-GBL₇₁ to the right (in the positive direction along the Y-axis). Thus, the required layout height of the metal lines ML₁ along the X-axis is 36 metal lines high.

A set of 36 metal lines ML₂ distribute the signals on global bit lines GBL₇₂-GBL₁₀₇ along the Y-axis, as illustrated. Nine of these 36 metal lines ML₂ distribute global bit lines GBL₉₉-GBL₁₀₇ to the right (in the positive direction along the Y-axis), and 27 of these 36 metal lines distribute global bit lines GBL₇₂-GBL₉₈ to the left (in the negative direction along the Y-axis). Thus, the required layout height of the metal lines ML₂ along the X-axis is only 27 metal lines high.

Similarly, a set of 36 metal lines ML₃ distribute the signals on global bit lines GBL₁₀₈-GBL₁₄₃ along the Y-axis, as illustrated. All 36 of these metal lines ML₃ distribute global bit lines GBL₁₀₈-GBL₁₄₃ to the right (in the positive direction along the Y-axis). Thus, the required layout height of the metal lines ML₃ along the X-axis is 36 metal lines high.

A set of 36 metal lines ML₄ distribute the signals on global bit lines GBL₁₄₄-GBL₁₇₉ along the Y-axis in a pattern having a height of 36 metal lines along the X-axis, as illustrated.

A set of 36 metal lines ML₅ distribute the signals on global bit lines GBL₁₈₀-GBL₂₁₅ in a pattern having a height of 27 metal lines along the X-axis, as illustrated. In the illustrated embodiment, the set of metal lines ML₅ are located at the same latitude as the set of metal lines ML₀, such that the set of metal lines ML₅ do not add to the required height of the metal line structure along the X-axis.

A set of 36 metal lines ML₆ distribute the signals on global bit lines GBL₂₁₆-GBL₂₅₁ along the Y-axis in a pattern having a height of 36 metal lines along the X-axis, as illustrated.

A set of 36 metal lines ML₇ distribute the signals on global bit lines GBL₂₅₂-GBL₂₈₇ in a pattern having a height of 27 metal lines along the X-axis, as illustrated. In the illustrated embodiment, the set of metal lines ML₇ are located at the same latitude as the set of metal lines ML₂, such that the set of metal lines ML₇ do not add to the required height of the metal line structure along the X-axis.

The configuration of FIG. 13 requires a total of 27+27+36+36+36+36, or 198 horizontal metal line tracks, each extending in parallel with the Y-axis. Note that sufficient area for these 198 horizontal metal line tracks is provided by limiting the main word line configuration to one (metal) word line per eight sub-word lines as set forth above in connection with FIG. 7 (wherein the sub-word lines SWL_{0,0}-SWL_{7,0} are implemented using conductive polysilicon structures, rather than metal layer lines). The pitch between the metal main word lines (MWL) (along the X-axis) is equal to the height of 4 bit cells (along the X-axis), so the above-described configuration (of one metal main word line for each eight rows of bit cells) advantageously reduces the number of main word line tracks required within the unit cell by a factor of 2, thereby freeing up the necessary horizontal tracks for routing the global bit lines in the manner illustrated by FIG. 13.

The configuration of FIG. 13 requires 288×2 or 576 vertical metal lines, including 288 global bit lines GBL₀-GBL₂₈₇ and 288 metal lines that extend vertically along the X-axis from the metal line sets ML₀-ML₇ to the multiplexer section MUX_{(1,1)A}.

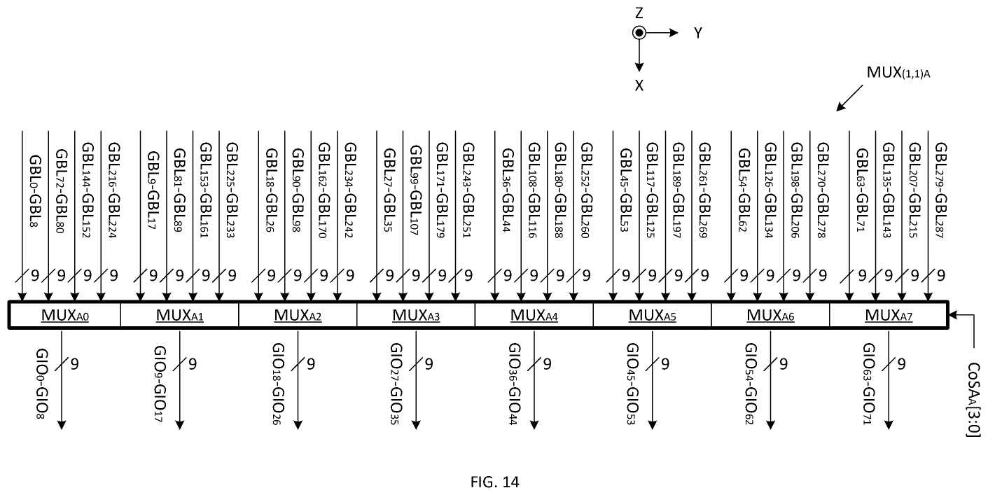

FIG. 14 is a diagram illustrating the manner in which the global bit lines GBL₀-GBL₂₈₇ are distributed to the multiplexer section MUX_{(1,1)A} in accordance with the present embodiment. Multiplexer section MUX_{(1,1)A} includes eight 4-to-1 multiplexers MUX_{A0}-MUX_{A7}, wherein each of these multiplexers is coupled to 9 global bit lines from each of the four sub-array columns CoSA₀-CoSA₃. For example, multiplexer MUX_{A0} is coupled to the nine global bit lines GBL₀-GBLs of sub-array column CoSA₀, the nine global bit lines GBL₇₂-GBL₈₀ of sub-array column CoSA₁, the nine global bit lines GBL₁₄₄-GBL₁₅₂ of sub-array column CoSA₂, and the nine global bit lines GBL₂₁₆-GBL₂₂₄ of sub-array column CoSA₃. This pattern is repeated for the remaining multiplexers MUX_{A1}-MUX_{A7}.

Multiplexers MUX_{A0}-MUX_{A7} are controlled by a pre-decoded sub-array column address CoSA_{A}[3:0], wherein the address values CoSA_{A}[0], CoSA_{A}[1], CoSA_{A}[2] and CoSA_{A}[3], when activated, connect the global bit lines from sub-array columns CoSA₀, CoSA₁, CoSA₂ and CoSA₃, respectively, to the global I/O lines GIO₀-GIO₇₁. For example, a sub-array column address CoSA_{A}[3:0] of ‘0001’ will cause multiplexers MUX_{A0}-MUX_{A7} to connect the global bit lines GBL₀-GBL₇₁ of sub-array column CoSA₀ to the global I/O lines GIO₀-GIO₇₁. The pre-decoded sub-array column address CoSA_{A}[3:0] is provided on the instruction bus INST₁.

It is understood that multiplexer MUX_{(1,1)B} operates in the same manner as multiplexer MUX_{(1,1)A}, although multiplexer MUX_{(1,1)B} operates in response to the signals on global bit lines GBL₂₈₈-GBL₅₇₅, and is controlled by a separate pre-decoded sub-array column address CoSA_{B}[3:0](wherein the address values CoSA_{B}[0], CoSA_{B}[1], CoSA_{B}[2] and CoSA_{B}[3], when activated, connect the global bit lines from sub-array columns CoSA₄, CoSA₅, CoSA₆ and CoSA₇, respectively, to the global I/O lines GIO₇₂-GIO₁₄₃). The pre-decoded sub-array column address CoSA_{B}[3:0] is provided on the instruction bus INST₁.

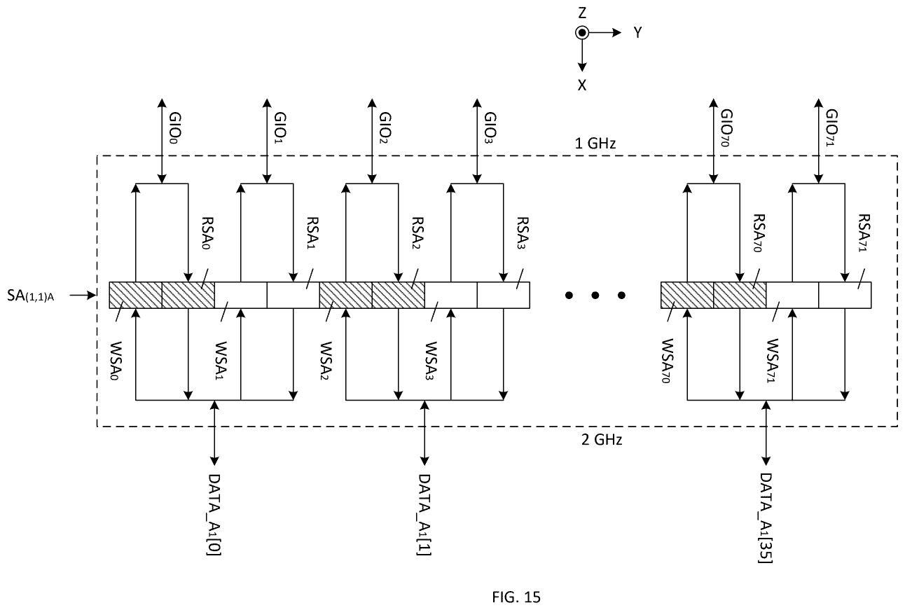

FIG. 15 is a diagram of secondary sense amplifier section SSA_{(1,1)A} in accordance with one embodiment of the present invention. It is understood that secondary sense amplifier section SSA_{(1,1)B} is configured and operates in the same manner as secondary sense amplifier circuit SSA_{(1,1)A}. Secondary sense amplifier circuit SSA_{(1,1)A} includes thirty-six identical ‘even’ read secondary sense amplifier circuits RSA₀, RSA₂, . . . RSA₇₀, which are coupled to receive read data values from ‘even’ global I/O lines GIO₀, GIO₂, . . . GIO₇₀, respectively, and thirty-six identical ‘odd’ read secondary sense amplifier circuits RSA₁, RSA₃, . . . RSA₇₁, which are coupled to receive read data values from ‘odd’ global I/O lines GIO₁, GIO₃, . . . GIO₇₁, respectively. Each consecutive pair of even/odd read secondary sense amplifier circuits is coupled to a corresponding single bit (TSV) of the data bus DATA_A₁[0:35]. For example, the even and odd read secondary sense amplifiers RSA₀ and RSA₁ coupled to global input output lines GIO₀ and GIO₁, respectively, are commonly coupled to a TSV (of set TSV_{1,1}) that carries the data bus signal DATA_A₁[0].

As described in more detail below, 72-bit read data on global I/O lines GIO₀-GIO₇₁ is transferred to secondary sense amplifier circuit SSA_{(1,1)A} at a data rate of 1 GHz, and 36-bit data is read from secondary sense amplifier circuit SSA_{(1,1)A} at a data rate of 2 GHz. This advantageously minimizes the required number of TSVs required to transfer read data from unit stack US₁ to ASIC processor block 105₁.

Secondary sense amplifier circuit SSA_{(1,1)A} also includes thirty-six identical ‘even’ write secondary sense amplifier circuits WSA₀, WSA₂, . . . WSA₇₀, which are coupled to provide write data values to ‘even’ global I/O lines GIO₀, GIO₂, . . . GIO₇₀, respectively, and thirty-six identical ‘odd’ write secondary sense amplifier circuits WSA₁, WSA₃, . . . WSA₇₁, which are coupled to provide write data values to ‘odd’ global I/O lines GIO₁, GIO₃, . . . GIO₇₁, respectively. Each consecutive pair of even/odd write secondary sense amplifier circuits is coupled to a corresponding single bit (TSV) of the data bus DATA_A₁[0:35]. For example, the even and odd write secondary sense amplifiers WSA₀ and WSA₁ coupled to global input output lines GIO₀ and GIO₁, respectively, are commonly coupled to a TSV (of set TSV_{1,1}) that carries the data bus signal DATA_A₁[0].

As described in more detail below, 36-bit write data on data bus DATA_A₁[0:35] is transferred to secondary sense amplifier section SSA_{(1,1)A} at a data rate of 2 GHz, and 72-bit write data is transferred from secondary sense amplifier section SSA_{(1,1)A} to global I/O lines GIO₀-GIO₇₁ at a data rate of 1 GHz. This advantageously minimizes the required number of TSVs required to transfer write data from ASIC processor block 105₁ to unit stack US₁.

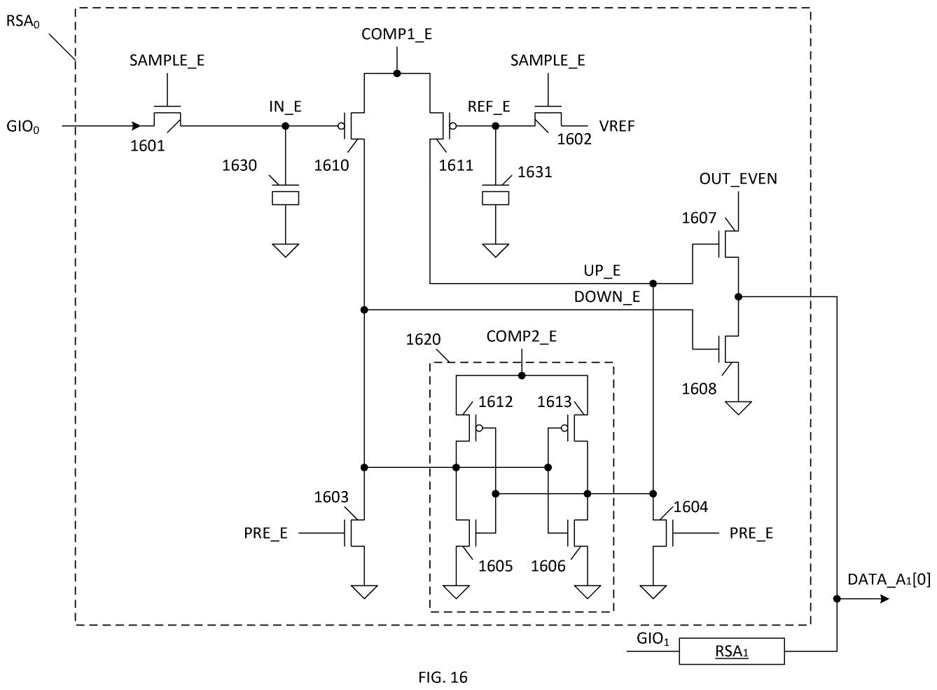

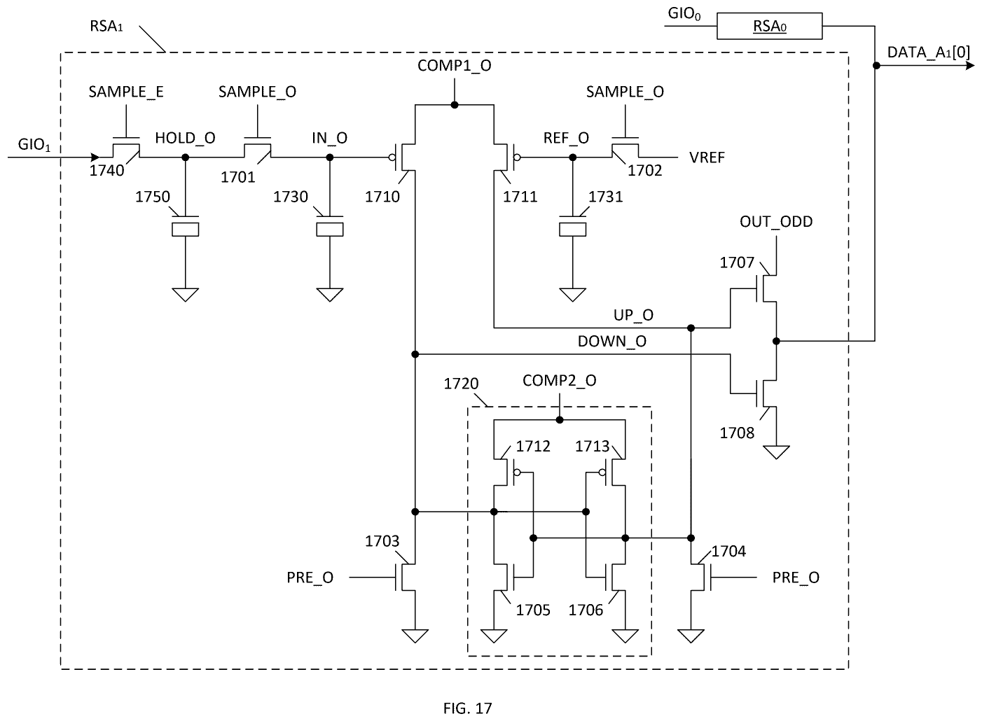

FIGS. 16 and 17 are circuit diagrams of ‘even’ read secondary sense amplifier circuit RSA₀ and ‘odd’ read secondary sense amplifier circuit RSA₁, respectively, in accordance with one embodiment of the present invention. Because each of these read secondary sense amplifier circuits operate in response to the signal received on a single global I/O line, these read secondary sense amplifiers are ‘single-ended sense amplifiers’ as described herein.

Even read secondary sense amplifier circuit RSA₀ includes n-channel transistors 1601-1608, p-channel transistors 1610-1613 and capacitors 1630-1631, which are connected as illustrated in FIG. 16. N-channel transistors 1605-1606 and p-channel transistors 1612-1613 are connected to form a sense amplifier latch 1620 that includes cross-coupled inverters. P-channel transistors 1610 and 1611 form a pre-amplifier differential pair.

As illustrated by FIG. 17, odd read secondary sense amplifier circuit RSA₁ includes n-channel transistors 1701-1708, p-channel transistors 1710-1713 and capacitors 1730-1731, which are connected in the same manner as n-channel transistors 1601-1608, p-channel transistors 1610-1613 and capacitors 1630-1631 of even read secondary sense amplifier circuit RSA₀. N-channel transistors 1705-1706 and p-channel transistors 1712-1713 are connected to form a sense amplifier latch 1720 that includes cross-coupled inverters. P-channel transistors 1710 and 1711 form a pre-amplifier differential pair. Odd read secondary sense amplifier circuit RSA₁ also includes an additional input stage that includes n-channel transistor 1740 and capacitor 1750.

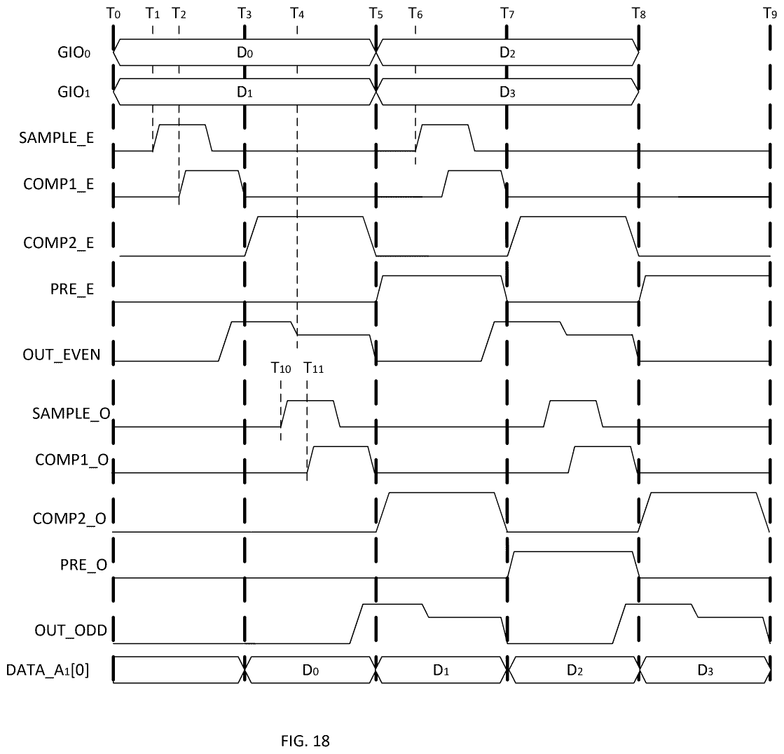

FIG. 18 is a waveform diagram illustrating the operation of ‘even’ read secondary sense amplifier circuit RSA₀ and ‘odd’ read secondary sense amplifier circuit RSA₁, in accordance with one embodiment of the present invention.

Although the present embodiment specifies particular voltages as the logic high voltages used to drive the various transistors of RSA₀ and RSA₁, it is understood that other logic high voltages can be specified in other embodiments. In general, it is desirable for the logic high voltage to be as low as possible to achieve power savings, while being high enough to enable the controlled circuits to meet speed and/or headroom requirements. In various embodiments, the logic high voltage has a value in the range of 250 mV to 1.1 Volts. It is noted that the use of specialized n-channel transistors fabricated in accordance with the MST process (described in commonly owned U.S. Pat. Nos. 10,109,342 and 10,107,854, which are hereby incorporated by reference in their entireties) allows the logic high voltage to be increased (e.g., up to 200 mV greater than the baseline Vdd supply voltage of 1.1 V), effectively overdriving n-channel transistors within RSA₀ and RSA₁.

In the embodiments described below, the SAMPLE_E, SAMPLE_O, PRE_O and PRE_E control signals have logic high voltages of about 250 mV, the COMP1_E, COMP1_O, COMP2_E and COMP2_O control signals have logic high voltages of about 1.1 V to 1.3 V, and the OUT_ODD and OUT_EVEN control signals have logic high voltages of 250 mV to 350 mV.

At time T0, data values D₀ and D₁ are read out of one of the sub-array columns CoSA₀-CoSA₃, and onto global I/O lines GIO₀ and GIO₁, respectively, in the manner described above.

At time T1, the read sample signal SAMPLE_E, which is applied to the gates of n-channel transistors 1601 and 1602 in RSA₀ and to the gate of n-channel transistor 1740 in RSA₁, is activated from a logic low voltage (0V) to a logic high voltage (250 mV). Under these conditions, transistors 1601 and 1740 turn on, such that the read data values on global I/O lines GIO₀ and GIO₁ (i.e., D₀ and D₁, respectively) are applied to (and are stored by) capacitors 1630 and 1750, respectively, as the input signals IN_E and HOLD_O, respectively. In the embodiments described herein, the data values transmitted on the global I/O lines GIO₀ and GIO₁, exhibit a logic low voltage of ground (0V) and a logic high voltage of 250 mV. Capacitor 1750 is large enough to ensure there is no noticeable charge leakage from this device during the time that the sampled data value must be stored as the HOLD_O value (e.g., a few ns).

Also under these conditions, transistor 1602 turns on, such that the reference voltage VREF is applied to (and is stored by) capacitor 1631 as the reference signal REF_E. In the embodiments described herein, the reference VREF (and therefore the reference signal REF_E) has a voltage a little less than half of the logic high voltage on the global I/O lines (e.g., a little less than 250 mV/2, or about 110 mV in one embodiment). Capacitors 1601 and 1602 are matched, and are large enough that there is no noticeable (e.g., 5% or less) differential signal coupling mismatch to transistors 1610 and 1611.

The input signal IN_E stored by capacitor 1630 is applied to the gate of p-channel transistor 1610 and the input signal REF_E stored by capacitor 1631 is applied to the gate of p-channel transistor 1611, as illustrated. In the described embodiments, transistors 1610-1611 are identical, transistors 1601-1602 are identical, and capacitors 1630-1631 are identical, thereby balancing the inputs of read secondary sense amplifier RSA₀.

At time T2, the comparator enable signal COMP1_E is activated from a logic low voltage (0V) to a logic high voltage of about 1.1 to 1.3 Volts within read secondary sense amplifier circuit RSA₀. Under these conditions, differential UP_E and DOWN_E voltages are developed on the drains of p-channel transistors 1610 and 1611, respectively, wherein the DOWN_E voltage developed on the drain of transistor 1610 is representative of the voltage of the input signal IN_E, and the UP_E voltage on the drain of transistor 1611 is representative of the reference voltage REF_E applied to the gate of transistor 1611. In the described embodiment, the reference voltage REF_E is equal to 110 mV, which is slightly less than half of the logic high voltage of input signal IN_E (250 mV).

If the voltage of the input signal IN_E is less than the reference voltage REF_E (i.e., if IN_E is =0V), then the voltage of the UP_E signal will be less than the voltage of the DOWN_E signal. Conversely, if the voltage of the input signal IN_E is greater than the reference voltage REF_E (i.e., if IN_E is =250 mV), then the voltage of the UP_E signal will be greater than the voltage of the DOWN_E signal.

At time T2, the comparator enable signal COMP1_E is deactivated from the logic high voltage to a logic low voltage (0V), as illustrated. Also at time T2, the comparator enable signal COMP2_E is activated from a logic low voltage (0V) to a logic high voltage of about 1.1 V to 1.3 V, thereby enabling sense amplifier latch 1620.

Under these conditions, sense amplifier latch 1620 amplifies the difference between the differential UP_E and DOWN_E voltages, such that the sense amplifier latch 1620 stores a data value representative of the voltage received on global I/O line GIO₀. For example, if the UP_E voltage is less than the DOWN_E voltage, then latch 1620 will pull the DOWN_E voltage up to the voltage of the COMP2_E signal (350 mV), and will pull the UP_E voltage to ground. Conversely, if the UP_E voltage is greater than the DOWN_E voltage, then latch 1620 will pull the DOWN_E voltage down to ground, and will pull the UP_E voltage up to the voltage of the COMP2_E signal (e.g., 1.1V to 1.3V).

The UP_E and DOWN_E voltages are applied to the gates of n-channel transistors 1607 and 1608, respectively. As described above, when the sense amplifier latch 1620 is enabled, either the UP_E voltage or the DOWN_E voltage will be pulled up to 1.1 to 1.3 V, thereby turning on the corresponding n-channel transistor 1607 or 1608, respectively.

Just prior to time T2, the output control signal OUT_EVEN is driven from ground (0V) to the slightly boosted voltage of 350 mV. Thus, if the UP_E voltage is pulled up to 350 mV, the corresponding n-channel transistor 1607 is turned on, and the DATA_A₁[0] output signal is initially pulled up to 350 mV at the output of read secondary sense amplifier RSA₀. Shortly after the sense amplifier latch 1620 is enabled (e.g., at time T4), the output control signal OUT_EVEN is reduced from 350 mV to 250 mV, such that the DATA_A₁[0] output signal is pulled up to 250 mV at the output of read secondary sense amplifier RSA₀. The voltage at the output of read secondary sense amplifier RSA₀ is initially boosted based on the significant capacitance of the DATA_A₁[0] signal line structure (see, e.g., FIG. 4). The duration of this voltage boost is controlled such that the voltage received at the processor block 105₁ quickly reaches, but does not exceed, 250 mV.

Maintaining the OUT_EVEN signal at 0V from time T0 until just prior to time T3 advantageously minimizes leakage current in n-channel transistor 1607 and reduces the power requirements of read secondary sense amplifier RSA₀. However, it is understood that in other embodiments the OUT_EVEN voltage can be maintained at a voltage of 250 mV (or 350 mV) from time T0 to time T3.

If the DOWN_E voltage is pulled up to the logic high voltage of 1.1 to 1.3V when the sense amplifier latch 1620 is enabled at time T2, the corresponding n-channel transistor 1608 is turned on, and the DATA_A₁[0] output signal is pulled down to ground (0V) at the output of read secondary sense amplifier RSA₀.

At time T5, the COMP2_E signal is deactivated from the logic high voltage (1.1 to 1.3V) to a logic low voltage (0V) as illustrated, thereby disabling the sense amplifier latch 1620, such that the secondary sense amplifier SSA_{EVEN} no longer actively drives the DATA_A₁[0] signal. In the illustrated embodiment, the duration from time T2 to T5 (i.e., the time that the output of the read secondary sense amplifier RSA₀ is active to drive the data value D₀ onto DATA_A₁[0]) is 0.5 ns, corresponding with an output data rate of 2 GHz.

Pre-charge operations, which prepare the read secondary sense amplifier RSA₀ to receive the next data value on global I/O line GIO₀, are then performed as follows.

Shortly after time T5, the PRE_E signal is activated from a logic low state (0V) to a logic high state (250 mV), thereby turning on n-channel pre-charge transistors 1603 and 1604. Under these conditions, the voltages of the UP_E and DOWN_E signals are pulled down to ground, thereby pre-charging these signals. The PRE_E signal is de-activated low (0V) to turn off transistors 1603-1604 prior to the next time the sense amplifier latch 1620 is enabled (e.g., at time T7 in FIG. 18).

The above-described signal pattern is repeated for successive accesses within read secondary sense amplifier RSA₀. Thus, as illustrated by FIG. 18, the next read access from read secondary sense amplifier RSA₀ is initiated at time T6 (with the activation of the SAMPLE_E signal), and continues with the next read data value D₂ being read out as the DATA_A₁[0] signal from time T7 to time T8.

Turning now to ‘odd’ read secondary sense amplifier RSA₁ (FIG. 17) at time T10, the sample signal SAMPLE_O applied to the gates of n-channel transistors 1701 and 1702 is activated from a logic low voltage (0V) to a logic high voltage (250 mV). Under this condition, transistor 1701 turns on, such that the data value previously received on global I/O line GIO₁ and stored by capacitor 1750 as the HOLD_O voltage is applied to (and stored by) capacitor 1730 as the input signal IN_O.

Also under these conditions, transistor 1702 turns on, such that the reference voltage VREF is applied to (and is stored by) capacitor 1731 as the reference signal REF_O. As described above, the reference voltage VREF (and therefore the reference signal REF_O) has a voltage of about 110 mV in the described embodiments.

At time T11, the comparator enable signal COMP1_O is activated from a logic low voltage (0V) to a logic high voltage (1.1 to 1.3V) within odd read secondary sense amplifier circuit RSA₁. Under these conditions, differential UP_O and DOWN_O voltages are developed on the drains of p-channel transistors 1710 and 1711, respectively, in the same manner the differential UP_E and DOWN_E voltages are developed on the drains of p-channel transistors 1610 and 1611 of the even read secondary sense amplifier RSA₀.

At time T5, the comparator enable signal COMP1_O is deactivated from a logic high voltage (1.1 to 1.3V) to a logic low voltage (0V), as illustrated. Also at time T5, the comparator enable signal COMP2_O is activated from a logic low voltage (0V) to a boosted logic high voltage (1.1 to 1.3V), thereby enabling sense amplifier latch 1720. Just prior to time T5, the output control signal OUT_ODD is driven from ground (0V) to the slightly boosted voltage of 350 mV.

Under these conditions, sense amplifier latch 1720 operates in the same manner described above in connection with sense amplifier latch 1620, wherein sense amplifier latch 1720 amplifies the difference between the differential UP_O and DOWN_O voltages, such that the sense amplifier latch 1720 stores a data value D₁ representative of the voltage received on global I/O line GIO₁.

The UP_O and DOWN_O voltages are applied to the gates of n-channel transistors 1707 and 1708, respectively. When the sense amplifier latch 1720 is enabled, either the UP_O voltage or the DOWN_O voltage will be pulled up to 1.1 to 1.3V, thereby turning on the corresponding n-channel transistor 1707 or 1708, respectively. The OUT_ODD output control signal of read secondary sense amplifier RSA₁ is controlled in the same manner described above for the OUT_EVEN output control signal of read secondary sense amplifier RSA₀. As a result, the read secondary sense amplifier RSA₁ drives the data value D₁ received on global I/O line GIO₁ onto the DATA_A₁[0] signal line starting from time T5.

At time T7, the COMP2_O signal is deactivated from the boosted logic high state (1.1 to 1.3V) to a logic low state (0V) as illustrated, thereby disabling the sense amplifier latch 1720, such that the read secondary sense amplifier RSA₁ no longer actively drives the DATA_A₁[0] signal. In the illustrated embodiment, the duration from time T5 to T7 (i.e., the time that the output of the read secondary sense amplifier RSA₁ is active to drive the data value D₁ onto DATA_A₁[0]) is 0.5 ns, corresponding with an output data rate of 2 GHz.

Pre-charge operations within read secondary sense amplifier RSA₁ are the same as the above-described pre-charge operations within read secondary sense amplifier RSA₀. In fact, it is noted that the signals used to operate the ‘even’ read secondary sense amplifier RSA₀ between time T0 and time T8 are identical to the signals used to operate the ‘odd’ secondary sense amplifier RSA₁ between time T3 and time T9.

It is further noted that the above-described operations are successively repeated in FIG. 18, wherein the next read data value D₂ received on global I/O line GIO₀ is read out onto the DATA_A₁[0] signal line during the time period from T7 to time T8, and the next data value D₃ received on global I/O line GIO₁ is read out onto the DATA_A₁[0] signal line during the time period from T8 to time T9

Although FIGS. 16-18 describe the transfer of data from the general I/O lines GIO₀ and GIO₁ to the corresponding DATA_A₁[0] signal line, it is understood that data is transferred from all of the general I/O lines GIO₀-GIO₇₁ to the corresponding DATA_A₁[0:35] signal lines in parallel. In this manner, 36-bit read data is provided on the DATA_A₁[0:35] TSVs at a frequency of 2 GHz. It is further understood that if the DATA_B₁ channel is also accessed, data is also transferred from all of the general I/O lines GIO₇₂-GIO₁₄₃ to the corresponding DATA_B₁[0:35] TSVs in parallel (such that 36-bit read data is also provided on DATA_B₁[0:35] signal lines at a frequency of 2 GHz).

Multiplexing the 72-bit data received on the global I/O lines GIO₀-GIO₇₁ (and/or GIO₇₂-GIO₁₄₃) at 1 GHz to 36-bit data on the TSVs associated with data bus DATA_A₁[0:71](and/or DATA_B₁[0:71]) at 2 GHz advantageously reduces the number of TSVs required to implement unit stack US₁, while maintaining a relatively low data transfer frequency on these TSVs. Moreover, operating data buses DATA_A₁[0:71] and DATA_B₁[0:71] at a signal swing of 250 mV advantageously minimizes the power requirements of data transmission on the corresponding TSVs.

Although the read operations have been described in connection with specific control voltages, it is understood that control voltages having other voltage levels can be used in other embodiments, corresponding with the particular characteristics of the unit cell UC_{1,1} (and unit stack US₁). For example, although the logic high voltage on the global bit lines are specified as 250 mV, and the reference voltage VREF has been specified as 110 mV in the embodiments described above, it is understood that in other embodiments, these voltages may be scaled upward or downward. For example, in one embodiment (which implements transistors fabricated in accordance with MST process technology), the logic high voltage on the global bit lines may be specified at 110 mV, and the reference voltage VREF may be specified at 45 mV.

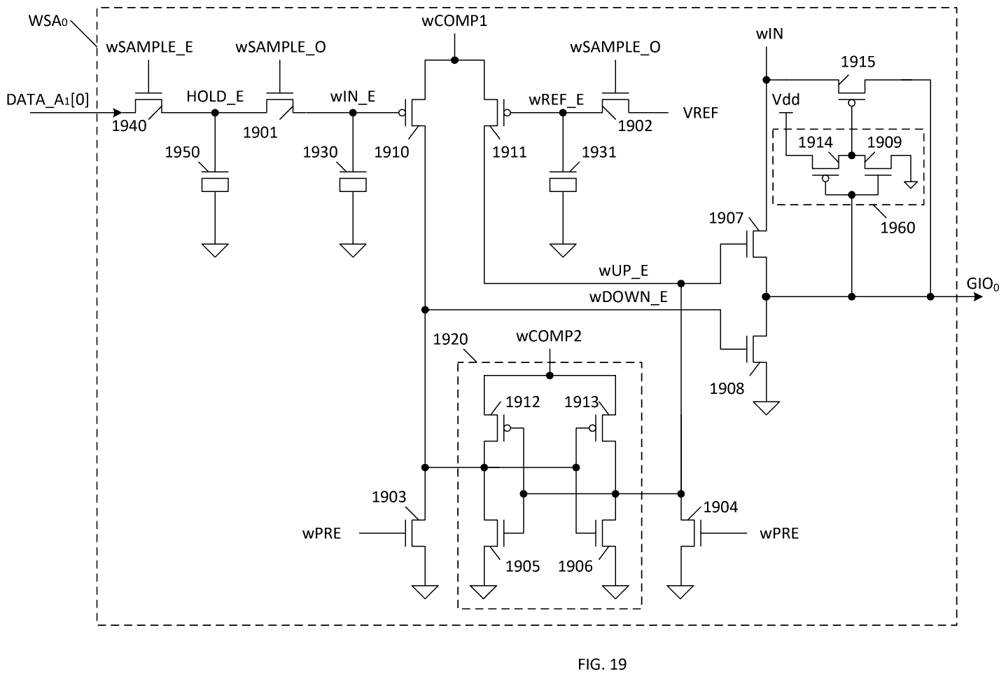

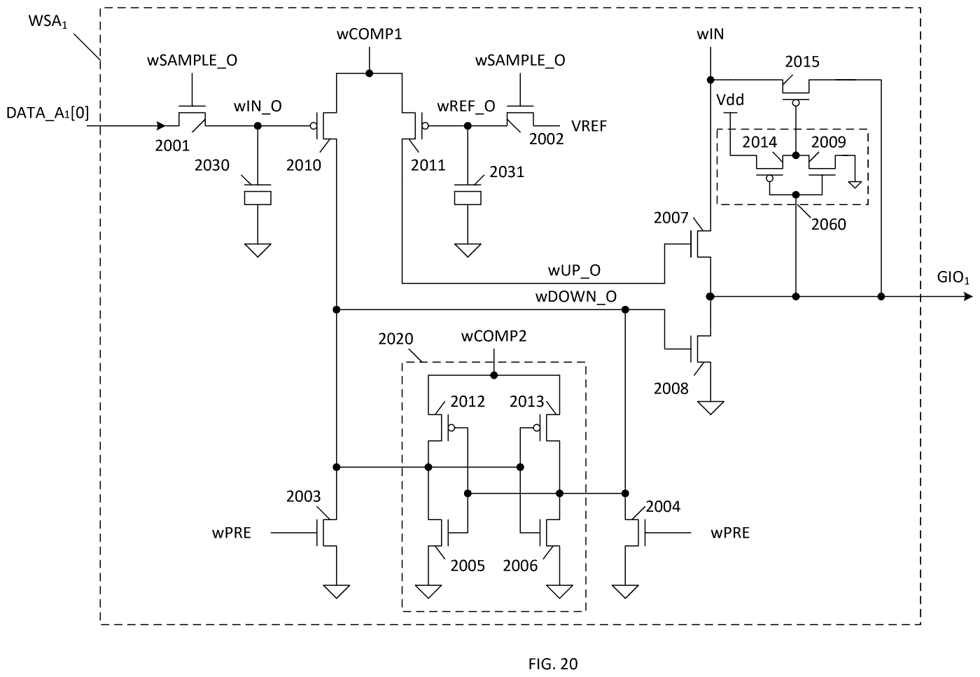

FIGS. 19 and 20 are circuit diagrams of ‘even’ write secondary sense amplifier circuit WSA₀ and ‘odd’ write secondary sense amplifier circuit WSA₁, respectively, in accordance with one embodiment of the present invention. Because each of these write secondary sense amplifier circuits operate in response to the signal received on a single data line, these write secondary sense amplifiers are ‘single-ended sense amplifiers’ as described herein.

Write secondary sense amplifier circuit WSA₀ includes n-channel transistors 1901-1909 and 1940, p-channel transistors 1910-1915, and capacitors 1930-1931 and 1950, which are connected as illustrated by FIG. 19. N-channel transistors 1905-1906 and p-channel transistors 1912-1913 are connected to form a sense amplifier latch 1920 that includes cross-coupled inverters. P-channel transistors 1910 and 1911 form a pre-amplifier differential pair. N-channel transistor 1940 and capacitor 1950 form an additional input stage for ‘even’ data values to be provided to general I/O signal line GIO₀. N-channel transistor 1909 and P-channel transistor 1914 are very small devices that form an inverter 1960, which along with p-channel transistor 1915, operate as a keeper circuit in a manner described in more detail below.

As illustrated by FIG. 20, ‘odd’ write secondary sense amplifier circuit WSA₁ includes n-channel transistors 2001-2009, p-channel transistors 2010-2015, and capacitors 2030-2031, which are connected in the same manner as n-channel transistors 1901-1909, p-channel transistors 1910-1915, and capacitors 1930-1931 of ‘even’ write secondary sense amplifier circuit WSA₀. Thus, n-channel transistors 2005-2006 and p-channel transistors 2012-2013 are connected to form a sense amplifier latch 2020 that includes cross-coupled inverters. P-channel transistors 2010 and 2011 form a pre-amplifier differential pair. P-channel transistor 2014 and n-channel transistor 2009 form an inverter 2060, which along with p-channel transistor 2015, operate as a keeper circuit in a manner described in more detail below.

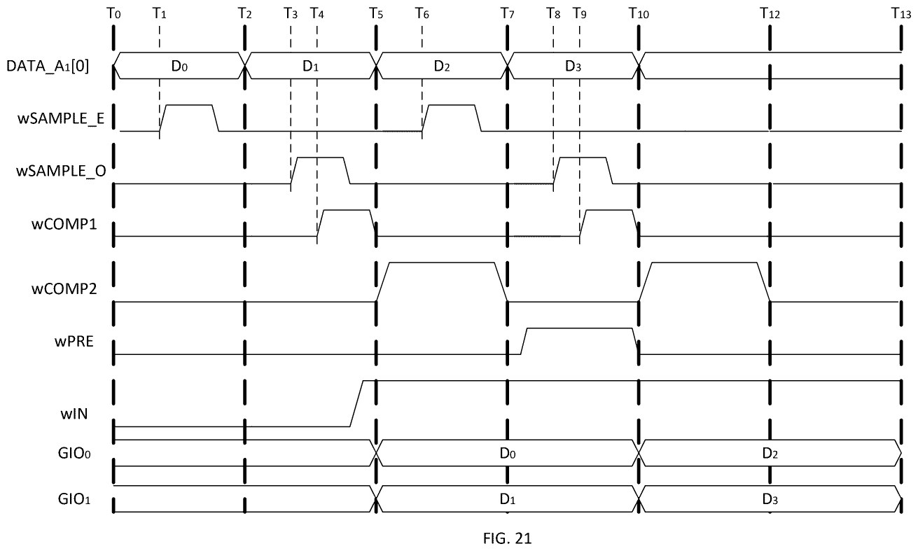

FIG. 21 is a waveform diagram illustrating the operation of ‘even’ write secondary sense amplifier circuit WSA₀ and ‘odd’ write secondary sense amplifier circuit WSA₁, in accordance with one embodiment of the present invention.

At time T0, even write data value D₀ is provided by processor block 105₁ on the data bus DATA_A₁ as the data signal DATA_A₁[0].

At time T1, the write sample signal wSAMPLE_E, which is applied to the gate of n-channel transistor 1940 in WSA₀, is activated from a logic low voltage (0V) to a logic high voltage (250 mV or higher). Under these conditions, transistor 1940 turns on, such that the write data value D₀ on DATA_A₁[0] is applied to (and is stored by) capacitor 1950, as the input signal HOLD_E. In the embodiments described herein, the data values transmitted on the data bus DATA_A₁ exhibit a logic low voltage of ground (0V) and a logic high voltage of about 250 mV. Capacitor 1950 is large enough to ensure there is no noticeable charge leakage from this device during the time that the sampled data value must be stored as the HOLD_E value (e.g., a few ns).

At time T2, odd write data value D₁ is provided by processor block 105₁ on the data bus DATA_A₁ as the data signal DATA_A₁[0].

At time T3, the write sample signal wSAMPLE_O, which is applied to the gates of n-channel transistors 1901-1902 in WSA₀ and to the gates of n-channel transistors 2001-2002 in WSA₁, is activated from a logic low voltage (0V) to a logic high voltage (250 mV or higher). Under these conditions, transistor 1901 withing WSA₀ turns on, thereby transferring the data value D₀ stored in capacitor 1950 as the HOLD_E signal is applied to (and stored by) capacitor 1930 as the write input signal wIN_E. Also under these conditions, transistor 2001 within WSA₁ turns on, such that the data value D₁ on DATA_A₁[0] is applied to (and is stored by) capacitor 2030, as the write input signal wIN_O.

Also under these conditions, transistors 1902 and 2002 turn on, such that the reference voltage VREF is applied to (and is stored by) capacitors 1931 and 2031 as the reference signals wREF_E and wREF_O, respectively. In the embodiments described herein, the reference VREF (and therefore the reference signals wREF_E and wREF_O) has a voltage a little less than half of the logic high voltage on the DATA_A₁ bus (e.g., a little less than 250 mV/2, or about 110 mV in one embodiment).

Within WSA₀, the input signal wIN_E stored by capacitor 1930 is applied to the gate of p-channel transistor 1910 and the input signal wREF_E stored by capacitor 1931 is applied to the gate of p-channel transistor 1911, as illustrated by FIG. 19. Similarly, within WSA₁, the input signal wIN_O stored by capacitor 2030 is applied to the gate of p-channel transistor 2010 and the input signal wREF_O stored by capacitor 2031 is applied to the gate of p-channel transistor 2011, as illustrated by FIG. 20.

In the described embodiments, transistors 1910-1911 and 2010-2011 are identical, transistors 1901-1902 and 2001-2002 are identical, and capacitors 1930-1931 and 2030-2031 are identical are identical, thereby balancing the inputs of write secondary sense amplifiers WSA₀-WSA₁.

At time T4, the write comparator enable signal wCOMP1 is activated from a logic low voltage (0V) to a logic high voltage (e.g., 1.1 to 1.3V) within write secondary sense amplifier circuits WSA₀ and WSA₁. Under these conditions, differential wDOWN_E and wUP_E voltages are developed on the drains of p-channel transistors 1910 and 1911, respectively, within WSA₀, and differential wDOWN_O and wUP_O voltages are developed on the drains of p-channel transistors 2010 and 2011, respectively, within WSA₁.

If the voltage of the input signal wIN_E is less than the reference voltage wREF_E (i.e., if wIN_E is =0V), then the voltage of the wDOWN_E signal will be greater than the voltage of the wUP_E signal. Conversely, if the voltage of the input signal wIN_E is greater than the reference voltage wREF_E (i.e., if wIN_E is =250 mV), then the voltage of the wDOWN_E signal will be less than the voltage of the wUP_E signal. The wUP_O and wDOWN_O signals are generated in a similar manner within WSA₁ in response to the wIN_O and wREF_O signals.

At time T5, the comparator enable signal wCOMP1 is deactivated from the logic high voltage to a logic low voltage (0V), as illustrated. Also at time T5, the comparator enable signal wCOMP2 is activated from a logic low voltage (0V) to a logic high voltage (e.g., 1.1 to 1.3V), thereby enabling sense amplifier latches 1920 and 2020 within WSA₀ and WSA₁, respectively.

Under these conditions, sense amplifier latch 1920 amplifies the difference between the differential wUP_E and wDOWN_E voltages, such that the sense amplifier latch 1920 stores a data value representative of the data value D₀ received on data bus DATA_A₁. For example, if the wUP_E voltage is less than the wDOWN_E voltage, then latch 1920 will pull the wUP_E voltage down to ground, and will pull the wDOWN_E voltage up to the voltage of the wCOMP2 signal (1.1 to 1.3V). Conversely, if the wUP_E voltage is greater than the wDOWN_E voltage, then latch 1920 will pull the wDOWN_E voltage down to ground, and will pull the wUP_E voltage up to the voltage of the wCOMP2 signal (1.1 to 1.3V). The wUP_O and wDOWN_O signals are generated in a similar manner within WSA₁ in response to the wUP_O and wDOWN_O signals.

The wUP_E and wDOWN_E voltages are applied to the gates of n-channel transistors 1907 and 1908, respectively. As described above, when the sense amplifier latch 1920 is enabled, either the wUP_E voltage or the wDOWN_E voltage will be pulled up to 1.1 to 1.3V, thereby turning on the corresponding n-channel transistor 1907 or 1908, respectively. The wUP_O and wDOWN_O signals control the corresponding n-channel transistors 2007 and 2008, respectively, in a similar manner within WSA₁.

Just prior to time T5, the write input control signal wIN is driven from ground (0V) to the slightly boosted voltage of 350 mV. Thus, if the wDOWN_E voltage is pulled up to 1.1 to 1.3V, the corresponding n-channel transistor 1908 is turned on, thereby coupling the global I/O line GIO₀ to ground. In this manner, the data value D₀ (D₀=0) is driven onto the global I/O line GIO₀ starting at time T5. Note that the ground voltage applied to GIO₀ turns on p-channel transistor 1914 within inverter 1960, such that the Vdd supply voltage (1.1 to 1.3 V) is applied to the gate of p-channel transistor 1915, thereby turning off this transistor 1915. As a result, the keeper circuit formed by inverter 1960 and p-channel transistor is turned off when a logic low write data value is driven onto global I/O line GIO₀.

Conversely, if the wUP_E voltage is pulled up to 1.1 to 1.3V, the corresponding transistor 1907 is turned on, thereby coupling the global I/O line GIO₀ to the wIN voltage of 350 mV. In this manner, the data value D₀ (D₀=1) is driven onto the global I/O line GIO₀ starting at time T5. Note that the logic high voltage (350 mV) applied to GIO₀ turns on p-channel transistor 1909 within inverter 1960, such that the ground voltage is applied to the gate of p-channel transistor 1915, thereby turning on this transistor 1915. The turned on p-channel transistor 1915 keeps the voltage on the global I/O line GIO₀ at the wIN voltage of 350 mV. In this manner, the keeper circuit formed by inverter 1960 and p-channel transistor is turned on when a logic high write data value is driven onto global I/O line GIO₀.

Within WSA₁, n-channel transistors 2007-2008, inverter 2060 and p-channel transistor 2015 operate in the above described manner to drive the data value D₁ onto global I/O line GIO₁, starting at time T5.

At time T7, the wCOMP2 signal is deactivated (to ground), effectively disabling sense amplifier latches 1920 and 2020 within WSA₀ and WSA₁, respectively. Shortly after time T7, the wPRE signal is activated, thereby pre-charging the sense amplifier latches 1920 and 2020 to ground, ahead of the next write operation. However, the data values D₀ and D₁ remain on the respective global I/O lines GIO₀ and GIO₁ until time T10. More specifically, global I/O lines GIO₀ and GIO₁ that were actively pulled to ground between time T5 and T7 will remain at ground until time T10, because there is no mechanism within WSA₀ or WSA₁ to pull the global I/O lines GIO₀ and GIO₁ up from ground (and the capacitances associated with the global I/O lines GIO₀ and GIO₁ and the global bit lines GBL inhibit any sudden voltage changes on these global I/O lines).

Global I/O lines GIO₀ and GIO₁ that were actively pulled to the positive wIN voltage (350 mV) between time T5 and T7 will be held at this positive wIN voltage by the corresponding keeper circuit until time T10. For example, if the global I/O line GIO₀ is actively pulled up to the wIN voltage (350 mV) between times T5 and T7, then the n-channel transistor 1909 of inverter 1960 and the p-channel transistor 1915 are turned on in the manner described above. When the n-channel transistor 1907 is turned off (in response to the wUP_E signal being pre-charged to ground shortly after time T7), the global I/O line GIO₀ continues to be held to the wIN voltage (350 mV) through turned on p-channel transistor 1915. Note that the small transistors (1909 and 1914) used to implement inverter 1960 allows this inverter 1960 to be easily overdriven in response to the next received write data value.

In the illustrated embodiment, the period between time T0 and time T2 (i.e., the period of the data value D₀ driven onto DATA_A1[0]) is 0.5 ns, corresponding with an input data rate of 2 GHz on data bus DATA_A₁, and the period between time T5 and time T10 is 1 ns, corresponding with an input data rate of 1 GHz on global input/output lines GIO₀ and GIO₁.

At time T5, the above described process begins again, wherein the next write data value D₂ provided on data bus line DATA_A₁[0] at time T5 is stored in capacitor 1950 of WSA₀ in response to the activated wSAMPLE_E signal at time T6, and wherein the next write data value D₃ provided on data bus line DATA_A₁[0] at time T7 is stored in capacitor 2030 of WSA₁ in response to the activated wSAMPLE_O signal at time T8, and wherein the write data values D₂ and D₃ are driven onto global I/O lines GIO₀ and GIO₁, respectively, from time T10 to time T13.

Although FIGS. 19-21 describe the transfer of write input data from the DATA_A₁[0] signal line (TSV) to the corresponding general I/O lines GIO₀ and GIO₁, it is understood that write input data is transferred from all of the DATA_A₁[0:35] signal lines to the corresponding general I/O lines GIO₀-GIO₇₁ in parallel. In this manner, 36-bit write data is provided on the DATA_A₁[0:35] signal lines at a frequency of 2 GHz and 72-bit write data is provided on general I/O lines GIO₀-GIO₇₁ at a frequency of 1 GHz. It is further understood that if a write operation is also performed on the DATA_B₁ channel, write input data is also transferred from the DATA_B₁[0:35] signal lines to the corresponding general I/O lines GIO₇₂-GIO₁₄₃ in parallel (such that 36-bit write data is provided on the DATA_B₁[0:35] signal lines at a frequency of 2 GHz, and 72-bit write input data is provided on general I/O lines GIO₇₂-GIO₁₄₃ at a frequency of 1 GHz).

Demultiplexing the 36-bit write data values received on DATA_A₁[0:71] signal lines (and/or the DATA_B₁[0:71] signal lines) at 2 GHz onto the 72-bit global I/O lines GIO₀-GIO₇₁ (and/or GIO₇₂-GIO₁₄₃) at 1 GHz advantageously reduces the number of TSVs required to implement unit stack US₁, while maintaining a relatively low data transfer frequency on these TSVs.

The above-described control signals used to operate the read secondary sense amplifiers and the write secondary sense amplifiers are generated by secondary sense amplifier driver circuit SSAD_{1,1} (shown in FIG. 6). The secondary sense amplifier driver circuit SSAD_{1,1} generates the control signals required to control the read secondary sense amplifiers (i.e., SAMPLE_E, SAMPLE_O, COMP1_E, COMP1_O, COMP2_E, COMP2_E, PRE_E, PRE_O, OUT_EVEN and OUT_ODD) in response to receiving signals on the instruction bus INST₁ that specify a read access to unit cell UC_{1,1} (e.g., RW=0, UC[3:0]=0001, CLK). Similarly, the secondary sense amplifier driver circuit SSAD_{1,1} generates the control signals required to control the write secondary sense amplifiers (i.e., wSAMPLE_E, wSAMPLE_O, wCOMP1, wCOMP2, wPRE and wIN) in response to receiving signals on the instruction bus INST₁ that specify a write access to unit cell UC_{1,1} (e.g., RW=1, UC[3:0]=0001, CLK). As described above in connection with FIG. 6, the secondary sense amplifier driver circuit SSAD_{1,1} is centrally located within the secondary sense amplifier circuit SSA_{1,1} in one embodiment. In one embodiment, secondary sense amplifier driver circuit SSAD_{1,1} separately controls the secondary sense amplifier sections SSA_{(1,1)A} and SSA_{(1,1)B}, wherein the secondary sense amplifier section SSA_{(1,1)A} is only activated if there is an access to one of the sub-array columns CoSA₀-CoSA₃, and the secondary sense amplifier section SSA_{(1,1)B} is only activated if there is an access to one of the sub-array columns CoSA₄-CoSA₇.

### Addressing/Data Path

The signals included on the instruction bus INST₁ used to access the unit cells UC_{1,1}, UC_{2,1}, UC_{3,1} and UC_{4,1} of unit stack US₁ will now be described in more detail, along with the access patterns that can be implemented within the unit stack US₁. It is understood that any combination (including all) of the unit stacks US₁-US₂₀₄₈ of MTDRAM system 100 may be simultaneously and independently accessed in parallel using the addressing implementation described below, advantageously providing high data bandwidth within MDRAM system 100.

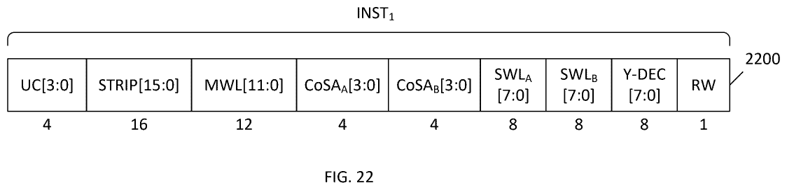

FIG. 22 is a block diagram representation illustrating the format of an instruction 2200 used to access the unit stack US₁ in accordance with one embodiment of the present invention. Unit stack access instruction 2200 is routed to each of the unit cells UC_{1,1}, UC_{2,1}, UC_{3,1} and UC_{4,1} on dedicated instruction bus INST₁, as illustrated by FIG. 4.

Instruction 2200 includes a unit cell address field UC[3:0], a strip address field STRIP[15:0] which is shared by data channels DATA_A₁ and DATA_B₁, a main word line address field MWL[11:0] which is shared by data channels DATA_A₁ and DATA_B₁, a sub-array column address field CoSA_{A}[3:0] associated with data channel DATA_A₁, a sub-array column address field CoSA_{B}[3:0] associated with data channel DATA_B₁, a sub-word line address field SWL_{A}[7:0] associated with data channel DATA_A₁, a sub-word line address field SWL_{B}[7:0] associated with data channel DATA_B₁, a Y-column address field Y-DEC[7:0] which is shared by data channels DATA_A₁ and DATA_B₁, and a read/write signal field RW which is shared by data channels DATA_A₁ and DATA_B₁.

The unit cell address field UC[3:0] specifies the unit cell (of unit cells UC_{1,1}, UC_{2,1}, UC_{3,1} and UC_{4,1}) to be accessed in response to the instruction. The signals of unit cell address field UC[3:0] are fully pre-decoded, such that the signals UC[3], UC[2], UC[1] and UC[0], when activated, specify accesses to unit cells UC_{4,1}, UC_{3,1}, UC_{2,1} and UC_{1,1}, respectively. The unit cell address UC[3:0] may specify up to one unit cell for an access. For example, an access to unit cell UC_{1,1} is specified by a UC[3:0] value of ‘0001’ and an access to unit cell UC_{3,1} is specified by a UC[3:0] value of ‘0100’.

The strip address field STRIP[15:0] specifies which one of the sixteen strips of the selected unit cell is accessed. In the described embodiments, the strip address value STRIP[15:0] specifies a single strip. When activated, the pre-decoded strip address bits STRIP[15] to STRIP[0] of instruction 2200 specify strips S_{(x,1)15} to S_{(x,1)0}, respectively, within the addressed unit cell UC_{x,1} (wherein x=1 to 4). Thus, an access to strip S_{(1,1)14} of unit cell UC_{1,1} is specified by a unit cell address value UC[3:0] of ‘0001’ and a strip address value STRIP[15:0] of ‘0100 0000 0000 0000’. Similarly, an access to strip S_{(2,1)1} of unit cell UC_{2,1} is specified by a unit cell address value UC[3:0] of ‘0010’ and a strip address value STRIP[15:0] of ‘0000 0000 0000 0010’.

The main word line address field MWL[11:0] specifies which one of the 32 main word lines of the specified strip is activated. The signals of the main word line address field MWL[11:0] are partially pre-decoded, wherein the signals MWL[11:0] are used to select one of thirty-two main word lines within the selected strip. In one embodiment, the eight main word line address signals MWL[4:11] are used to select one of eight sets of four main word lines, and the four main word line signals MWL[0:3] are used to select one of the four main word lines in the selected set.

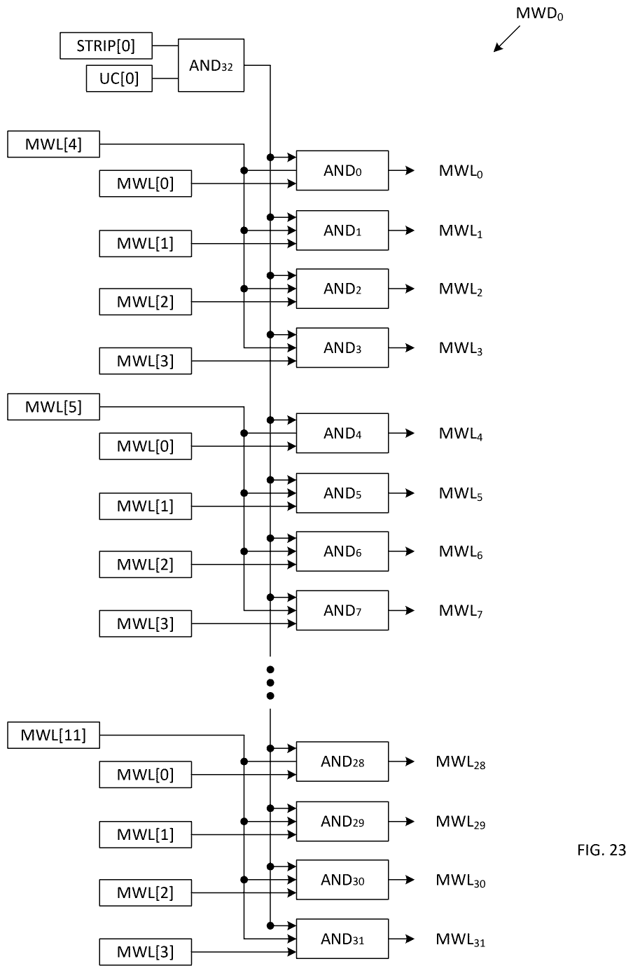

FIG. 23 illustrates the main word line decoder circuit MWD₀ associated with strip S_{(1,1)0} of unit cell UC_{1,1} in accordance with one embodiment. Main word line decoder circuit MWD₀ includes 3-input AND gates AND₀-AND₃₂, which are connected as illustrated. If the received instruction specifies an access to strip S_{(1,1)0} of unit cell UC_{1,1} (i.e., UC[0]=1 and STRIP[0]=1), then AND gate AND₃₂ provides a logic high output signal to each of the 32 AND gates AND₀-AND₃₁ of main word line decoder circuit MWD₀. Each of the eight main word line address signals MWL[4:11] is provided to a corresponding set of four AND gates. More specifically, MWL[4] is provided to AND gates AND₀-AND₃, MWL[5] is provided to AND gates AND₄-AND₇, . . . and MWL[11] is provided to AND gates AND₂₈-AND₃₁. Only one of the signals MWL[4:11] is activated during an access.

Each of the four main word line address signals MWL[3:0] is provided to an AND gate in each of the eight sets of AND gates. More specifically, the signals MWL[0]-MWL[3] are provided to AND gates AND₀-AND₃, respectively, to AND gates AND₄-AND₇, respectively, . . . and to AND gates AND₂₈-AND₃₁, respectively. Only one of the signals MWL[3:0] is activated during an access. In this manner, one of the thirty-two main word lines MWL₀-MWL₃₁ is activated during an access to strip S_{(1,1)0} of unit cell UC_{1,1}. Because only two of the main word line address signals MWL[11:0] are activated during an access, power savings are realized within the unit stack US₁. Although a particular circuit has been described for decoding the signals required to activate the main word lines MWL₀-MWL₃₂, it is understood that other decoding circuits are possible, and would be apparent to one of ordinary skill.

It is noted that each of the strips of unit cells UC_{1,1}, UC_{2,1}, UC_{3,1} and UC_{4,1} includes a corresponding centrally located main word line decoder circuit (having the same circuitry as main word line decoder circuit MWD₀), as illustrated by FIG. 6 (wherein each of these main word line decoder circuits operates in response to a corresponding strip address bit and a corresponding unit cell address bit). The timing of the main word line address signals MWL[0:11] is controlled to provide the desired timing of the main word line signal MWL₀. This timing is described in more detail in U.S. patent application Ser. No. 18/399,579, which is hereby incorporated by reference in its entirety.

The fully pre-decoded sub-array column address field CoSA_{A}[3:0] specifies one (or none) of the four sub-array columns CoSA₀-CoSA₃ associated with data channel DATA_A₁, and the fully pre-decoded sub-array column address field CoSA_{B}[3:0] specifies one (or none) of the four sub-array columns CoSA₄-CoSA₇ associated with data channel DATA_B₁. For example, a sub-array column address CoSA_{A}[3:0] having a value of ‘0001’ indicates that the sub-array column COSA₀ is selected for an access on data channel DATA_A₁, and a sub-array column address CoSA_{B}[3:0] having a value of ‘0010’ indicates that the sub-array column CoSA₅ is selected for an access on data channel DATA_B₁.

The sub-array column address signals CoSA_{A}[3:0] and CoSA_{B}[3:0] are used in combination with the unit cell signals UC[3:0] and strip address signal STRIP[15:0] to generate the sub-array select signals (e.g., EN_SUBA_{0,0}) used to enable the sub-word line driver circuits and primary sense amplifier sub-circuits in the sub-array(s) to be accessed.

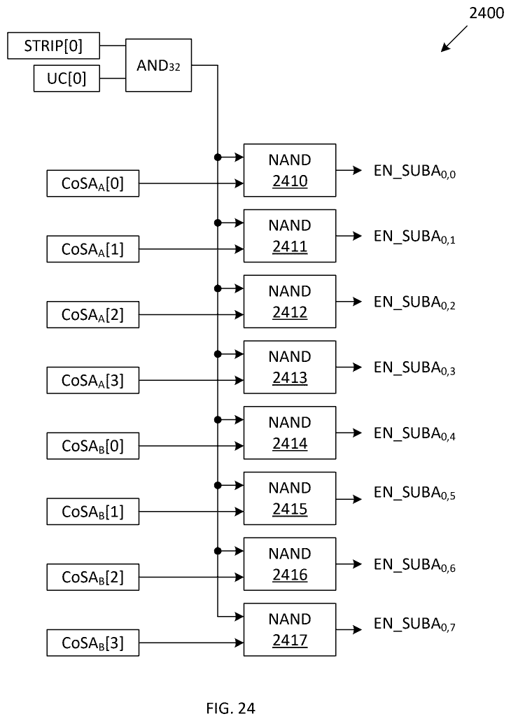

FIG. 24 illustrates a sub-array decoder circuit 2400 associated with strip S_{(1,1)0} of unit cell UC_{1,1} in accordance with one embodiment. In the described embodiment, the sub-array decoder circuit 2400 is centrally located within the strip S_{(1,1)0}, adjacent to the corresponding main word line decoder circuit MWD₀. It is understood that each strip of unit stack US₁ has a corresponding sub-array decoder circuit similar to sub-array decoder circuit 2400 (wherein each of these sub-array decoder circuits operates in response to a corresponding strip address bit and a corresponding unit cell address bit).

Sub-array decoder circuit 2400 includes eight NAND gates 2410-2417, as illustrated. Each of these NAND gates 2410-2417 is coupled to the output of AND gate NAND₃₂ (FIG. 23). Thus, sub-array decoder circuit 2400 is activated when the corresponding word line decoder circuit MWD₀ is activated. NAND gates 2410 to 2413 are also coupled to receive the sub-array column address signals CoSA_{A}[0] to CoSA_{A}[3], respectively. NAND gates 2414 to 2417 are also coupled to receive the sub-array column address signals CoSA_{B}[0] to CoSA_{B}[3], respectively. The outputs of NAND gates 2410 to 2417 provide the sub-array enable signals EN_SUBA_{0,0} to EN_SUBA_{0,7}, respectively. As described above in connection with FIG. 7, the sub-array enable signals EN_SUBA_{0,0} to EN_SUBA_{0,7}, are provided to enable the sub-word line driver circuits in the sub-arrays SUBA_{0,0} to SUBA_{0,7}, respectively. In the described embodiments, the sub-array enable signals EN_SUBA_{0,0} to EN_SUBA_{0,7} are activated low (i.e., enable a corresponding sub-word line driver circuit when having a logic low voltage) in a manner consistent with that described in U.S. patent application Ser. No. 18/399,579.

At most, only one of the sub-array column address signals CoSA_{A}[3:0] is activated high, such that only one (or none) of the EN_SUBA_{0,0}, EN_SUBA_{0,1}, EN_SUBA_{0,2} and EN_SUBA_{0,3} signals is activated (low) for any given access. Similarly, at most, only one of the sub-array column address signals CoSA_{B}[3:0] is activated high, such that only one (or none) of the EN_SUBA_{0,4}, EN_SUBA_{0,5}, EN_SUBA_{0,6} and EN_SUBA_{0,7} signals is activated (low) for any given access.

For example, sub-array column address signals CoSA_{A}[3:0] having a value of ‘0001’ activates the EN_SUBA_{0,0} signal, thereby activating the sub-word line drivers in sub-array SUBA_{0,0} (see, e.g., FIG. 7). Sub-array column address signals CoSA_{B}[3:0] having a value of ‘0010’ activates the EN_SUBA_{0,5} signal, thereby activating the sub-word line drivers in sub-array SUBA_{0,5}. If the sub-array column address signals CoSA_{A}[3:0] have a value of ‘0000’, then none of the sub-arrays SUBA_{0,0}, SUBA_{0,1}, SUBA_{0,2}, or SUBA_{0,3}, are activated (i.e., no data is read on the corresponding data channel DATA_A₁). Similarly, sub-array column address signals CoSA_{B}[3:0] having a value of ‘0000’, result in no data being read on the corresponding data channel DATA_B₁. The timing of the sub-array column address signals CoSA_{A}[3:0] and CoSA_{B}[3:0] are controlled to provide the desired timing of the sub-array enable signals EN_SUBA_{0,0} to EN_SUBA_{0,7}. This timing is described in more detail in U.S. patent application Ser. No. 18/399,579, which is hereby incorporated by reference in its entirety.

As described above in connection with FIG. 7, each main word line is coupled to eight corresponding sub-word lines. For example, main word line MWL₀ is coupled to eight corresponding sub-word lines SWL_{0,0} to SWL_{7,0} via sub-word line driver circuits SWD_{0,0} to SWD_{7,0}. The sub-word line address value SWL_{A}[7:0] includes eight pre-decoded sub-word line address signals, each associated with one of the eight sub-word lines associated with the activated main word line for data channel DATA_A₁. For example, if the instruction 2200 specifies the main word line MWL₀ of strip S_{(1,1)0} of sub-array SUBA_{0,0}, then an activated sub-word line address signal SWL_{A}[x] is used to activate the sub-word line SWL_{x,0} associated with the activated main word line MWL₀. In the described embodiments, the sub-word line address signals SWL_{A}[7:0] and SWL_{B}[7:0] are ‘activated’ to a logic low state. More specifically, a sub-word line address value SWL_{A}[7:0] having a value of ‘1111 1110’ (i.e., SWL_{A}[0] is activated) is used to activate the sub-word line SWL_{0,0} associated with the activated main word line MWL₀.

Each of the sub-word line address values SWLA_{A}[7:0] is provided to a corresponding sub-word line driver circuit associated with the corresponding sub-word line. For example, in FIG. 7, each sub-word line address value SWLA_{A}[x] is provided to a corresponding sub-word line driver circuit SWD_{x,0} (wherein x=0 to 7).

When a sub-word line driver circuit receives an activated sub-array enable signal EN_SUBA, an activated main word line signal, and an activated sub-word line address signal, the sub-word line driver circuit drives the corresponding sub-word line to a high state to implement an access to the bit cells coupled to the sub-word line. For example, if the instruction 2200 specifies the main word line MWL₀ of strip S_{(1,1)0} of sub-array SUBA_{0,0} within unit cell UC_{1,1}, and the sub-word line address value SWL_{A}[7:0] specifies the sub-word line SWL_{0,0} associated with the activated main word line MWL₀, then the MWL₀, EN_SUBA_{0,0} and SWL_{A}[0] signals will all be activated, thereby enabling sub-word line driver SWD_{0,0} to activate sub-word line SWL_{0,0}, thereby accessing bit cells bc_{0,0} to bc_{0,575}. In one embodiment, the activated sub-word line address value SWL_{A}[0] is controlled to transition to a logic high state, and then transition to a boosted logic high state partway through the access to sub-word line SWL_{0,0}. This process is described in more detail in U.S. patent application Ser. No. 18/399,579, which is hereby incorporated by reference in its entirety.

As described above in connection with FIGS. 7 and 8, data read from bit cells bc_{0,0}-bc_{0,575} is latched into the corresponding primary sense amplifier sub-circuits PSA_{0,0} and PSA_{1,0} in response to the activated EN_SUBA_{0,0} signal.

Similarly, the sub-word line address value SWL_{B}[7:0] is a pre-decoded address value that specifies one of the eight sub-word lines associated with the activated main word line within data channel DATA_B₁. In the described embodiment, the sub-word line address value SWL_{B}[7:0] is independent of the sub-word line address value SWL_{A}[7:0], enabling different sub-word lines to be accessed in data channels DATA_A₁ and DATA_B₁. This advantageously provides flexibility in addressing the sub-arrays within these two data channels. In an alternate embodiment, a single sub-word line address value SWL[7:0] is used to select the sub-word line in both data channels DATA_A₁ and DATA_B₁. This embodiment advantageously reduces the number of TSVs required to implement unit stack US₁ by 8.

Instruction 2200 also includes a pre-decoded Y-address value Y-DEC[7:0] that selects one of eight 72-bit data values stored in the primary sense amplifier sub-circuits in the access, in the manner described above in connection with FIGS. 8-10.

Instruction 2200 also includes a read/write control bit (RW), which indicates whether the corresponding access is a read operation or a write operation.

Thus, the pre-decoded instruction 2200 requires 65 TSVs in the corresponding TSV region of the unit cell. When added to the 72 TSVs required to implement the two 36-bit data buses DATA_A₁ and DATA_B₁, and the TSV required to provide the clock signal CLK, the entire unit stack US₁ requires a total of 138 TSVs. In the alternate embodiment where both data channels DATA_A₁ and DATA_B₁ share a single sub-word line address, the unit stack US₁ only requires a total of 130 TSVs.

The dimensions of unit cell UC_{1,1}, along with the manner in which the TSVs of the unit cell UC_{1,1} are laid out will now be described.

### Unit Cell Height

In accordance with the embodiments described above, each MTDRAM bit cell of unit cell UC_{1,1} (e.g., bit cell bc_{0,0} of FIG. 7) has a vertical height along the Y-axis of 0.0243 microns (um). In the embodiment of FIG. 8, unit cell UC_{1,1} includes 576 columns of bit cells per sub-array, and 8 sub-arrays per strip. In this embodiment, the height along the Y-axis required for the bit cells is about 112 microns (0.0243 um×576 bit cells/sub-array×8 sub-arrays/strip).

In the embodiment of FIG. 8, each strip of unit cell UC_{1,1} includes 8 sub-word line driver circuits and one main word line driver circuit along the Y-axis. Assuming each sub-word line driver circuit has a height along the Y-axis of about 1.86 um, and the main word line driver circuit has a height along the Y-axis of about 7 um, then the height along the Y-axis required for the sub-word line driver circuits and the main word line driver circuit is about 22 um (1.855 um×8+7 um).

Thus, the total height of the unit cell UC_{1,1} along the Y-axis is about 134 um (112+22). Assuming a TSV pitch of 2 um, a row of TSVs extending the height of the unit cell UC_{1,1} may include up to about 67 TSVs.

FIG. 25 is a block diagram illustrating the layout of the 137 TSVs required to service unit cell UC_{1,1} in the manner described above. It is noted that unit cells UC_{2,1}, UC_{3,1} and UC_{4,1} have the same TSV pattern as unit cell UC_{1,1} to facilitate the required connections of the corresponding unit stack US₁. The TSV pattern of FIG. 25 utilizes three rows of TSVs located adjacent to the secondary sense amplifier SSA_{1,1}. Each row of TSVs include 44 or fewer TSVs, easily allowing this TSV pattern to be located within the 134 um height of unit cell UC_{1,1}.

In the embodiment of FIG. 25, the twelve TSVs carrying the main word line address MWL[11:0] are centrally located (under the main word line driver circuits MWD). Six of these twelve TSVs are located in open space between the secondary sense amplifier circuits SSA_{(1,1)A} and SSA_{(1,1)B} and/or in open space between multiplexer circuits MUX_{(1,1)A} and MUX_{(1,1)B}, as illustrated. The remaining six TSVs are located in the three rows of TSV located below the secondary sense amplifier SSA_{1,1}, as illustrated.

The 36 TSVs required to implement the DATA_A₁[35:0] bus are shown as shaded circles in FIG. 25. Note that these TSVs are evenly distributed along the width of the secondary sense amplifier circuit SSA_{(1,1)A}, wherein 9 bits of the DATA_A₁[35:0] bus are located along each of the four sub-array columns CoSA₀-CoSA₃, thereby minimizing signal delay and power.

The 36 TSVs required to implement the DATA_B₁[35:0] bus are shown as black-filled circles in FIG. 25. Note that these TSVs are evenly distributed along the width of the secondary sense amplifier circuit SSA_{(1,1)B}, wherein 9 bits of the DATA_B₁[35:0] bus are located along each of the four sub-array columns CoSA₄-CoSA₇.

The TSVs required to implement the UC[3:0] address values, the STRIP[15:0] address values, the CoSA_{A}[3:0] and CoSA_{B}[3:0] address values, the SWL_{A}[7:0] and SWL_{B}[7:0] address values, the Y-DEC[7:0] address values, the RW value and the CLK signal are distributed as illustrated by FIG. 25.

In accordance with one embodiment, the TSV pattern is selected such that most of the TSVs are centrally located within the unit cell UC_{1,1} (along the Y-axis). That is, the TSV pattern is sparsely populated at the outer edges along the Y-axis (i.e., under sub-array columns CoSA₀-CoSA₁ and CoSA₆-CoSA₇). As described in more detail below, these sparsely populated TSV regions advantageously provide room for routing structures (which extend along the X-axis) on the underlying processor block 105₁.

Having determined the configuration of the TSVs of unit cell UC_{1,1}, the width of the unit cell UC_{1,1} along the X-axis can be determined.

### Unit Cell Width

In accordance with the embodiments described above, each MTDRAM bit cell of unit cell UC_{1,1} (e.g., bit cell bc_{0,0} of FIG. 7) has a width along the X-axis of 0.0383 um. In the embodiment of FIG. 8, unit cell UC_{1,1} includes 256 rows of bit cells per strip, and 16 total strips. In this embodiment, the width along the X-axis required for the bit cells is about 156.88 microns (0.0383 um×256 bit cells/strip×16 strips/unit cell).

In the embodiment of FIG. 6, unit cell UC_{1,1} includes 17 primary sense amplifier circuits PSA₀-PSA₁₆. Assuming each primary sense amplifier circuit has a width along the X-axis of about 2.65 um, then the width along the X-axis required for the primary sense amplifier circuits is about 45.05 um (2.65 um×17).

In the embodiment of FIG. 6, unit cell UC_{1,1} also includes multiplexer MUX_{1,1} and secondary sense amplifier circuit SSA_{0,0}. In one embodiment, the width of multiplexer MUX_{1,1} and secondary sense amplifier circuit SSA_{0,0} along the X-axis is about 10 um (based on the circuitry of FIGS. 14-20).

In accordance with the embodiment of FIG. 25, unit cell UC_{1,1} requires three rows of TSVs, with a pitch of 2 um. Thus, the required width of the TSV set TSV_{1,1} along the X-axis is about 6 um.

The total required width of unit cell UC_{1,1} along the X-axis is therefore about 222 um (156.88 um+45.05 um+10 um+4 um+6 um) in the described embodiment.

Because the MTDRAM chip 101 includes 64 rows and 32 columns of unit cells UC_{1,1}-UC_{1,2048} (FIG. 2), the total required width of chip 101 is about 7.1 mm (32×222 um) along the X-axis, and the total required height of chip 101 is about 8.6 mm (64×134 um) along the Y-axis. Thus, MTDRAM chip 101 has an advantageous size in view of conventional fabrication practices. This is due to the significant amount of signal pre-decoding being performed by the ASIC controller chip 105 for accesses to all four MTDRAM chips 101-104. Furthermore, obsolete functionality, such as self-refresh and other area-consuming features typically included in prior art DRAMs, is either removed completely or is implemented on the ASIC controller chip 105.

In alternate embodiments of the present invention, the number of sub-arrays per strip and the number of strips per unit cell can be modified to make the unit cell size larger or smaller, as desired. In a ‘tiny cell’ embodiment, the number of sub-arrays per strip is reduced from eight to four, and the number of strips per unit cell is reduced from sixteen to eight. This ‘tiny cell’ configuration increases the number of unit cells per chip from 2048 to 8192, thereby greatly increasing the addressable locations within the MTDRAM system.

The random access cycle time to the same strip is 4 ns, and the random access cycle time to ‘legal’ strips (i.e., strips that are not subject to pre-charging conditions as described above) is 1 ns. The nearly random access rate of MTDRAM system 100 (for 72-bit data) is therefore 1 GHz/channel×2 channels/unit stack×2048 unit stacks=4.096E+12. This nearly random access rate is about 12,800 times greater than the semi-random address rate of 3.2E+08 achieved by conventional HBM3 memory.

A MTDRAM system that implements the ‘tiny cell’ embodiment will exhibit a nearly random access rate of 1 GHz/channel×2 channels/unit stack×8192 unit stacks=1.6384E+13, which is about 51,200 times greater than the semi-random address rate of 3.2E+08 achieved by conventional HBM3 memory.

As described above, the data rate on the TSVs that implement the DATA_A₁ and DATA_B₁ channels is 2 Gb/sec/pin. This data rate is advantageously lower than the data rate of 5.2 Gb/sec/pin associated with a conventional HBM3 memory, advantageously resulting in significant power savings.

As described above, MTDRAM system 100 includes 72 TSVs to carry data signals per unit stack. Because MTDRAM system 100 includes 2048 unit stacks, a total of 147,456 TSVs are available to carry data in MTDRAM system 100. Because data is transmitted on each of these TSVs at a rate of 2 Gb/sec, the total data rate of MTDRAM system is 147,456×2 Gb/sec=294,912 Gb/sec. This total data rate is about 55 times greater than the total data rate of a conventional HBM3 memory system, which exhibits a total data rate of about 5,325 Gb/sec. This total data rate is also about 16 times greater than the total data rate of a conventional HBM3E memory system, which exhibits a total data rate of about 18,842 Gb/sec.

A MTDRAM system that implements the ‘tiny cell’ embodiment will include 8,192 unit stacks, with a total of 589,824 TSVs available to carry data. With data transmitted on each of these TSVs at a rate of 2 Gb/sec, the total data rate of a MTDRAM system the implements the ‘tiny cell’ embodiment is 589,824×2 Gb/sec=1,179,648 Gb/sec.

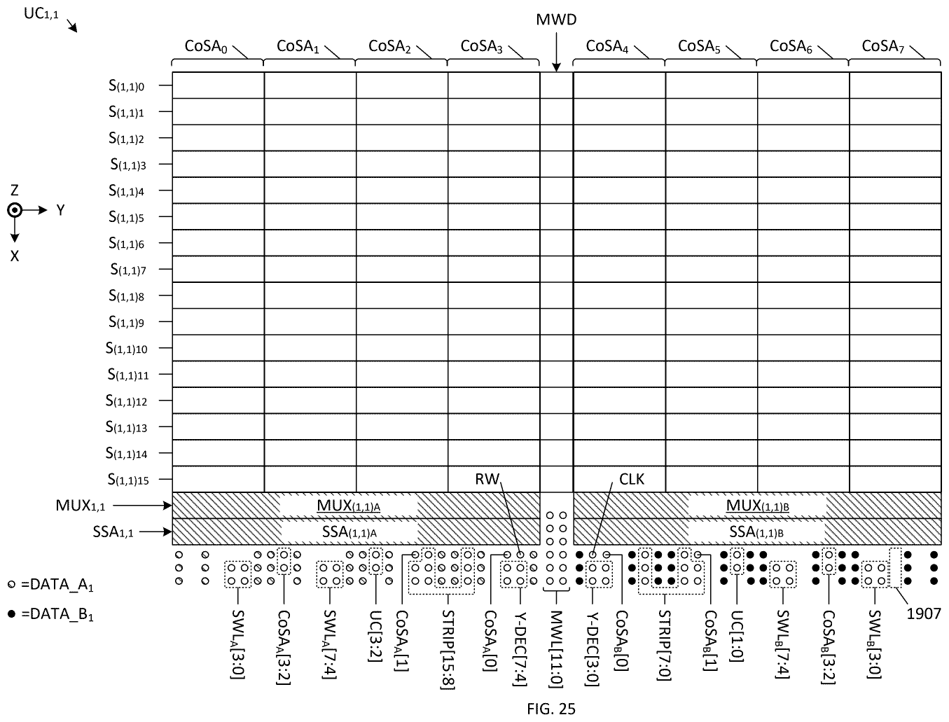

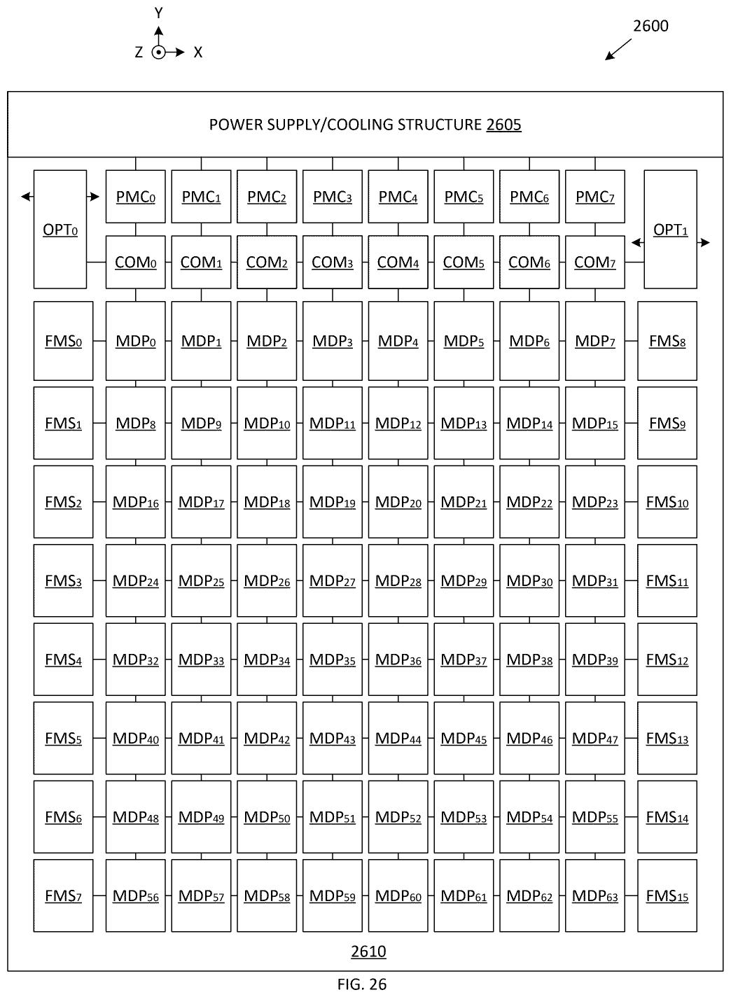

FIG. 26 is a block diagram of an arrayed processor system 2600 in accordance with one embodiment of the present invention. Arrayed processor system 2600 includes an 8×8 array of MTDRAM processor systems MDP₀-MDP₆₃, sixteen stacked flash memory systems FMS₀-FMS₁₅, eight communication control chips COM₀-COM₇, eight power management chips PMC₀-PMC₇, two high-speed optical communication links OPT₀-OPT₁, and power supply/cooling structure 2605. As described in more detail below, the above-described elements of the arrayed processor system 2600 are mounted on (and interconnected by) an interconnect structure 2610 that includes a silicon substrate (e.g., wafer) with a plurality of patterned metal interconnect layers formed thereon.

In the embodiment illustrated by FIG. 26, each of the MTDRAM processor systems MDP₀-MDP₆₃ is identical to MTDRAM system 100 (FIG. 1). Thus, each of the MTDRAM processor system systems MDP₀-MDP₆₃ includes an ASIC controller chip and plurality of (4) MTDRAM chips, which are connected in a stack. More specifically, each MTDRAM processor system includes a plurality of (2048) independent unit stacks, wherein each unit stack includes: a processor block on the ASIC controller chip and a corresponding plurality of (4) MTDRAM unit cells (i.e., one MTDRAM unit cell per MTDRAM chip). In general, each processor block can transfer data to/from its corresponding plurality of 4 MTDRAM unit cells, in the manner described above.

Because there are so many processor blocks (2048) within each of the MTDRAM processor systems MDP₀-MDP₆₃, and there are so many MTDRAM processor systems (64) in arrayed processor system 2600, it is desirable to have an efficient communication system for transmitting data between all of the processor blocks within the arrayed processor system 2600. It is also desirable to have an efficient communication system that allows data to be transmitted between the processor blocks of MTDRAM processor systems MDP₀-MDP₆₃ and the stacked flash memory systems FSM₀-FMS₁₅. It is also desirable to have an efficient communication system that allows data to be transmitted between the processor blocks of MTDRAM processor systems MDP₀-MDP₆₃ and the optical communication links OPT₀-OPT₁. Accordingly, the present invention provides various communication elements within the ASIC controller chips of the MTDRAM processor systems MDP₀-MDP₆₃ and within the silicon substrate interconnect structure 2610 to enable the data transmissions specified above.

As described in more detail below, the silicon substrate interconnect structure 2610 includes a set of connections which enable the transmission of data horizontally (along the X-axis) between the plurality of MTDRAM processor systems MDP₀-MDP₆₃ (and also between the MTDRAM processor systems MDP₀-MDP₆₃ and the stacked flash memory systems FMS₀-FMS₁₅). The silicon substrate interconnect structure 2610 also includes a set of connections which enable the transmission of data vertically (along the Y-axis) within (and between) the plurality of MTDRAM processor systems MDP₀-MDP₆₃ (and also between the MTDRAM processor systems MDP₀-MDP₆₃ and the communication management chips COM₀-COM₇).

As illustrated by FIG. 26, the plurality of stacked flash memory systems FMS₀-FMS₁₅ are located at opposite edges of the array of MTDRAM processor systems MDP₀-MDP₆₃. In one embodiment, each of the stacked flash memory systems FMS₀-FMS₁₅ includes an ASIC controller chip coupled to a plurality of flash memory chips in a stacked configuration similar to that described above in connection with MTDRAM system 100. In this embodiment, each of the stacked flash memory systems FMS₀-FMS₁₅ includes a plurality of independent flash unit stacks, wherein each flash unit stack includes a corresponding processor block and a corresponding plurality of stacked flash unit cells, which operate in a similar manner as the processor block and MTDRAM unit cells of an MTDRAM unit stack within MTDRAM system 100. That is, the stacked flash memory systems FMS₀-FMS₁₅ are similar to the MTDRAM processor systems MDP₀-MDP₆₃, wherein the stacked flash memory systems FMS₀-FMS₁₅ implement flash memory cells, rather than MTDRAM memory cells. In one embodiment, the flash memory cells operate at a relatively slow access frequency, wherein data read from the flash memory cells is serialized using a high speed interface included in the flash unit cell, and the serialized data is provided to a corresponding processor block. In one embodiment, each of the flash memory chips includes fewer than 2048 stacked flash unit cells, based on given limitations of flash memory technology. In particular embodiments, each of the flash memory chips may include 256 (4×64) to 512 (8×64) flash unit cells.

As illustrated by FIG. 26, the plurality of communication management chips COM₀-COM₇ are located at an upper edge of the array of MTDRAM processor systems MDP₀-MDP₆₃, wherein a plurality of high speed connections are included within the interconnect structure 2610 to transmit data vertically (along the Y-axis) between the communication management chips COM₀-COM₇ and the array of MTDRAM processor systems MDP₀-MDP₆₃.

In accordance with another embodiment, the plurality of communication management chips COM₀-COM₇ are further connected to a plurality of high-speed optical communication links OPT₀-OPT₁, which allow for the transmission of data between the communication management chips COM₀-COM₇ and other external (e.g., remote) communication devices. Although high-speed optical links are designated in the present embodiments, it is understood that other high-speed communication links (e.g., satellite communication links) can be used in other embodiments. In one embodiment, the high-speed optical communication links OPT₀-OPT₁ can transfer data anywhere in the world almost instantaneously.

In accordance with another embodiment, the plurality of power management chips PMC₀-PMC₇ receive power (e.g., the required supply voltages) from power supply/cooling structure 2605. Power management chips PMC₀-PMC₇ distribute the received power supply voltages to the other elements of arrayed processor system 2600 via a power distribution network implemented by connections within interconnect structure 2610.

In addition to routing the required power supply voltages to power management chips PMC₀-PMC₇, the power supply/cooling structure 2605 also provides the necessary cooling for arrayed processor system 2600. For example, cooling may be provided by forced air and/or forced liquid circulation.

In accordance with one embodiment, the interconnect structure 2610 includes metal lines formed over a silicon substrate using conventional processing techniques, wherein the array of MTDRAM processor systems, the stacked flash memory systems, communication management chips and power management chips are mounted on the silicon substrate interconnect structure 2610 using conventional bump technology, or any other conventional chip mounting technology compatible with the TSV pitch implemented by the various elements of the arrayed processor system 2600. In a particular embodiment, the silicon substrate interconnect structure 2610 may contain up to 50-100 patterned metal layers (or more) having loose dimensional specifications, when compared to metal layers typically found in a state of the art modern logic chip. That is, the metal widths and spacings necessary to implement interconnect structure 2610 are much larger than the metal widths and spacings required on the MTDRAM chips and ASIC communication chips described herein, advantageously allowing the use of lower cost materials and systems in the fabrication of silicon substrate interconnect structure 2610. In a particular embodiment, silicon substrate interconnect structure 2610 is fabricated on an inexpensive 6 inch silicon wafer, with contact-printed metal layers (which do not require expensive reticles). Advantageously, the silicon substrate interconnect structure 2610 exhibits a similar coefficient of expansion as the attached silicon-based structures (e.g., ASIC controller chip 105 and MTDRAM chips 101-104), increasing reliability of the arrayed processor system 2600. Note that conventional FR4-based interconnect structures exhibit a different coefficient of expansion than silicon-based structures, which can result in failures based on repeated temperature cycling.

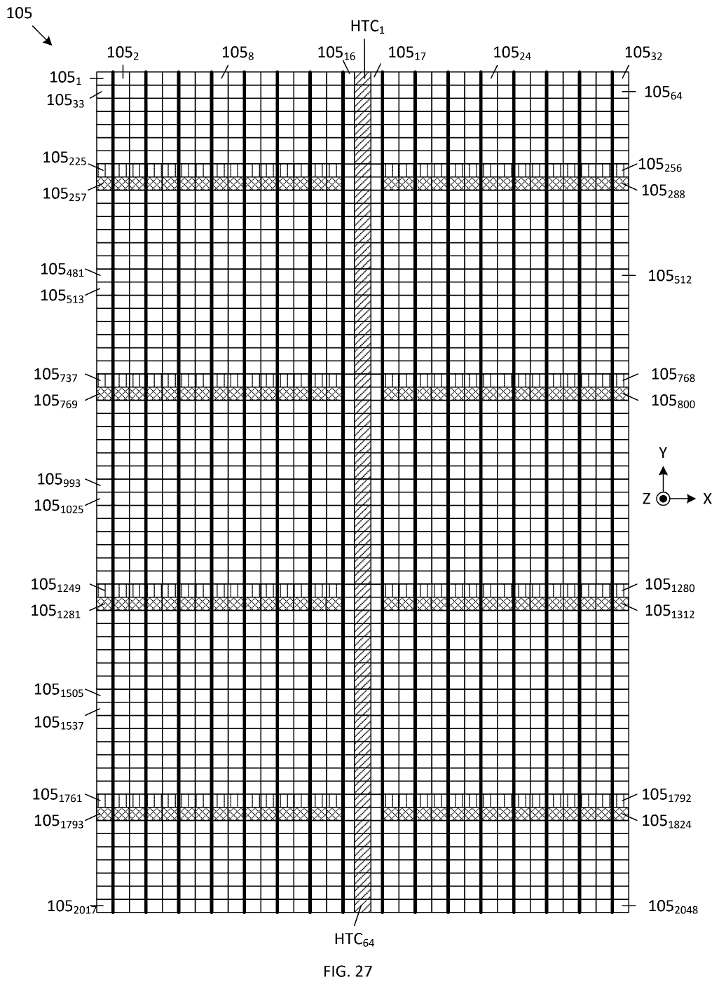

FIG. 27 is a top view representation of the layout of the 2048 processor blocks 105₁-105₂₀₄₈ which are included in the 2048 unit stacks US₁-US₂₀₄₈, respectively, of MTDRAM processor system MDP₀ (which has the same configuration as MTDRAM system 100). As described above, data can be transferred locally (along the Z-axis) between each processor block and the MTDRAM unit cells of its corresponding unit stack (e.g., data can be transferred locally between processor block 105₁ and unit cells UC_{1,1}, UC_{2,1}, UC_{3,1} and UC_{4,1}, within unit stack US₁).

In addition, data can be transferred in an intra-chip manner between each of the processor blocks 105₁-105₂₀₄₈ on ASIC controller chip 105. In general, data can be transferred horizontally (along the X-axis) and/or vertically (along the Y-axis) between the 2048 processor blocks 105₁-105₂₀₄₈ on ASIC controller chip 105.

In addition, within arrayed processor system 2600, data can be transferred in an inter-chip manner between the processor blocks included in the ASIC controller chips included in the MTDRAM processor systems MDP₀-MDP₆₃, the stacked flash memory systems FMS₀-FMS₁₅, and the communication management chips COM₀-COM₇. The manner in which the inter-chip and intra-chip communications are performed is described in more detail below.

As illustrated by FIG. 27, a set of sixty-four horizontal transport controllers HTC₁-HTC₆₄ are centrally located (along the X-axis) within each of the 64 rows of processor blocks. For example, horizontal transport controller HTC₁ is located within processor blocks 105₁₆ and 105₁₇ of the first row of processor blocks. Although not individually numbered in FIG. 27, it is understood that the sixty-four horizontal transport controllers HTC₁-HTC₆₄ are sequentially numbered from top to bottom in FIG. 27.

In accordance with one embodiment, each of the processor blocks that include the horizontal transport controllers HTC₁-HTC₆₄ (e.g., processor blocks 105₁₆ and 105₁₇, which include the horizontal transport controller HTC₁ in the first row of processor blocks) do not include vertical transport controllers (described below) or other logic, which is present in processor blocks that do not include the horizontal transport controllers HTC₁-HTC₆₄. In this manner, the processor blocks that include the horizontal transport controllers HTC₁-HTC₆₄ have a different configuration (and functionality) than the other processor blocks of ASIC controller chip 105.

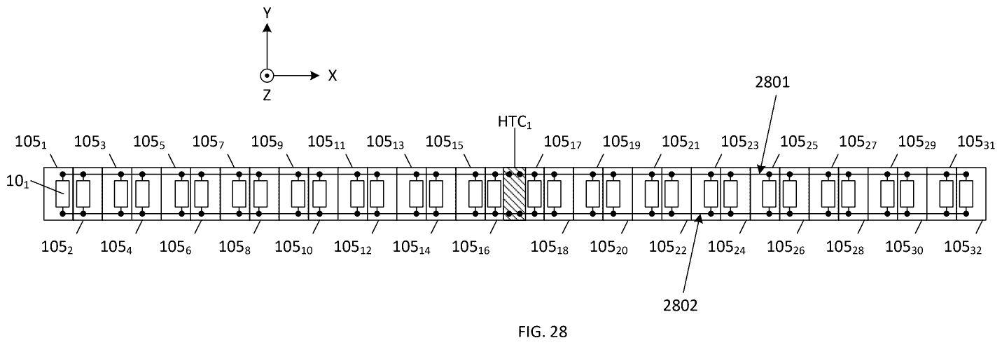

FIG. 28 generally illustrates the first row of processor blocks of ASIC controller chip 105, including processor blocks 105₁-105₃₂. Each of the processor blocks 105₁-105₃₂ includes a processor nexus, which is illustrated as a rectangle within the processor block. For example, processor block 105₁ includes processor nexus 10₁. It is understood that each processor nexus controls accesses to the corresponding MTDRAM unit cells of the corresponding MTDRAM unit stack (as well as accesses external to the processor block 105₁). Each processor nexus is also configured to perform various operations (such as comparison operations) on data received from its corresponding MTDRAM unit cells, as well as data received from locations external to the processor block (e.g., along the horizontal and vertical communication paths described below). In accordance with one embodiment, all (or most) of the processor nexuses on ASIC controller chip 105 have the same configuration, enabling a large plurality of similar operations to be performed in parallel. In another embodiment, all (or most) of the processor nexuses on ASIC controller chip 105 have different configurations, enabling a large plurality of different operations to be performed in parallel. In another embodiment, a combination of these two embodiments may be implemented.

Horizontal interconnect structures 2801-2802 provide horizontal communication paths (along the X-axis) that allow the processor nexuses within each of the processor blocks 105₁-105₃₂ to communicate with one another (and with horizontal transport controller HTC₁). More specifically, horizontal interconnect structures 2801-2802 enable the transmission of data/control information between any of the processor blocks 105₁-105₃₂. Horizontal interconnect structures 2801-2802 also enable any of the processor blocks 105₁-105₃₂ to transfer data/control information to/from the horizontal transport controller HTC₁. Although horizontal interconnect structures 2801-2802 are illustrated as continuous buses in FIG. 28, it is understood that horizontal interconnect structures 2801-2802 are divided into smaller segments (or wheels) to avoid direct long distance signal transmission across the entire ASIC controller chip 105. For example, each smaller segment (or wheel) may facilitate horizontal transmission across up to four processor blocks, with repeaters being used to transmit signals horizontally between segments (wheels), if necessary. The horizontal interconnect structures 2801-2802 (including the repeaters within these structures) and the horizontal transport controller HTC₁ are designed to have enough bandwidth to keep data moving continuously through the arrayed processor system 2600, with no gaps or stalls. Design parameters that can be varied to achieve this bandwidth include, but are not limited to, data transmission frequency, data signal swing and data bus width and length. These parameters can further be adjusted in consideration of trade-offs necessitated by power and area limitations.

As illustrated by FIG. 28, horizontal interconnect structure 2801 extends along an upper edge of the row of processor blocks 105₁-105₃₂ and horizontal interconnect structure 2802 extends along a lower edge of the row of processor blocks 105₁-105₃₂. Within each of the processor blocks 105₁-105₃₂, the corresponding processor nexus is coupled to both of the horizontal interconnect structures 2801-2802, as illustrated. For example, processor nexus 10₁ of processor block 105₁ is coupled to both of the horizontal interconnect structures 2801-2802.

In the illustrated described embodiments, horizontal interconnect structures 2801 and 2802 each include a plurality of bus lines which are fabricated in the metal layers of ASIC controller chip 105. As described above in connection with FIG. 25, the TSV pattern associated with the MTDRAM unit cells (and therefore the TSV pattern existing in the underlying processor block) is intentionally sparsely populated at the upper and lower edges (along the Y-axis) of each MTDRAM unit cell. This configuration advantageously provides room for locating the metal bus lines of the horizontal interconnect structures 2801-2802 in the locations illustrated by FIG. 28.

The horizontal interconnect structures 2801 and 2802 are also coupled to the horizontal transport controller HTC₁. As described in more detail below, the horizontal transport controller HTC₁ is coupled to other horizontal transport controllers external to ASIC controller chip 105, thereby providing horizontal communication paths between the processor blocks 105₁-105₃₂ on ASIC controller chip 105 and horizontally aligned processor blocks external to ASIC controller chip 105.

It is understood that the remaining horizontal transport controllers HTC₂-HTC₆₄ of ASIC controller chip 105 are coupled to their corresponding rows of processor blocks in the same manner that horizontal transport controller HTC₁ is connected to its corresponding row of processor blocks 105₁-105₃₂.

It is further understood that each of the processor blocks 105₁-105₁₅ and 105₁₈-105₃₂ includes additional circuitry (not shown in FIG. 28), which enables the transfer of data vertically (i.e., along the Y-axis) between the processor blocks within ASIC controller chip 105. This vertical transport control circuitry, which is included within most of the processor blocks of ASIC controller chip 105 (i.e., the processor blocks that do not include horizontal transport controllers), is described in more detail below in connection with FIGS. 30-32.

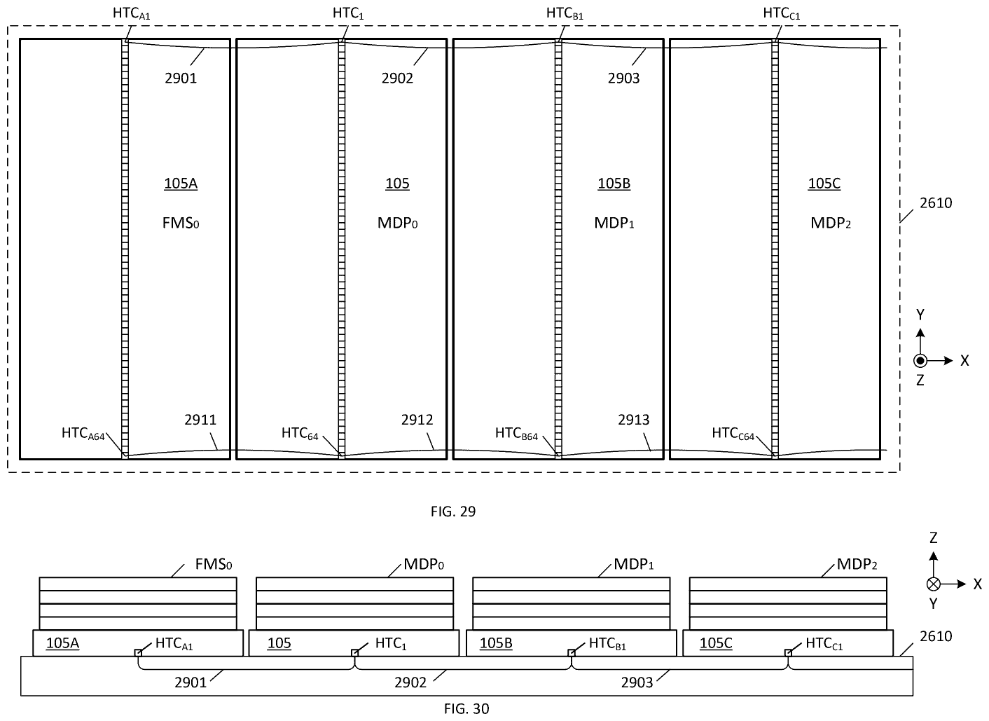

FIG. 29 is a block diagram that generally illustrates sixty-four horizontal transport controllers HTC_{A1} to HTC_{A64} included on the ASIC controller chip 105A of stacked flash memory system FMS₀, sixty-four horizontal transport controllers HTC₁ to HTC₆₄ included on the ASIC controller chip 105 of MTDRAM processor system MDP₀, sixty-four horizontal transport controllers HTC_{B1} to HTC_{B64} included on the ASIC controller chip 105B of MTDRAM processor system MDP₁, and sixty-four horizontal transport controllers HTC_{C1} to HTC_{C64} included on the ASIC controller chip 105C of MTDRAM processor system MDP₂, in accordance with one embodiment.

Horizontal communication paths are provided between horizontally adjacent horizontal transport controllers HTC_{AX}, HTC_{X}, HTC_{BX} and HTC_{CX} (wherein X=1 to 64). For example, horizontal communication path 2901 extends between horizontal transport controllers HTC_{A1} and HTC₁, horizontal communication path 2902 extends between horizontal transport controllers HTC₁ and HTC_{B1}, horizontal communication path 2903 extends between horizontal transport controllers HTC_{B1} and HTC_{C1}. Similarly, horizontal communication path 2911 extends between horizontal transport controllers HTC_{A64} and HTC₆₄, horizontal communication path 2912 extends between horizontal transport controllers HTC₆₄ and HTC_{B64}, and horizontal communication path 2913 extends between horizontal transport controllers HTC_{B64} and HTC_{C64}. Although FIG. 29 only illustrates horizontal communication paths 2901-2903 associated with horizontal transport controllers HTC_{A1}, HTC₁, HTC_{B1} and HTC_{C1} of the first row of horizontal transport controllers, and horizontal communication paths 2911-2913 associated with horizontal transport controllers HTC_{A64}, HTC₆₄, HTC_{B64} and HTC_{C64} of the sixty-fourth row of horizontal transport controllers, it is understood that all sixty-four rows of horizontal transport controllers have similar horizontal communication paths.

This pattern continues horizontally across the X-axis width of the arrayed processor system 2600 (i.e., through MTDRAM processor systems MDP₃-MDP₇ and stacked flash memory system FMSs). This pattern also continues vertically along the Y-axis (within each row of stacked flash memory systems/MTDRAM processor systems in the arrayed processor system 2600).

In accordance with one embodiment, the above-described horizontal communication paths of the arrayed processor system 2600 are implemented by metal traces in the underlying silicon substrate interconnect structure 2610. FIG. 30 is a block diagram illustrating the general routing of the horizontal communication paths 2901-2903 within silicon substrate interconnect structure 2610.

In one embodiment, data transfer between horizontal transport controllers occurs at an intermediate frequency, which is greater than the operating frequency of the MTDRAM unit cells (e.g., 1 to 2 GHz). The bandwidth of the horizontal communication paths between the horizontally aligned horizontal transport controllers is designed to be high enough to enable the simultaneous transfer of data to/from all processor nexuses within the corresponding row of processor blocks within the arrayed processor system 2600. For example, the horizontal communication path 2902 has a bandwidth capable of transmitting data from horizontal transport controller HTC₁ (received from all of the processor nexuses of processor blocks 105₁-105₃₂) to horizontal transport controller HTC_{B1}, while simultaneously receiving data from horizontal transport controller HTC_{B1} (received from all of the processor nexuses of the first row of processor blocks within ASIC controller chip 105B). In one embodiment, the horizontal communication paths are designed to exhibit the full bandwidth specified above. However, in alternate embodiments, the horizontal communication paths are designed to exhibit a partial bandwidth (less than the full bandwidth), which is adequate to support the design goals of a particular system that uses the above-described architecture. This configuration advantageously allows for rapid horizontal transfer of data throughout the arrayed processor system 2600.

Vertical communication paths (along the Y-axis) within arrayed processor system 2600 will now be described.

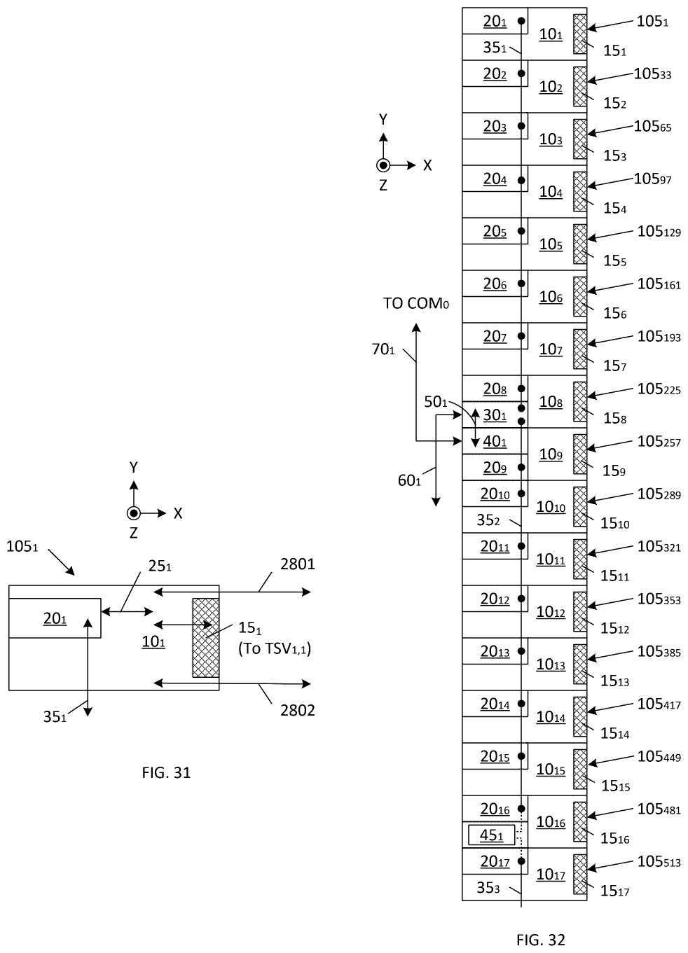

FIG. 31 is a block diagram of processor block 105₁ of ASIC controller chip 105 in accordance with one embodiment of the present invention. Processor block 105₁ includes processor nexus 10₁ (which is also illustrated in FIG. 28, along with on-chip horizontal interconnect structures 2801-2802), TSV connectors 151 (which are coupled to TSV set TSV_{1,1} of unit cell UC_{1,1}) and local vertical transport controller 20₁. In general, processor nexus 10₁ transfers data to/from its corresponding MTDRAM unit cells UC_{1,1}, UC_{2,1}, UC_{3,1} and UC_{4,1} via TSV set TSV_{1,1} in the manner described above. Local vertical transport controller 20₁ also transfers data to/from processor nexus 10₁, as illustrated by interface 25₁. In addition, local vertical transport controller 20₁ transfers data vertically to/from other local vertical transport controllers in the same column as processor block 105₁, as illustrated by vertical interconnect structure 351.

In the embodiment illustrated by FIG. 27, most (but not all) of the processor blocks 105₁-105₂₀₄₈ of ASIC controller chip 105 include the circuit elements illustrated by FIG. 31. In the illustrated embodiment, the processor blocks that include the horizontal transport controllers HTC₁-HTC₆₄ do not include a local vertical transport controller as illustrated by FIG. 31 (because the area required to implement a local vertical transport controller is consumed by the horizontal transport controller). For example, processor blocks 10515 and 105₁₆, which include horizontal transport controller HTC₁, do not include local vertical transport controllers.

In addition to the circuit elements included in processor block 105₁, a first subset of the processor blocks of ASIC controller chip 105 also include a regional vertical transport controller, which allows for short vertical communication ‘hops’ within the ASIC controller chip 105 (as well as short vertical communication ‘hops’ to vertically adjacent ASIC controller chips). In the embodiment illustrated by FIG. 27, the first subset of processor blocks on ASIC controller chip 105 includes processor blocks 105₂₂₅-105₂₃₉ and 105₂₄₂-105₂₅₆ (i.e., each of the processor blocks in the 8^{th} row of processor blocks, except for the two centrally located processor blocks within this row), processor blocks 105₇₃₇-105₇₅₁ and 105₇₅₄-105₇₆₈ (i.e., each of the processor blocks in the 24th row of processor blocks, except for the two centrally located processor blocks within this row), the processor blocks 105₁₂₄₉-105₁₂₆₃ and 105₁₂₆₆-105₁₂₈₀ (i.e., each of the processor blocks in the 40th row of processor blocks, except for the two centrally located processor blocks within this row) and each of the processor blocks 105₁₇₆₁-105₁₇₇₅ and 105₁₇₇₈-105₁₇₉₂ (i.e., each of the processor blocks in the 56^{th} row of processor blocks, except for the two centrally located processor blocks within this row). The processor blocks including a regional vertical transport controller are shown with similar shading in FIG. 27.

In addition to the circuit elements included in processor block 105₁, a second subset of the processor blocks of ASIC controller chip 105 also include a long-distance vertical transport controller, which allows for long vertical communication ‘hops’ from the ASIC controller chip 105 to the vertically aligned communication management chip COM₀ (FIG. 26). In the embodiment illustrated by FIG. 27, the second subset of processor blocks on ASIC controller chip 105 includes processor blocks 105₂₅₇-105₂₇₁ and 105₂₇₄-105₂₈₈ (i.e., each of the processor blocks in the 9^{th} row of processor blocks, except for the two centrally located processor blocks within this row), processor blocks 105₇₆₉-105₇₈₃ and 105₇₈₆-105₈₀₀ (i.e., each of the processor blocks in the 25th row of processor blocks, except for the two centrally located processor blocks within this row), the processor blocks 105₁₂₈₁-105₁₂₉₅ and 105₁₂₉₈-105₁₃₁₂ (i.e., each of the processor blocks in the 41^{st} row of processor blocks, except for the two centrally located processor blocks within this row) and each of the processor blocks 105₁₇₉₃-105₁₈₀₇ and 105₁₈₁₀-105₁₈₂₄ (i.e., each of the processor blocks in the 57^{th} row of processor blocks, except for the two centrally located processor blocks within this row). The processor blocks including a long-distance vertical transport controller are shown with similar shading in FIG. 27.

FIG. 32 is a block diagram of the first seventeen processor blocks 105₁, 105₃₃, 105₆₅, 105₉₇, 105₁₂₉, 105₁₆₁, 105₁₉₃, 105₂₂₅, 105₂₅₇, 105₂₈₉, 105₃₂₁, 105₃₅₃, 105₃₈₅, 105₄₁₇, 105₄₄₉, 105₄₈₁, and 105₅₁₃, included in the first column of processor blocks within ASIC controller chip 105.

Processor blocks 105₁, 105₃₃, 105₆₅, 105₉₇, 105₁₂₉, 105₁₆₁, 105₁₉₃, 105₂₂₅, 105₂₅₇, 105₂₈₉, 105₃₂₁, 105₃₅₃, 105₃₈₅, 105₄₁₇, 105₄₄₉, 105₄₈₁, and 105₅₁₃ include processor nexuses, 10₁-10₁₇, respectively, TSV connector sets 15₁-15₁₇, respectively, and local vertical transport controllers 20₁-20₁₇, respectively. All of the local vertical transport controllers 20₁-20₈ are coupled to one another, and to regional vertical transport controller 30₁ by local vertical communication path 35₁, which is implemented by metal lines on underlying silicon substrate interconnect structure 2610. Similarly, all of the local vertical transport controllers 20₉-20₁₆ are coupled to one another, and to regional vertical transport controller 30₁ by local vertical communication path 35₂, which is implemented by metal lines on underlying silicon substrate interconnect structure 2610. Local vertical communication path 35₁ enables communication (and the transfer of data) between any/all of the local vertical transport controllers 20₁-20₈ (as well as regional vertical transport controller 30₁). Similarly, local vertical communication path 35₂ enables communication (and the transfer of data) between any/all of the local vertical transport controllers 20₉-20₁₆ (as well as regional vertical transport controller 30₁). Regional vertical transport controller 30₁ enables the transfer of data between the local vertical transport controllers 20₁-20₈ and the local vertical transport controllers 20₉-20₁₆.

The regional vertical transport controller 30₁ is also coupled to a vertically aligned regional vertical transport controller by a regional vertical communication path 60₁, which is described in more detail below.

Although each of the local vertical communication paths 35₁ and 35₂ is illustrated as a single continuous bus in FIG. 32, it is understood that local vertical communication paths 35₁ and 35₂ are sub-divided into a plurality of smaller segments (or wheels) to enable flexible transmission of data between the corresponding local vertical transport controllers 20₁-20₈ and 20₉-20₁₆ and to avoid direct long distance signal transmission. The local vertical communication paths 35₁ and 35₂ and the regional vertical transport controller 30₁ are designed to have enough bandwidth to keep data moving continuously between the processor nexuses 10₁-10₁₆, with no gaps or stalls.

Local vertical transport controller 20₁₇ is included in a third set of eight local vertical transport controllers (20₁₇-20₂₄), which extend vertically below the first two sets of eight local vertical transport controllers 20₁-20₈ and 20₉-20₁₆. This third set of eight local vertical transport controllers are commonly coupled by another local vertical communication path 35₃, which is similar to the above-described local vertical communication paths 35₁ and 35₂. In accordance with one embodiment, a vertical bridge circuit 45₁ is located between the vertical communication paths 35₂ and 35₃. This bridge circuit 45₁ may be located within processor block 105₄₈₁ and/or processor block 105₅₁₃. Vertical bridge circuit 45₁ receives the information transmitted on both vertical communication paths 35₂ and 35₃. If vertical bridge circuit 45₁ detects information on communication path 35₃ that addresses one of the processor nexuses 10₁-10₁₆ associated with one of the vertical communication paths 35₁ or 35₂, then vertical bridge circuit 45₁ transmits this information onto vertical communication path 35₂. Conversely, if vertical bridge circuit 45₁ detects information on communication path 35₂ that addresses one of the processor nexuses associated with the vertical communication path 35₃, then vertical bridge circuit 45₁ transmits this information onto vertical communication path 35₃.

In one embodiment, the local vertical communication paths 35₁, 35₂ and 35₃, the regional vertical transport controller 30₁ and the vertical bridge circuit 45₁ are designed to have enough bandwidth to keep data moving continuously between the processor nexuses 10₁-10₁₆, and the next eight vertically located processor nexuses 10₁₇-10₂₄ with no gaps or stalls.

This pattern is repeated vertically within the first column of processor blocks of ASIC controller chip 105, such that vertical bridge circuits (identical to vertical bridge circuit 45₁) are located between the ends of vertical communication paths that end in processor blocks 105₉₉₃ and 105₁₀₂₅, and between the ends of vertical communication paths that end in processor blocks 105₁₅₀₅ and 105₁₅₃₇. This pattern of vertical bridge circuits is also repeated horizontally (along the X-axis) within each column of processor blocks within ASIC controller chip 105.

In addition, processor block 105₂₅₇ includes long-distance vertical transport controller 40₁. Long-distance vertical transport controller 40₁ is coupled to regional vertical transport controller 30₁ via regional vertical communication path 50₁, which enables communication (and the transfer of data) between long-distance vertical transport controller 40₁ and regional vertical transport controller 30₁. In one embodiment, regional vertical communication path 50₁ is implemented by metal lines on underlying silicon substrate interconnect structure 2610. In another embodiment, regional vertical communication path 50₁ is implemented by lines fabricated on the ASIC controller chip 105. Long-distance vertical transport controller 40₁ is also coupled to communication management chip COM₀ through long-distance vertical communication path 70₁, which is implemented by metal lines on underlying silicon substrate interconnect structure 2610. In one embodiment, long-distance vertical transport controller 40₁ is a PAM4 controller that transfers data to/from communication management chip COM₀ at a rate of 25-50 GHz.

In one embodiment, the pattern of FIG. 32 is repeated both horizontally and vertically across the ASIC controller chip 105. Each of the ASIC controller chips included in MTDRAM processor systems MDP₁-MDP₆₃ have the same horizontal and vertical routing structures as those described above for the ASIC controller chip 105 of MTDRAM processor system MDP₀.

Although the long-distance vertical transport controllers and the regional vertical transport controllers are located in two adjacent rows of processor blocks in FIGS. 27 and 31, it is understood that the long-distance vertical transport controllers and the regional vertical transport controllers may be fitted within a single row of processor blocks in an alternate embodiment (shortening the lines required to transmit data between these long-distance and regional vertical transport controllers, advantageously saving some power and area).

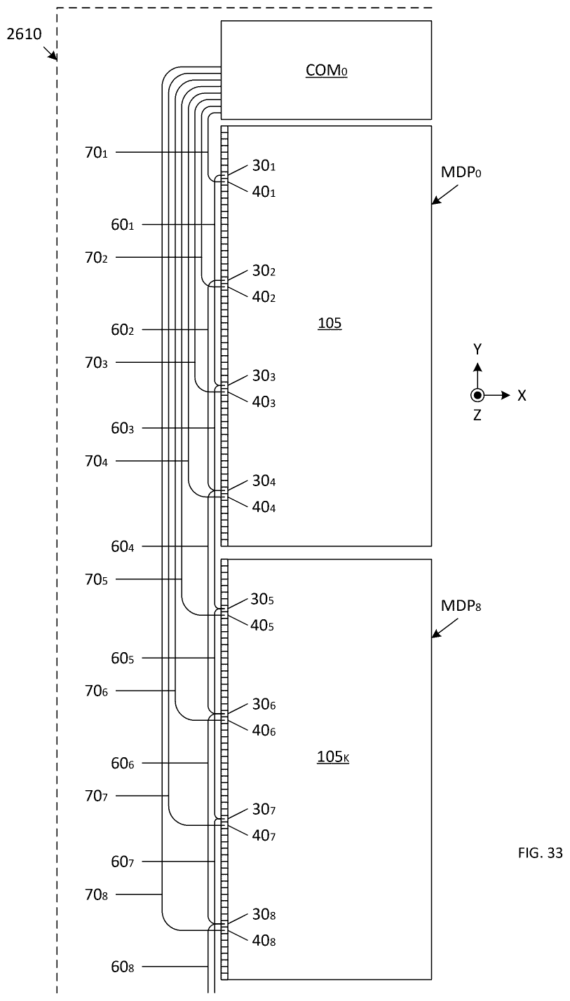

FIG. 33 is a block diagram illustrating the vertical routing of data between communication management chip COM, the first column of processor blocks in ASIC controller chip 105 of MTDRAM processor system MDP₀ and the first column of processor blocks in the ASIC controller chip 105_{K} of vertically adjacent MTDRAM processor system MDP₈.

FIG. 33 illustrates the regional vertical transport controller 30₁ present in processor block 105₂₂₅ and the long-distance vertical transport controller 40₁ present in processor block 105₂₅₇, which are described above in connection with FIGS. 27 and 32.

In addition, FIG. 33 illustrates regional vertical transport controllers 30₂, 30₃, and 30₄, which are present in processor blocks 105₇₃₇, 105₁₂₄₉, and 105₁₇₆₁, respectively, on ASIC controller chip 105. FIG. 33 also illustrates regional vertical transport controllers 30₅, 30₆, 30₇, and 30₈, which are laid out in a manner similar to vertical transport controllers 30₁, 30₂, 30₃, and 30₄, respectively, within ASIC controller chip 105_{K}. In the described embodiment, regional vertical transport controllers 30₂-30₈ have the same configuration as regional vertical transport controller 30₁.

Every other vertically adjacent regional vertical transport controller is coupled to one another. Thus, regional vertical transport controllers 30₁ and 30₃ are coupled by corresponding regional vertical communication path 60₁ and regional vertical transport controllers 30₂ and 30₄ are coupled by corresponding regional vertical communication path 60₂. Similarly, regional vertical transport controller pairs 30₃ and 30₅, 30₄ and 30₆, 30₅ and 30₇ and 30₆ and 30₈, are coupled by corresponding regional vertical communication paths 60₃, 60₄, 60₅ and 60₆, respectively. This pattern is repeated vertically throughout the arrayed processor system 2600. For example, a regional vertical communication paths 60₇ and 60₈ further couple regional vertical transport controllers 30₇ and 30₈ to corresponding regional vertical transport controllers within MTDRAM processor system MDP₁₆. In the described embodiment, the regional vertical communication paths (e.g., 60₁-60₈) of arrayed processor system 2600 are implemented by metal traces in the underlying silicon substrate interconnect structure 2610. The regional vertical communication paths specified above enable rapid communication (and the transfer of data) between processor blocks that are separated by large vertical distances (along the Y-axis).

Although FIG. 33 illustrates regional vertical transport controllers and regional vertical communication paths associated with the first column of processor blocks within the first column of ASIC controller chips within the arrayed processor system 2600, it is understood that all columns of processor blocks within the arrayed processor system 2600 (that are capable of vertical communication) include regional vertical transport controllers and corresponding regional vertical communication paths configured in the manner described above.

In one embodiment, the regional vertical transport controllers transmit data on the corresponding regional vertical communication paths at an intermediate frequency which is greater than the operating frequency of the MTDRAM unit cells (e.g., 1 to 2 GHz). This advantageously allows for rapid vertical transfer of data throughout the arrayed processor system 2600.

FIG. 33 also illustrates long-distance vertical transport controllers 40₂, 40₃, and 40₄, which are present in processor blocks 105₇₆₉, 105₁₂₈₁, and 105₁₇₉₃, respectively, on ASIC controller chip 105. FIG. 33 also illustrates long-distance vertical transport controllers 40₅, 40₆, 40₇, and 40₈, which are laid out in a manner similar to long-distance vertical transport controllers 40₁, 40₂, 40₃, and 40₄, respectively, within ASIC controller chip 105_{K}. In the described embodiment, long-distance vertical transport controllers 40₂-40₈ have the same configuration as long-distance vertical transport controller 40₁. Long-distance vertical transport controllers 40₁-40₈ are locally coupled to corresponding regional vertical transport controllers 30₁-30₈, respectively (in the manner illustrated by FIG. 32). In addition, each of the long-distance vertical transport controllers 40₁-40₈ is coupled to communication management chip COM₀ by a corresponding long-distance vertical communication path 70₁-70₈, respectively. This pattern repeats vertically throughout the arrayed processor system 2600. For example, four long-distance vertical communication paths couple four corresponding long-distance vertical transport controllers within MTDRAM processor system MDP₁₆ to communication management chip COM₀. As described above, each of the long-distance vertical communication paths (e.g., 70₁-70₈) of arrayed processor system 2600 are implemented by metal traces in the underlying silicon substrate interconnect structure 2610.

Although FIG. 33 illustrates long-distance vertical transport controllers and long-distance vertical communication paths associated with the first column of processor blocks within the first column of ASIC controller chips within the arrayed processor system 2600, it is understood that all columns of processor blocks within the arrayed processor system 2600 (that are capable of vertical communication) include long-distance vertical transport controllers and corresponding long-distance vertical communication paths configured in the manner described above.

The above-described configuration enables flexible routing of data within arrayed processor system 2600. More specifically, data can be transmitted horizontally between any pair of processor blocks in the same row of the arrayed processor system 2600 using the horizontal transport mechanisms described in connection with FIGS. 27-30. Similarly, data can be transmitted vertically between any pair of processor blocks in the same column of the arrayed processor system 2600 (except for the pair of centrally located columns of processor blocks within each ASIC controller chip) using the vertical transport mechanisms described in connection with FIGS. 27 and 31-33. “Diagonal” data transfer between pairs of processor blocks not located in the same row/column of the arrayed processor system 2600 is accomplished using a combination of both the above-described horizontal and vertical transport mechanisms. Data transfer between a processor block of the arrayed processor system 2600 and a processor external to arrayed processor system 2600 is accomplished by transferring data along a communication path that includes a long-distance vertical transport controller, a long-distance vertical communication path, one of the communication management chips COM₀-COM₇, and one of the optical links OPT₀-OPT₁.

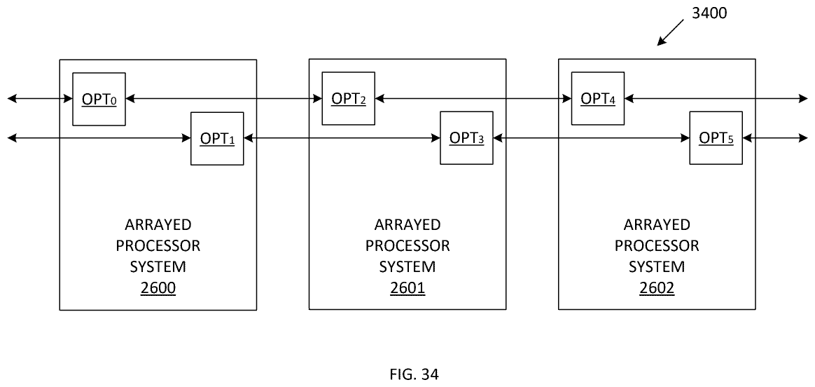

In accordance with one variation of the embodiments described above, a plurality of arrayed processor systems, each similar to (or identical to) arrayed processor system 2600 can be interconnected, effectively creating an expanded arrayed processor system. FIG. 34 is a block diagram of an expanded arrayed processor system 3400, which includes arrayed processor systems 2600 (FIG. 26), 2601 and 2602. Arrayed processor systems 2601 and 2602 include high-sped optical communication links OPT₂-OPT₃ and OPT₄-OPT₅, respectively. Although not illustrated by FIG. 34, it is understood that arrayed processor systems 2601-2602 also include an array of MTDRAM processor systems (identical or similar to MTDRAM processor systems MDP₀-MDP₆₃), communication control chips (identical or similar to communication control chips COM₀-COM₇), power management chips (identical or similar to power management chips PMC₀-PMC₇), a power supply/cooling structure (identical or similar to power supply/cooling structure 2605), and optionally, a plurality of stacked flash memory (identical or similar to stacked flash memory systems FMS₀-FMS₁₅). Data is transferred between arrayed processor systems 2600-2602 via optical communication links OPT₀, OPT₂ and OPT₃, and/or via optical communication links OPT₁, OPT₃ and OPT₅, as illustrated.

In accordance with other embodiments of the present invention, the single-ended sense amplifiers included in the primary sense amplifier circuits can have configurations other than those described above in connection with FIGS. 8, 11A and 11B.

FIG. 35 is a circuit diagram of single-ended sense amplifiers SA′_{0,1} and SA′_{0,3} of primary sense amplifier circuit PSA_{1,0} in accordance with an alternate embodiment of the present invention. Single ended sense amplifiers SA′_{0,1} and SA′_{0,3} are similar to single ended sense amplifiers SA_{0,1} and SA_{0,3} (FIG. 8), with differences noted below. Single ended sense amplifiers SA′_{0,1} and SA′_{0,3} do not include the kick capacitors 821-824 of single ended sense amplifiers SA_{0,1} and SA_{0,3}. In addition, single ended sense amplifiers SA′_{0,1} and SA′_{0,3} do not require the NCOM control signal (which is coupled to n-channel transistors N1-N4 of single ended sense amplifiers SA_{0,1} and SA_{0,3}). Rather, the sources of n-channel transistors N1-N4 are simply connected to ground (0V) in single ended sense amplifiers SA′_{0,1} and SA′_{0,3}. Advantageously, the primary sense amplifier driver circuit PSAD_{1,0} of FIG. 35 does not need to generate the kick voltage signal Vk or the NCOM signal in the manner described above in connection with FIGS. 11A-11B.

The sources of n-channel pre-charge transistors N12 and N14 are coupled to receive a reference voltage signal Vref in accordance with the present embodiment of the invention. As described in more detail below, the n-channel pre-charge transistors N12 and N14 are controlled to apply the reference voltage signal Vref to the internal nodes INT0 # and INT2 #, respectively. Note that the primary sense amplifier driver circuit PSAD_{1,0} of FIG. 35 generates the reference voltage signal Vref in the present embodiment.

Before describing the operation of single-ended sense amplifiers SA′_{0,1} and SA′_{0,3}, the operating characteristics of a conventional dual-ended sense amplifier will be described for comparison purposes. A conventional dual-ended sense amplifier is coupled to a bit line of a bit cell being read, and also to a dummy bit line. This bit line and dummy bit line are pre-charged to an intermediate voltage that is half the logic ‘1’ voltage written to the bit cell. For example, if the logic ‘1’ voltage written to the bit cell is 1.1 Volts, then the bit line pre-charge voltage is 550 mV. The DRAM bit cell loses charge over time, and therefore must be periodically refreshed. In one example, the refresh interval of the DRAM bit cell is 32 msec, wherein the ‘1’ bit cell voltage stored by the bit cell drops by about 14% at the end of the 32 msec refresh interval. In the example described herein, the DRAM bit cell is refreshed by the time the logic ‘1’ bit cell voltage reaches 0.95 V.

The change in the bit line voltage (ΔV) during a read operation is defined by the following equation:

$$ΔV = ( Vbitcell - {V}_{BLP} ) / ( 1 + {C}_{B} / {C}_{S} ) ,$$

wherein Vbitcell is the bit cell voltage stored by the DRAM bit cell at the time of the read operation (e.g., 1.1 to 0.95V), V_{BLP} is the pre-charge voltage of the bit line (e.g., 0.55V), C_{B} is the capacitance of the bit line, and C_{S} is the capacitance of the DRAM bit cell. Common values for C_{B}/C_{S} are 4, 6 and 8. Thus, in a conventional dual-ended sense amplifier, ΔV is about 80 mV, 57 mV and 44 mV (at the end of the 32 msec refresh interval) for C_{B}/C_{S} values of 4, 6 and 8, respectively. Note that a bit line being read in one direction (e.g., being pulled up in response to a logic ‘1’ bit cell) may be located adjacent to other bit lines being read in the opposite direction (e.g., being pulled down in response to a logic ‘0’ bit cell). In this case, the voltage on a bit line being read in one direction can be pulled in the other direction due to bit line coupling. Common bit line coupling estimates include 15%, 25% and 35%. In the example given above for a conventional dual-ended sense amplifier, the above-described ΔV values of 80/57/44 mV would be adjusted down to 60/43/33 mV (for C_{B}/C_{S} values of 4/6/8, respectively) for an adverse bit line coupling of 25%.

In accordance with one embodiment, the value of the reference voltage Vref implemented within the single-ended sense amplifiers SA′_{0,1} and SA′_{0,3} of FIG. 35 is selected to provide an equivalent ΔV with respect to the above-described dual-ended sense amplifier. In accordance with the present embodiment, the logic ‘0’ bit cell value is 0 Volts (e.g., bit line bl_{0,1} is pulled down to 0 Volts to write a logic ‘0’ value to the corresponding bit cell bc_{0,1}). Thus, when reading a logic ‘0’ value from bit cell bc_{0,1} (or bc_{0,3}), the voltage on the corresponding bit line bl_{0,1} (or bl_{0,3}) will be equal to 0 Volts (without considering adverse bit line coupling). In order to obtain a ΔV value of 60/43/33 mV (to match the performance of the above-described dual-ended sense amplifier), the nominal value of Vref should be 60/43/33 mV (for DRAM systems with C_{B}/C_{S}=4/6/8, respectively). In this case, the nominal value of a logic ‘1’ value read on the bit line bl_{0,1} (or bl_{0,3}) should be equal to 120/86/66 mV (i.e., 60/43/33 mV+60/43/33 mV=120/86/66 mV). To achieve read bit line voltages of 120/86/66 mV based on C_{B}/C_{S} values of 4/6/8, the corresponding bit cell voltages must be at least 600/602/594 mV (i.e., 120/86/66 mV×(1+4)/(1+6)/(1+8)=600/602/594 mV). In order to ensure a minimum bit cell voltage of at least 600/602/594 mV at the end of a refresh interval, the DRAM bit cell should initially be written to a bit cell voltage that is about 14% greater, or 698/700/691 mV. In this instance, the maximum read bit line voltage (assuming the read operation occurs immediately after a refresh operation) is about 140/100/77 mV (i.e., 698/700/691 mV divided by (1+4)/(1+6)/(1+8)=140/100/77 mV).

Assuming that a bit line reading a logic ‘0’ value experiences 25% adverse bit line coupling from adjacent bit lines reading logic ‘1’ values, the bit line reading a logic ‘0’ value may be pulled up from 0 Volts to 35/25/19 mV (i.e., 140/100/77 mV×25%=35/25/19 mV). To compensate for this bit line coupling, the value of Vref can be adjusted upward to 95/68/52 mV (i.e., because the voltage level of a logic ‘0’ bit line can be pulled up from 0 Volts to 35/25/19 mV by adverse bit line coupling, the nominal value of Vref is adjusted upward from 60/43/33 mV by adding 35/25/19 mV to provide 95/68/52 mV). In this case, the nominal value of a logic ‘1’ value read on the bit line bl_{0,1} (or bl_{0,3}) should be adjusted up to at least 155/111/85 mV (i.e., 95/68/52 mV+60/43/33 mV=155/111/85 mV) to maintain the specified ΔV values of 60/43/33 mV. To achieve read bit line voltages of 155/111/85 mV based on C_{B}/C_{S} values of 4/6/8, the corresponding bit cell voltages must be at least 775/777/765 mV (i.e., 155/111/85 mV×(1+4)/(1+6)/(1+8)=775/777/765 mV). In order to ensure a minimum bit cell voltage of at least 775/777/765 mV at the end of a refresh interval, the DRAM bit cell should initially be written to a bit cell voltage that is about 14% greater, or 901/904/890 mV. In this instance, the maximum read bit line voltage (assuming the read operation occurs immediately after a refresh operation) is about 180/129/99 mV for C_{B}/C_{S} values of 4/6/8, respectively (i.e., 901/904/890 mV divided by (1+4)/(1+6)/(1+8)=180/129/99 mV).

Assuming 25% adverse bit line coupling from adjacent bit lines reading logic ‘1’ values, a bit line reading a logic ‘0’ value may be pulled up from 0 Volts to 45/32/25 mV (i.e., 180/129/99 mV×25%=45/32/25 mV). Again, to compensate for this bit line coupling, the value of Vref can be adjusted upward to 105/75/58 mV (i.e., because the voltage level of a logic ‘0’ bit line can be pulled up from 0 Volts to 45/32/25 mV by adverse bit line coupling, the value of Vref is adjusted to 60/43/33 mV+45/32/25 mV=105/75/58 mV).

As described above, adjusting the value of Vref may necessitate adjusting the nominal voltage of a logic ‘1’ value read on a bit line, the logic ‘1’ bit cell voltage, and the bit cell coupling voltage (which in turn, necessitates adjusting the value of Vref). Over a plurality of iterations, these adjustments converge to a final set of values, wherein the final iteration is selected in view of the required accuracy of the particular application. In the present example, four iterations results in a bit line coupling voltage of 49/35/27 mV, a reference voltage Vref of 109/78/60 mV, a nominal logic ‘1’ read bit line voltage of 169/121/93 mV and a full DRAM bit cell voltage of 983/985/973 mV (for C_{B}/C_{S} of 4/6/8, respectively). Having determined these voltages (to establish a ΔV equivalency with a conventional dual-ended sense amplifier), the operation of single-ended sense amplifiers SA′_{0,1} and SA′_{0,3} will now be described.

In the examples provided below, read accesses are performed to bit cells bc_{0,1} and bc_{0,3} coupled to bit lines bl_{0,1} and bl_{0,3}, respectively, wherein the bit cell bc_{0,1} stores a logic ‘1’ bit cell voltage, and the bit cell bc_{0,3} stores a logic ‘0’ bit cell voltage. Bit cells bc_{0,1} and bc_{0,3} are coupled to receive a common sub-word line signal SWL_{0,0}, as illustrated.

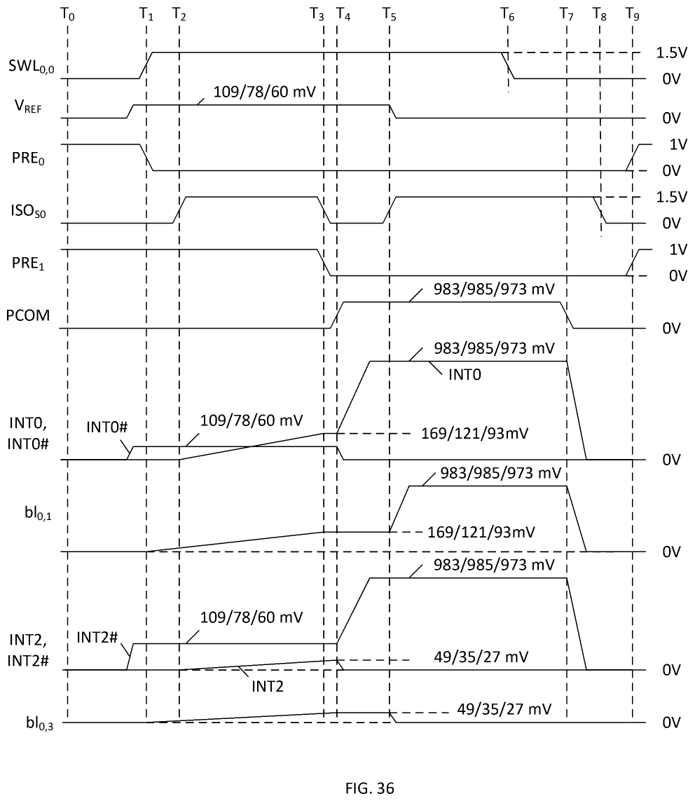

FIG. 36 is a waveform diagram illustrating signals associated with a read access to bit cells bc_{0,1} and bc_{0,3}.

At time T0, the sub-word line SWL_{0,0} is at a logic low state (0V) and the reference voltage signal Vref is at ground (0V). The pre-charge control voltages PRE₀ and PRE₁ are activated high (1V), thereby turning on the pre-charge transistors N11-N14. Under these conditions, the internal nodes INT0/INT0 # and INT2/INT2 # are all pulled down to ground. The ISO_{S0} and ISO_{S1} signals are deactivated low (0V), thereby isolating the single-ended sense amplifiers SA_{0,1} and SA_{0,3} from the bit lines bl_{0,1} and bl_{0,3} (and the bit lines bl_{1,1} and bl_{1,3}). The PCOM signal is held at logic low state (0V) and the bit lines bl_{0,1} and bl_{0,3} are pre-charged to ground (0V).

The read operation starts at time T1. Just prior to time T1, the reference voltage signal Vref is driven to a predetermined positive voltage, thereby pre-charging the voltages on internal nodes INT0 # and INT2 # to the predetermined reference voltage Vref of 109/78/60 mV (for C_{B}/C_{S} of 4/6/8, respectively). As described in more detail below, the read voltages developed on the bit lines bl_{0,1} and bl_{0,3} are compared with the reference voltage Vref within the sense amplifier circuits SA′_{0,1} and SA′_{0,3}, respectively.

Because there is no/negligible current flow on bit lines reading a logic ‘0’ value (because the bit lines are pre-charged to 0V, and remain near 0V during a read operation), there is no significant adverse bit line coupling associated with bit lines reading a logic ‘1’ value. Thus, when reading a logic ‘1’ value from bit cell bc_{0,1} (or bc_{0,3}), in order to obtain a ΔV value of 60/43/33 mV (to match the performance of the above-described dual-ended sense amplifier), the voltage developed on the read bit line should therefore be at least as great as the sum of the Vref reference voltage of 109/78/60 mV plus the ΔV value of 60/43/33 mV, or 169/121/93 mV. A logic ‘1’ bit read line voltage of 169/121/93 mV translates to a bit cell voltage of 845/847/837 mV for C_{B}/C_{S}=4/6/8 (i.e., 169/121/93 mV×(1+Cb/Cs)=845/847/837 mV). In order to ensure a minimum bit cell voltage of 845/847/837 mV at the end of a refresh interval, the bit cell should initially be written to a full bit cell voltage that is about 14% greater, or 983/985/973 mV (for C_{B}/C_{S}=4/6/8).

Returning to FIG. 36, at time T1, the sub-word line SWL_{0,0} is activated high (1.5V). Under these conditions, read voltages are developed on the bit lines bl_{0,1} and bl_{0,3}, wherein these read voltages are dependent upon the data values stored by the corresponding bit cells coupled to these bit lines. In the illustrated embodiment, bit line bl_{0,1} begins to be pulled up from the bit line pre-charge voltage of 0V towards the logic ‘1’ read bit line voltage level (e.g., 169/121/93 mV or more, as described above). Although bit line bl_{0,3} should be held at a logic ‘0’ value equal to 0 Volts, in a worst case situation, bit line bl_{0,3} is surrounded by a plurality of adjacent bit lines all being pulled up to a logic “1” read voltage level. In this case, bit line bl_{0,3} begins to be slightly pulled up from the bit line pre-charge voltage of 0V, due to adverse bit line coupling with the logic ‘1’ read voltages being developed on adjacent bit line bl_{0,1} and other adjacent bit lines. As described above, this adverse bit line coupling may pull up the voltage on bit line bl_{0,3} to a voltage as high as about 49/35/27 mV (for C_{B}/C_{S}=4/6/8).

Also at time T1, the pre-charge control signal PRE₀ is deactivated low (0V), thereby turning off n-channel transistors N11 and N13, such that the internal nodes INT0 and INT2 are no longer actively pulled down to ground.

At time T2 (shortly after time T1), the ISO_{S0} signal is activated high (1.5V), thereby turning on n-channel transistors 801 and 802, such that the read voltages developed on bit lines bl_{0,1} and bl_{0,3} are applied to internal nodes INT0 and INT2, respectively. Thus, as illustrated by FIG. 36, the voltage on internal node INT0 begins to increase toward the logic ‘1’ read bit line voltage of 169/121/93 mV, and the voltage on internal node INT2 begins to increase toward 49/35/27 mV (in the worst case) due to adverse bit line coupling.

The voltages on nodes INT0 and INT2 are allowed to develop until time T3. By time T3, the voltages on bit line bl_{0,1} and internal node INT0 have reached a read bit line voltage of at least 169/121/93 mV (described above), and the voltage on internal node INT2 reaches as high as 49/35/27 mV (worst case) due to adverse bit line coupling. At time T3, the pre-charge control signal PRE₁ is deactivated low, thereby turning off transistors N12 and N14, such that the internal nodes INT0 # and INT2 # are no longer actively driven to the reference voltage Vref of 109/78/60 mV.

Also at time T3, the ISO_{S0} signal is deactivated low (0V), thereby turning off n-channel transistors 801 and 802, temporarily isolating bit lines bl_{0,1} and bl_{0,3} from the internal nodes INT0 and INT2, respectively.

At time T4 (immediately after de-activating the pre-charge control signal PRE₁ and the ISO_{S0} signals), the PCOM signal is activated to the logic high bit cell voltage (983/985/973 mV), thereby activating the single ended sense amplifier circuits SA_{0,1} and SA_{0,3}. Under these conditions, sense amplifier circuit SA′_{0,1} amplifies the voltage difference between the signals on internal nodes INT0 and INT0 #, and sense amplifier circuit SA_{0,3} amplifies the voltage difference between the signals on internal nodes INT2 and INT2 #. In the illustrated example, the voltage on internal node INT0 is at least 169/121/93 mV, and the reference voltage on node INT0 # is 109/78/60 mV (for a ΔV of 60/43/33 mV). Within single-ended sense amplifier SA′_{0,1}, the relatively low voltage on internal node INT0 # causes transistor P2 to turn on first as the PCOM voltage transitions high, which increases the differential voltage between internal nodes INT0 and INT0 #, until the voltage on internal node INT0 becomes high enough to cause transistor N1 to turn on.

As a result, the voltage on internal node INT0 is pulled up to the full PCOM voltage of 983/985/973 mV, and the voltage on node INT0 # is pulled down to ground (0V). Note that during this initial sensing phase, it is important to balance the capacitances of internal nodes INT0 and INT0 #. Turning off isolation transistor 801 during this initial sensing phase temporarily decouples the capacitance of bit line bl_{0,1} from internal node INT0, such that the capacitance of internal node INT0 more nearly matches the capacitance of INT0 # during this initial sensing phase.

Similarly, sense amplifier circuit SA_{0,3} amplifies the voltage difference between the signals on internal nodes INT2 and INT2 #. In the illustrated example, the voltage on internal node INT2 is 49/35/27 mV due to worst case adverse bit line coupling of adjacent logic ‘1’ bit lines, and the reference voltage on internal node INT2 # is 109/78/60 mV (for a ΔV of 60/43/33 mV). Within single-ended sense amplifier SA_{0,3}, the relatively low voltage on internal node INT2 causes transistor P3 to turn on first as the PCOM voltage transitions high, which increases the differential voltage between internal nodes INT2 and INT2 #, until the voltage on the internal node INT2 # becomes high enough to cause transistor N4 to turn on. As a result, the voltage on internal node INT2 # is pulled up to the full PCOM voltage of 983/985/973 mV, and the voltage on node INT2 is pulled down to ground (0V).

At time T5 (after a full signal swing of 983/985/973 mV is developed across each pair of internal nodes INT0/INT0 # and INT2/INT2 #), the ISO_{S0} signal is re-activated high (1.5V), thereby turning on isolation transistors 801 and 802 and re-coupling bit lines bl_{0,1} and bl_{0,3} to internal nodes INT0 and INT2, respectively. Under these conditions, bit lines bl_{0,1} and bl_{0,3} are driven to 983/985/973 mV and 0V, respectively, thereby refreshing the data values in the corresponding bit cells bc_{0,1} and bc_{0,3}, respectively. Although the example of FIG. 36 shows that the isolation transistors 801 and 802 are re-activated after the full signal swing of 983/985/973 mV has been developed across each pair of internal nodes INT0/INT0 # and INT2/INT2 #, in an alternate embodiment, the isolation transistors 801 and 802 are re-activated when the signal swing across each pair of internal nodes is less than the full signal swing of 983/985/973 mV, but large enough to overcome the capacitances introduced by bit lines bl_{0,1} and bl_{0,3} when the isolation transistors 801 and 802 are re-activated. Also at time T5, the reference voltage signal Vref is driven to ground (for power savings).

At time T6, the sub-word line SWL_{0,0} is deactivated, thereby turning off the access transistors of bit cells bc_{0,1} and bc_{0,3} (isolating the bit lines bl_{0,1} and bl_{0,3} from the cell capacitors of bit cells bc_{0,1} and bc_{0,3}). At this time, the data values read from bit cells bc_{0,1} and bc_{0,3} have been restored to these bit cells.

At time T7, the PCOM control signal is driven to ground. As a result, the INT0 and INT2 # voltages are also driven to ground. At this time, the INT0 node is still coupled to bit line bl_{0,1} (through isolation transistor 801), so the voltage on bit line bl_{0,1} is also driven to ground. Bit line bl_{0,3} remains at ground during this time, such that bit lines bl_{0,1} and bl_{0,3} are both pre-charged to ground.

At time T8, the ISO_{S0} voltage is driven to ground, turning off isolation transistors 801 and 802, and isolating the primary sense amplifiers SA′_{0,1} and SA′_{0,3} from bit lines bl_{0,1} and bl_{0,3}. At time T9, the pre-charge control voltages PRE₀ and PRE₁ are driven from ground to 1 V to pre-charge the sense amplifiers SA′_{0,1} and SA′_{0,3}, wherein INT0, INT0 #, INT2 and INT2 # are actively pulled to ground by transistors N11, N12, N13, and N14, respectively.

The single-ended sense amplifier specified by FIG. 36 provides bit line CV²f power savings of at least about 20% when compared with the conventional dual-ended sense amplifier, when reading a logic ‘1’ value. That is, the bit line CV²f power of the single-ended sense amplifier of FIG. 36 divided by CV²f power of a dual-ended sense amplifier is at least equal to (0.985×0.985)/(1.1×1.1), or 0.80. The single-ended sense amplifier specified by FIG. 36 provides power savings of 100% when compared with a conventional dual-ended sense amplifier, when reading a logic ‘0’ value (because the bit line being read is maintained at/near ground for the entire read operation, thereby consuming no/negligible power). Assuming that read operations, on average, include half logic ‘1’ values and half logic ‘0’ values, the single-ended sense amplifier specified by FIG. 36 achieves an average power savings of about 60% (100%×50+20%×50=60%), or a power reduction of about 2.5×, with respect to a conventional dual-ended sense amplifier.

Note that in the embodiment illustrated by FIG. 36, the isolation transistors 801-802 (as well as the transistor driving the sub-word line SWL_{0,0}) must be thick oxide transistors that can be overdriven such that the read voltages developed on the bit lines can be provided to the sense amplifier latches, and the full positive voltages developed by the sense amplifier latches can be driven onto the bit lines. Embodiments described below advantageously do not require the thick oxide transistors of the embodiment specified by FIG. 36.

### First Alternate Embodiment

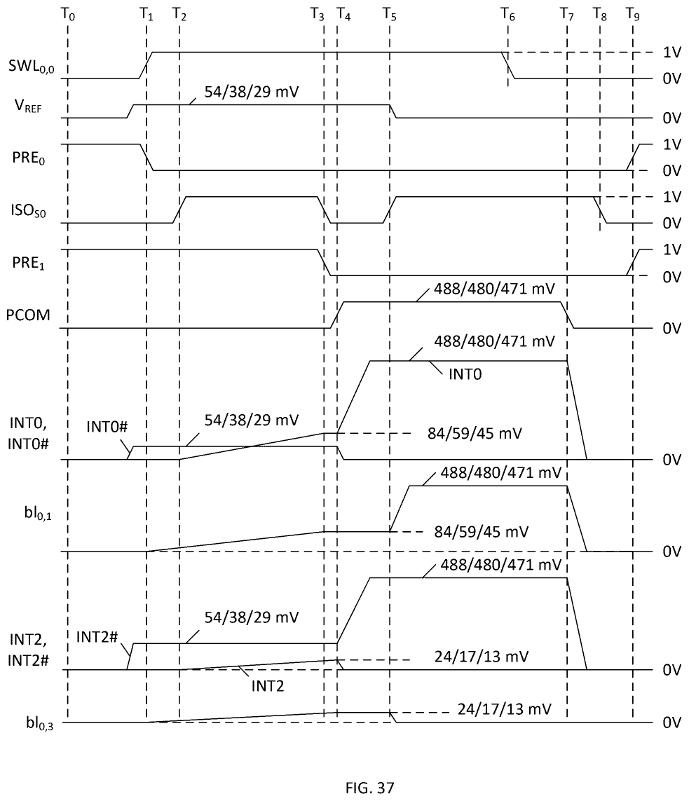

In a first alternate embodiment, the n-channel transistors N1-N4 and the p-channel transistors P1-P4 are fabricated in accordance with MST technology, which includes a superlattice channel extending between source and drain regions of these transistors. This technology is described in more detail in commonly owned U.S. Pat. Nos. 10,109,342 and 10,107,854, and commonly owned U.S. patent application Ser. No. 18/311,465, which are hereby incorporated by reference in their entirety. Fabricating transistors N1-N4 and P1-P4 with MST technology advantageously allows these transistors to exhibit more precisely defined threshold voltages. As a result, sense amplifiers that implement transistors fabricated with MST technology (hereinafter referred to as ‘MST sense amplifiers’) can more reliably detect a specific bit cell voltage. As a result, the variation of ΔV values capable of being reliably sensed by MST sense amplifiers SA′_{0,1} and SA′_{0,3} are significantly reduced (e.g., about half). Thus, while non-MST sense amplifiers (e.g., the sense amplifiers described above in connection with the embodiment of FIG. 36) may exhibit a ΔV value of 60/43/33 mV, MST sense amplifiers (e.g., the sense amplifiers described below in connection with the embodiment of FIG. 37) advantageously exhibit an improved ΔV value range of about 30/21/16 mV (for C_{B}/C_{S} values of 4/6/8, respectively). That is, the MST sense amplifiers are able to reliably operate at a ΔV value range that is about half of the ΔV value range of a non-MST sense amplifier.

FIG. 37 is a waveform diagram illustrating signals associated with read accesses to bit cells bc_{0,1} and bc_{0,3}, in a first alternate embodiment wherein the n-channel transistors N1-N4 and p-channel transistors P1-P4 are fabricated to include superlattice channel in accordance with MST technology (i.e., sense amplifiers SA′_{0,1} and SA′_{0,3} are MST sense amplifiers).

The waveform diagram of FIG. 37 is similar to the waveform diagram of FIG. 36, with differences noted below. Because the waveform diagram of FIG. 37 corresponds with the use of MST sense amplifiers having a ΔV value of 30/21/16 mV, the nominal value of Vref should initially be 30/21/16 mV. Assuming 25% adverse bit line coupling from adjacent bit lines being pulled up to a logic ‘1’ voltage level, the adjusted value of Vref can be calculated as 54/38/29 mV (over three iterations using the method described above). More specifically, the voltage level of a logic ‘0’ read bit line can be pulled up from 0 Volts to 24/17/13 mV by adverse 25% bit line coupling, such that the adjusted value of Vref is equal to 30/21/16 mV+24/17/13 mV, or 54/38/29 mV (for C_{B}/C_{S} values of 4/6/8, respectively).

When reading a logic ‘1’ value from bit cell bc_{0,1} (or bc_{0,3}), in order to obtain a ΔV value of 30/21/16 mV, the voltage developed on the read bit line should therefore be at least as great as the Vref reference voltage of 54/38/29 mV plus the ΔV value of 30/21/16 mV, or 84/59/45 mV at the end of the refresh interval.

The logic ‘1’ read bit line voltage of 84/59/45 mV translates to bit cell voltages of 420/413/405 mV for C_{B}/C_{S}=4/6/8 (i.e., 84/59/45 mV×(1+Cb/Cs)=420/413/405 mV). In order to ensure a minimum bit cell voltage of 420/413/405 mV at the end of a refresh interval, the bit cell should initially be written to a bit cell voltage that is about 14% greater, or 488/480/471 mV. Because the logic ‘1’ bit cell voltage is only 488/480/471 mV, the isolation transistors 801-802 (and the transistor driving the sub-word line voltage SWL_{0,0}) can be implemented conventional logic transistors, and do not need to be thick oxide transistors (as required in the embodiment of FIG. 36). In addition, the sub-word line voltage SWL_{0,0} (and ISO_{S0} and ISO_{S1} voltages) can be reduced to a voltage of 1V or lower. More specifically, the sub-word line voltage SWL_{0,0} (and ISO_{S0} and ISO_{S1} voltages) only needs to be high enough to ensure that the logic ‘1’ bit cell voltage of 488/480/471 mV is written back to the bit cell.

The waveform diagram of FIG. 37 illustrates the adjusted reference voltage Vref of 54/38/29 mV, the adjusted worst case bit line coupling voltage of 24/17/13 mV, the logic ‘1’ read bit line voltage of 84/59/45 mV, and the logic ‘1’ bit cell voltage of 488/480/471 mV achieved due to the use of MST sense amplifiers. The timing of the various signals is the same as that described above in connection with the waveform diagram of FIG. 36.

The single-ended sense amplifier specified by FIG. 37 provides bit line CV²f power savings of about 80% when compared with the conventional dual-ended sense amplifier, when reading a logic ‘1’ value. That is, the bit line CV²f power of the single-ended sense amplifier of FIG. 37 divided by CV²f power of a dual-ended sense amplifier is equal to at least (0.488×0.488)/(1.1×1.1), or 0.20. The single-ended sense amplifier specified by FIG. 37 provides power savings of 100% when compared with a conventional dual-ended sense amplifier, when reading a logic ‘0’ value (because the bit line being read is maintained at/near ground for the entire read operation, thereby consuming no/negligible power). Assuming that read operations, on average, include half logic ‘1’ values and half logic ‘0’ values, the single-ended sense amplifier specified by FIG. 37 achieves an average power savings of 90% (100%×50+80%×50=90%), or a power reduction of about 10×, with respect to a conventional dual-ended sense amplifier.

### Second Alternate Embodiment

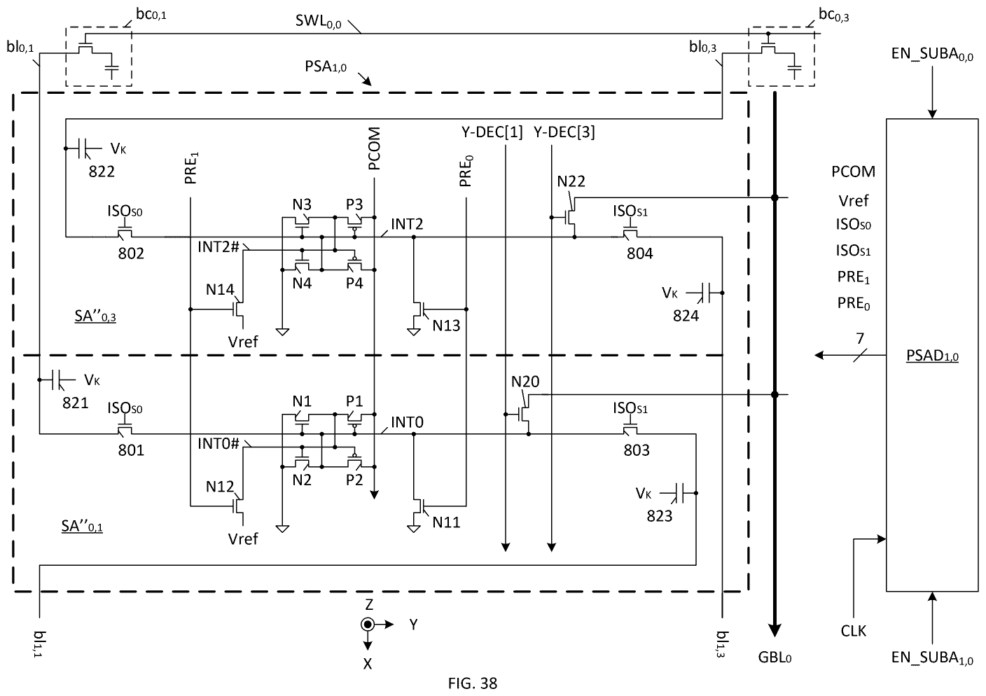

FIG. 38 is a circuit diagram of single-ended MST sense amplifiers SA″_{0,1} and SA″_{0,3} in accordance with a second alternate embodiment of the present invention. Single-ended MST sense amplifiers SA″_{0,1} and SA″_{0,3} are similar to single-ended sense amplifiers SA′_{0,1} and SA′_{0,3} (FIG. 35), with differences noted below. Within single-ended MST sense amplifiers SA″_{0,1} and SA″_{0,3}, n-channel transistors N1-N4 and the p-channel transistors P1-P4 are fabricated in accordance with MST technology (i.e., with superlattice channels extending between the source and drain regions of these transistors), such that the single-ended MST sense amplifiers SA″_{0,1} and SA″_{0,3} exhibit a ΔV value range of 30/21/16 mV (in the manner described above in connection with FIG. 37). In addition, single-ended MST sense amplifiers SA″_{0,1} and SA″_{0,3} include kick capacitors 821, 822, 823 and 824, which are coupled to bit lines bl_{0,1}, bl_{0,3}, bl_{1,1} and bl_{1,3}, respectively.

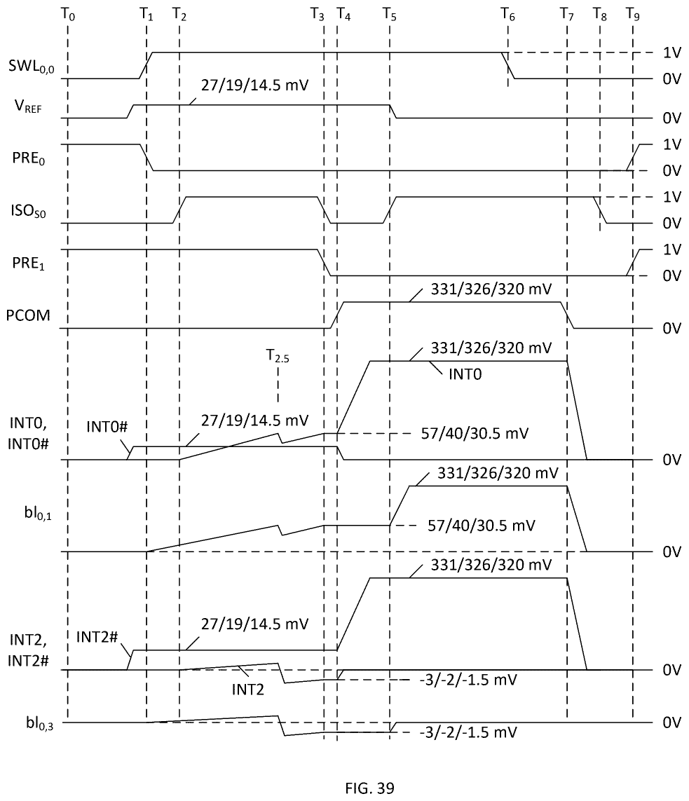

FIG. 39 is a waveform diagram illustrating signals associated with read accesses to bit cells bc_{0,1} and bc_{0,3} in single-ended MST sense amplifiers SA″_{0,1} and SA″_{0,3} in accordance with the second alternate embodiment of the present invention. The waveform diagram of FIG. 39 is similar to the waveform diagram of FIG. 37, with differences noted below.

Because the waveform diagram of FIG. 37 corresponds with the use of MST sense amplifiers having a ΔV value of 30/21/16 mV, the nominal value of Vref should initially be 30/21/16 mV. Assuming 25% adverse bit line coupling from adjacent bit lines being pulled up to a logic ‘1’ voltage level, the adjusted value of Vref can be calculated as 54/38/29 mV (over three iterations using the method described above). More specifically, the voltage level of a logic ‘0’ read bit line can be pulled up from 0 Volts to 24/17/13 mV by adverse 25% bit line coupling, such that the adjusted value of Vref is equal to 30/21/16 mV+24/17/13 mV, or 54/38/29 mV (for C_{B}/C_{S} values of 4/6/8, respectively).

Moreover, in the embodiment of FIGS. 38-39, each of the kick capacitors 821-824 is designed to kick down the voltage on the associated bit lines by half of the adjusted Vref reference voltage of 54/38/29 mV during read operations. More specifically, kick capacitors 821 and 822 are selected to kick down the voltages on bit lines bl_{0,1} and bl_{0,3}, respectively, by −27/−19/−14.5 mV during read accesses to bit cells bc_{0,1} and bc_{0,3}. As a result, the reference voltage Vref required by the single-ended MST sense amplifiers SA″_{0,1} and SA″_{0,3} is similarly reduced from 54/38/29 mV to 27/19/14.5 mV (i.e., 54/38/29 mV−27/19/14.5 mV=27/19/14.5 mV). In the embodiment of FIGS. 38-39, the kick capacitors are controlled to kick down the voltages on bit lines bl_{0,1} and bl_{0,3} between time T2 and time T3 (i.e., at time T2.5). In one embodiment, the kick capacitors are switched on as close to time T3 as possible.

Given a reference voltage Vref of 27/19/14.5 mV, the logic ‘1’ bit line read voltage required by the single-ended MST sense amplifiers SA″_{0,1} and SA″_{0,3} to obtain a ΔV value range of 30/21/16 mV is 57/40/30.5 mV (i.e., 30/21/16 mV+27/19/14.5 mV=57/40/30.5 mV). These logic ‘1’ bit line read voltages are illustrated in FIG. 39. Note that these logic ‘1’ bit line read voltages provide the appropriate ΔV value of 30/21/16 mV when compared to the reference voltage Vref of 27/19/14.5 mV.

The logic ‘1’ bit line read voltage of 57/40/30.5 mV translates to bit cell voltages of 285/280/275 mV for C_{B}/C_{S}=4/6/8 (i.e., 57/40/30.5 mV×(1+Cb/Cs)=285/280/275 mV). In order to ensure a minimum bit cell voltage of 285/280/275 mV at the end of a refresh interval, the bit cell should initially be written to a bit cell voltage that is about 14% greater, or 331/326/320 mV. Because the logic ‘1’ bit cell voltage is only 331/326/320 mV, the isolation transistors 801-802 (and the transistor driving the sub-word line voltage SWL_{0,0}) can be implemented conventional logic transistors, and do not need to be thick oxide transistors (as required in the embodiment of FIG. 36). In addition, the sub-word line voltage SWL_{0,0} (and the ISO_{S0} and ISO_{S1} voltages) can be reduced to a voltage of 1V or lower. More specifically, the sub-word line voltage SWL_{0,0} (and the ISO_{S0} and ISO_{S1} voltages) only needs to be high enough to ensure that the logic ‘1’ bit cell voltage of 331/326/320 mV is written to the bit cell.

As described above, the voltage level of a logic ‘0’ bit line (e.g., bit line bl_{0,3} in the example of FIG. 38) can be pulled up from 0 Volts to 24/17/13 mV due to adverse 25% bit line coupling. Because the kick capacitor 822 kicks down the voltages on bit line bl_{0,3} by −27/19/14.5 mV a during read access to bit cells bc_{0,3}, the logic ‘0’ bit line read voltage is adjusted to −3/−2/−1.5 mV (i.e., 24/17/13 mV−27/19/14.5 mV=−3/−2/−1.5 mV). These logic ‘0’ bit line read voltages are illustrated in FIG. 39. Note that these logic ‘0’ bit line read voltages provide the appropriate ΔV value of 30/21/16 mV when compared to the reference voltage Vref of 27/19/14.5 mV. Because there is no/negligible current flow on bit lines reading a logic ‘0’ value (because the bit lines are pre-charged to 0V, and remain near 0V during a read operation), there is no significant adverse bit line coupling associated with bit lines reading a logic ‘1’ value.

The single-ended sense amplifier specified by FIGS. 38-39 provides bit line CV²f power savings of at least about 91% when compared with the conventional dual-ended sense amplifier, when reading a logic ‘1’ value. That is, the bit line CV²f power of the single-ended sense amplifier of FIG. 39 divided by CV²f power of a dual-ended sense amplifier is at least (0.331×0.331)/(1.1×1.1), or 0.091. The single-ended sense amplifier specified by FIG. 39 provides power savings of 100% when compared with a conventional dual-ended sense amplifier, when reading a logic ‘0’ value (because the bit line being read is maintained near ground for the entire read operation, thereby consuming no/negligible power). Assuming that read operations, on average, include half logic ‘1’ values and half logic ‘0’ values, the single-ended sense amplifier specified by FIG. 39 achieves an average power savings of 95.5% (100%×50+91%×50=95.5%), or a power reduction of about 22×, with respect to a conventional dual-ended sense amplifier.

Note that the single-ended sense amplifiers SA″_{0,1} and SA″_{0,3} of FIGS. 38-39 are controlled in a manner similar to the single-ended sense amplifiers SA′_{0,1} and SA′_{0,3} of FIGS. 35-37. That is, the timing of the SWL_{0,0}, Vref, PRE₀, ISO_{S0}, PRE₁ and PCOM signals is consistent throughout the operation of these single-ended sense amplifiers.

### Third Alternate Embodiment

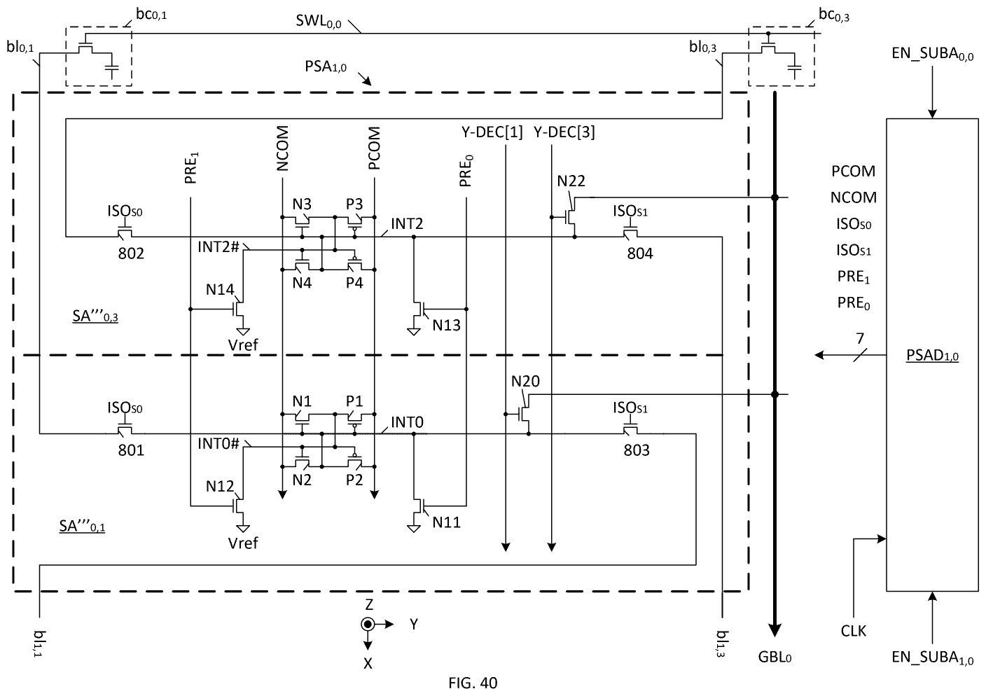

FIG. 40 is a circuit diagram of single-ended MST sense amplifiers SA′″_{0,1} and SA′″_{0,3} in accordance with a third alternate embodiment of the present invention. Single-ended MST sense amplifiers SA′″_{0,1} and SA′″_{0,3} are similar to single-ended sense amplifiers SA′_{0,1} and SA′_{0,3} (FIG. 35), with similarities and differences noted below.

Within single-ended MST sense amplifiers SA′″_{0,1} and SA′″_{0,3}, n-channel transistors N1-N4 and the p-channel transistors P1-P4 are fabricated in accordance with MST technology (including superlattice channels that extend between source and drain regions of these transistors), such that the single-ended MST sense amplifiers SA′″_{0,1} and SA′″_{0,3} exhibit a ΔV value range of 30/21/16 mV (for C_{B}/C_{S}=4/6/8, respectively).

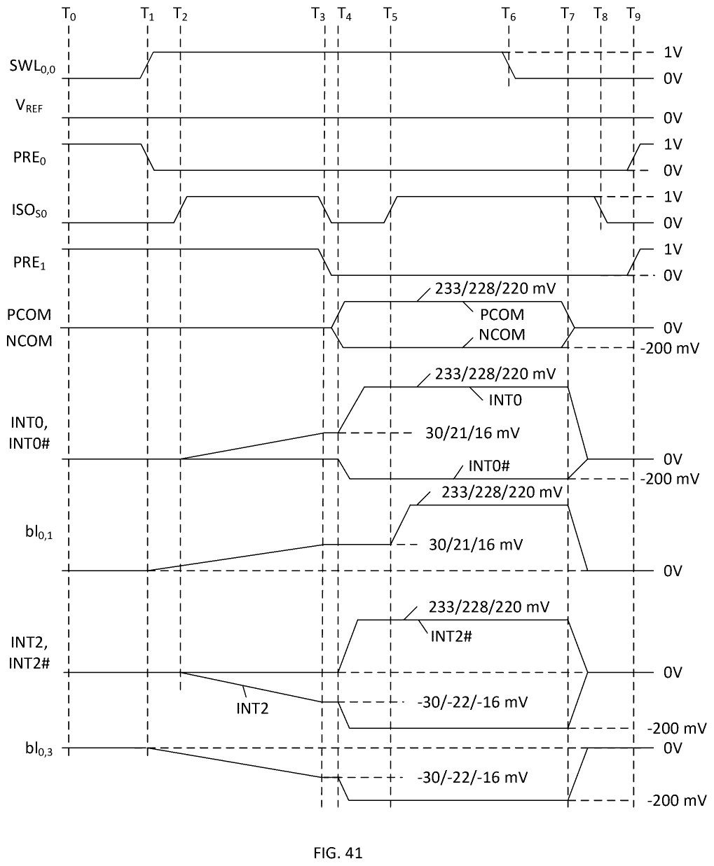

Within single-ended sense amplifiers SA′″_{0,1} and SA′″_{0,3}, the reference voltage Vref is set to ground (0V), and the sources of n-channel transistors N1-N4 are coupled to receive an NCOM control signal from primary sense amplifier driver PSAD_{1,0} (rather than ground). In addition, the logic ‘0’ bit cell voltage is set to −200 mV (instead of 0V). As shown in FIG. 41, the logic ‘0’ bit cell voltage of −200 mV is achieved by pulling the NCOM control signal down to −200 mV during the sensing operations.

FIG. 41 is a waveform diagram illustrating signals associated with read accesses to bit cells bc_{0,1} and bc_{0,3} in single-ended MST sense amplifiers SA′″_{0,1} and SA′″_{0,3} in accordance with the third alternate embodiment of the present invention. The waveform diagram of FIG. 41 is similar to the waveform diagram of FIG. 37, with differences noted below.

Having specified a nominal ‘0’ bit cell voltage of −200 mV, nominal logic ‘0’ read bit line voltages are −40/−29/−22 mV for C_{B}/C_{S} values of 4/6/8 (i.e., −200 mV+(1+C_{B}/C_{S})=−40/−29/−22 mV for C_{B}/C_{S} values of 4/6/8). Assuming that a bit line reading a logic ‘0’ value experiences 25% adverse bit line coupling from a plurality of adjacent bit lines reading logic ‘1’ values, a bit line reading a logic ‘0’ value may be pulled up by 10/7/6 mV (i.e., 40/29/22 mV×0.25) That is, a logic ‘0’ read bit line voltage will be pulled up to −30/−22/−16 mV. Note that with the reference voltage Vref set at 0 Volts, the logic ‘0’ read bit line voltages of −30/−22/−16 mV meet the specified ΔV values of the single-ended sense amplifiers SA′″_{0,1} and SA′″_{0,3} (i.e., ΔV=30/21/16 mV).

As described above, the reference voltage Vref is set to ground in the present embodiment. In order to obtain a ΔV value of 30/21/16 mV for a logic ‘1’ read data value, the nominal value of a logic ‘1’ value read on the bit line bl_{0,1} (or bl_{0,3}) should at least be equal to 30/21/16 mV (i.e., 0 mV+30/21/16 mV=30/21/16 mV). Assuming 25% adverse bit line coupling from adjacent bit lines being pulled down to a logic ‘0’ read value (i.e., a negative voltage level), the nominal value of a logic ‘1’ value read on the bit line bl_{0,1} (or bl_{0,3}) should therefore be adjusted to 40/28/21 mV (i.e., 30/21/16 mV divided by 0.75=40/28/21 mV) to compensate for this adverse bit line coupling. A logic ‘1’ bit line voltage of 40/28/21 mV translates to bit cell voltages of 200/196/189 mV for C_{B}/C_{S} values of 4/6/8 (i.e., 40/28/21 mV×(1+C_{B}/C_{S})=200/196/189 mV). In order to ensure a minimum bit cell voltage of 200/196/189 mV at the end of a refresh interval, the bit cell should initially be written to a bit cell voltage that is about 14% greater, or 233/228/220 mV. Because the logic ‘1’ bit cell voltage is only 233/228/220 mV, the isolation transistors 801-802 (and the transistor driving the sub-word line voltage SWL_{0,0}) can be implemented conventional logic transistors, and do not need to be thick oxide transistors. More specifically, the sub-word line voltage SWL_{0,0} (and ISO_{S0} and ISO_{S1} voltages) only needs to be high enough to ensure that the logic ‘1’ bit cell voltage of 233/228/220 mV is written to the bit cell.

The single-ended sense amplifier specified by FIGS. 40-41 provides bit line CV²f power savings of about 95.5% when reading a logic ‘1’ value (compared with the conventional dual-ended sense amplifier). That is, the logic ‘1’ bit line CV²f power of the single-ended sense amplifier of FIG. 39 divided by the logic ‘1’ bit line CV²f power of a dual-ended sense amplifier is equal to (0.233×0.233)/(1.1×1.1), or 0.045.

The single-ended sense amplifier specified by FIGS. 40-41 provides bit line CV²f power savings of about 96.7% when reading a logic ‘0’ value (compared with the conventional dual-ended sense amplifier). That is, the logic ‘0’ bit line CV²f power of the single-ended sense amplifier of FIG. 39 divided by the logic ‘0’ bit line CV²f power of a dual-ended sense amplifier is equal to (−0.200×−0.200)/(1.1×1.1), or 0.033.

Assuming that read operations, on average, include half logic ‘1’ values and half logic ‘0’ values, the single-ended sense amplifier specified by FIG. 40 achieves an average power savings of 96.1% (95.5%×50+96.7%×50=96.1%), or a power reduction of about 26×, with respect to a conventional dual-ended sense amplifier.

Note that the single-ended sense amplifiers SA′″_{0,1} and SA′″_{0,3} of FIGS. 39-40 are controlled in a manner similar to the single-ended sense amplifiers SA′_{0,1} and SA′_{0,3} of FIGS. 35-37. That is, the timing of the SWL_{0,0}, PRE₀, ISO_{S0}, PRE₁ and PCOM signals is consistent throughout the operation of these single-ended sense amplifiers. Note that when the single-ended sense amplifiers SA′″_{0,1} and SA′″_{0,3} are enabled at time T4 (i.e., when the PCOM signal is driven from 0V to 233/228/220 mV), the NCOM signal is driven from 0V down to a negative voltage of −200 mV. This advantageously allows the INT2 node and the bit line bl_{0,3} to be driven to −200 mV to properly refresh the bit cell voltage of bit cell bc_{0,3}.

### Fourth Alternate Embodiment

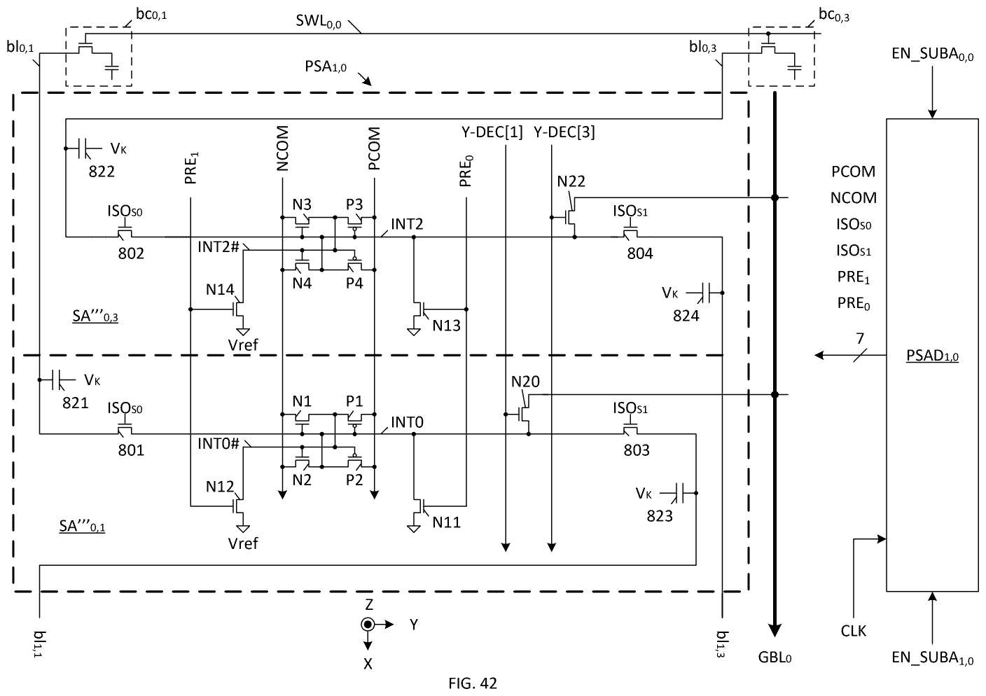

FIG. 42 is a circuit diagram of single-ended MST sense amplifiers SA″″_{0,1} and SA″″_{0,3} in accordance with a fourth alternate embodiment of the present invention. Single-ended MST sense amplifiers SA″″_{0,1} and SA″″_{0,3} are similar to single-ended sense amplifiers SA′″_{0,1} and SA′″_{0,3} (FIG. 40), with similarities and differences noted below.

Within single-ended MST sense amplifiers SA″″_{0,1} and SA″″_{0,3}, n-channel transistors N1-N4 and the p-channel transistors P1-P4 are fabricated in accordance with MST technology (including superlattice channels that extend between source and drain regions of these transistors), such that the single-ended MST sense amplifiers SA″″_{0,1} and SA″″_{0,3} exhibit a ΔV value range of 30/21/16 mV.

Within single-ended sense amplifiers SA″″_{0,1} and SA″″_{0,3}, the reference voltage Vref is set to ground (0V), and the NCOM control signal is pulled down to −100 mV (instead of −200 mV) to activate the single-ended sense amplifiers SA″″_{0,1} and SA″″_{0,3}. Thus, the logic ‘0’ bit cell voltage is set to −100 mV (instead of −200 mV).

In addition, single-ended MST sense amplifiers SA″″_{0,1} and SA″″_{0,3} include kick capacitors 821, 822, 823 and 824, which are coupled to bit lines bl_{0,1}, bl_{0,3}, bl_{1,1} and bl_{1,3}, respectively. As described in more detail below, each of the kick capacitors 821-824 is designed to kick down the voltage on the associated bit lines during read operations.

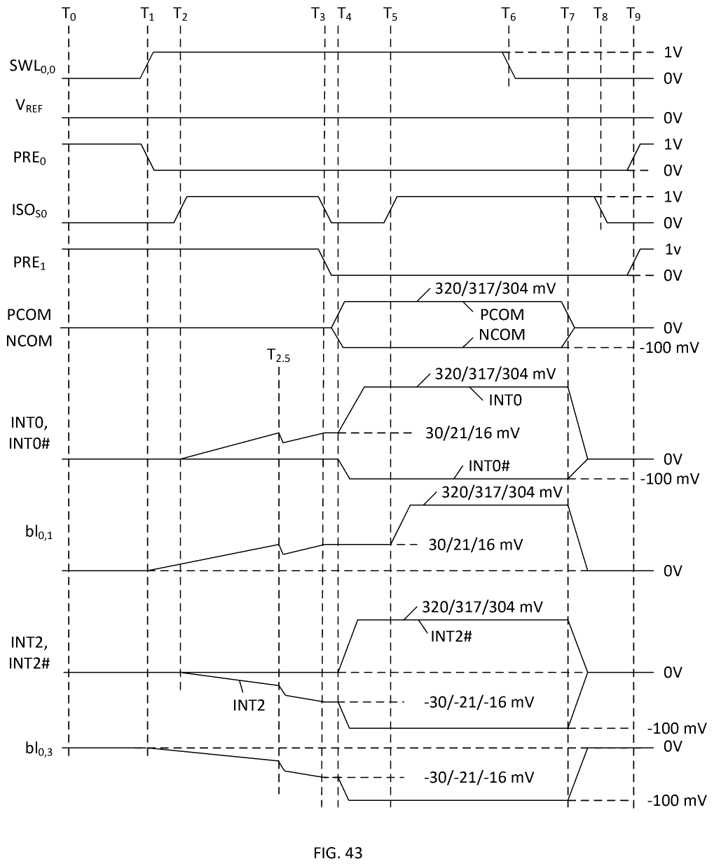

FIG. 43 is a waveform diagram illustrating signals associated with read accesses to bit cells bc_{0,1} and bc_{0,3} in single-ended MST sense amplifiers SA″″_{0,1} and SA″″_{0,3} in accordance with the fourth alternate embodiment of the present invention. The waveform diagram of FIG. 43 is similar to the waveform diagram of FIG. 41, with differences noted below.

Having specified a nominal ‘0’ bit cell voltage of −100 mV, nominal logic ‘0’ read bit line voltages are −20/−14/−11 mV for C_{B}/C_{S} values of 4/6/8 (i.e., −100 mV+(1+C_{B}/C_{S})=−20/−14/−11 mV for C_{B}/C_{S} values of 4/6/8). Assuming that a bit line reading a logic ‘0’ value experiences 25% adverse bit line coupling from a plurality of adjacent bit lines reading logic ‘1’ values, a bit line reading a logic ‘0’ value may be pulled up by 5/4/3 mV (i.e., 20/14/11 mV×0.25) That is, a logic ‘0’ read bit line voltage will be pulled up to −15/−10/−8 mV. Note that with a reference voltage Vref equal to 0 Volts, these logic ‘0’ read bit line voltages do not meet the specified ΔV values of the single-ended sense amplifiers SA″″_{0,1} and SA″″_{0,3} (i.e., ΔV=30/21/16 mV). In order to obtain the ΔV values of 30/21/16 mV required to read a logic ‘0’ read data value, the switched kick capacitors 821-822 are activated to kick the voltages on the corresponding bit lines bl_{0,1} and bl_{0,3} down by −15/−11/−8 mV for C_{B}/C_{S} values of 4/6/8, respectively. As a result, the logic ‘0’ bit line voltage is kicked down from −15/−10/−8 mV to −30/−21/−16 mV (i.e., −15/−10/−8 mV−15/11/8 mV=−30/−21/−16 mV), thereby meeting the specified ΔV values of the single-ended sense amplifiers SA″″_{0,1} and SA″″_{0,3} (i.e., ΔV=30/21/16 mV). In the embodiment of FIGS. 42-43, the kick capacitors 821-822 are controlled to kick the voltages on bit lines bl_{0,1} and bl_{0,3} between time T2 and time T3 (i.e., at time T2.5). In one embodiment, the kick capacitors are switched on as close to time T3 as possible.

As described above, the reference voltage Vref is set to ground in the present embodiment. In order to obtain a ΔV value of 30/21/16 mV for a logic ‘1’ read data value, the nominal value of a logic ‘1’ value read on the bit line bl_{0,1} (or bl_{0,3}) should at least be equal to 30/21/16 mV (i.e., 0 mV+30/21/16 mV=30/21/16 mV). Assuming 25% adverse bit line coupling from adjacent bit lines being pulled down to a logic ‘0’ read value (i.e., a negative voltage level), the nominal value of a logic ‘1’ value read on the bit line bl_{0,1} (or bl_{0,3}) should therefore be adjusted to 40/28/21 mV (i.e., 30/21/16 mV divided by 0.75=40/28/21 mV) to compensate for this adverse bit line coupling. The nominal value of a logic ‘1’ value read on the bit line bl_{0,1} (or bl_{0,3}) should also be adjusted upward by 15/11/8 mV to compensate for the kick down voltages applied by kick capacitors 821-822. More specifically, the nominal value of a logic ‘1’ value read on the bit line bl_{0,1} (or bl_{0,3}) should therefore be adjusted to 55/39/29 mV (i.e., 40/28/21 mV+15/11/8 mV=55/39/29 mV) to compensate for kick capacitor voltages.

A logic ‘1’ bit line voltage of 55/39/29 mV translates to bit cell voltages of 275/273/261 mV for C_{B}/C_{S} values of 4/6/8 (i.e., 55/39/29 mV×(1+C_{B}/C_{S})=275/273/261 mV). In order to ensure a minimum bit cell voltage of 275/273/261 mV at the end of a refresh interval, the bit cell should initially be written to a bit cell voltage that is about 14% greater, or 320/317/304 mV. Because the logic ‘1’ bit cell voltage is only 320/317/304 mV, the isolation transistors 801-802 (and the transistor driving the sub-word line voltage SWL_{0,0}) can be implemented conventional logic transistors, and do not need to be thick oxide transistors. More specifically, the sub-word line voltage SWL_{0,0} (and ISO_{S0} and ISO_{S1} voltages) only needs to be high enough to ensure that the logic ‘1’ bit cell voltage of 320/317/304 mV is written to the bit cell.

The single-ended sense amplifier specified by FIGS. 42-43 provides bit line CV²f power savings of about 91.5% when reading a logic ‘1’ value (compared with the conventional dual-ended sense amplifier). That is, the logic ‘1’ bit line CV²f power of the single-ended sense amplifier of FIG. 39 divided by the logic ‘1’ bit line CV²f power of a dual-ended sense amplifier is equal to (0.320×0.320)/(1.1×1.1), or 0.085.

The single-ended sense amplifier specified by FIGS. 40-41 provides bit line CV²f power savings of about 99.2% when reading a logic ‘0’ value (compared with the conventional dual-ended sense amplifier). That is, the logic ‘0’ bit line CV²f power of the single-ended sense amplifier of FIG. 39 divided by the logic ‘0’ bit line CV²f power of a dual-ended sense amplifier is equal to (−0.100×−0.100)/(1.1×1.1), or 0.008.

Assuming that read operations, on average, include half logic ‘1’ values and half logic ‘0’ values, the single-ended sense amplifier specified by FIG. 40 achieves an average power savings of 95.4% (91.5%×50+99.2%×50=95.4%), or a power reduction of about 22×, with respect to a conventional dual-ended sense amplifier.

Note that the single-ended sense amplifiers SA″″_{0,1} and SA″″_{0,3} of FIGS. 42-43 are controlled in a manner similar to the single-ended sense amplifiers SA″_{0,1} and SA″_{0,3} of FIGS. 38-39. That is, the timing of the SWL_{0,0}, PRE₀, ISO_{S0}, PRE₁ and PCOM signals is consistent throughout the operation of these single-ended sense amplifiers. Note that when the single-ended sense amplifiers SA″″_{0,1} and SA″″_{0,3} are enabled at time T4 (i.e., when the PCOM signal is driven from 0V to 320/317/304 mV), the NCOM signal is driven from 0V down to a negative voltage of −100 mV. This advantageously allows the INT2 node and the bit line bl_{0,3} to be driven to −100 mV to properly refresh the bit cell voltage of bit cell bc_{0,3}.

In the embodiments described above, the voltage required to be applied to the capacitor plate of the DRAM bit cells bc_{0,1} and bc_{0,3} (i.e., Vplate) is significantly reduced, because the logic ‘1’ bit cell voltage is significantly reduced. In the embodiments described above, the bit cell voltage is reduced from 1.1 V (for a conventional dual-ended sense amplifier) to about 985 mV (for the single-ended sense amplifier of FIGS. 35-36), about 488 mV (for the single-ended sense amplifier of FIG. 37), about 331 mV (for the single-ended sense amplifier of FIGS. 38-39), about 233 mV (for the single-ended sense amplifier of FIGS. 40-41), and about 320 mV (for the single-ended sense amplifier of FIGS. 42-43). Assuming capacitor plate voltage Vplate is half of the bit cell voltage, the capacitor plate voltage can be reduced from 550 mV (for a conventional dual-ended sense amplifier) to about 493 mV, 244 mV, 166 mV, 117 mV and 160 mV for the single-ended sense amplifiers of the above described embodiments. The reduced voltages across the DRAM bit cell capacitors may advantageously enable the use of different capacitor materials/structures within the DRAM bit cells. In addition, the single-ended sense amplifiers described above enable the fabrication of a DRAM bit cell having a 4F² unit cell area because there are no dummy bit lines running through the bit cell array/sense amplifier region.

Although the invention has been described in connection with several embodiments, it is understood that this invention is not limited to the embodiments disclosed, but is capable of various modifications, which would be apparent to a person skilled in the art. Accordingly, the present invention is limited only by the following claims.

I claim:

1. An integrated circuit chip comprising:
a plurality of unit cells arranged in an array having a plurality of rows and columns, wherein each of the unit cells comprises:
a plurality of DRAM memory strips (S_{(1,1)0}-S_{(1,1)15}), each comprising:
a plurality of independently accessible DRAM sub-arrays arranged in a row, wherein each of the DRAM sub-arrays includes an array of DRAM bit cells arranged in rows and columns, wherein the DRAM sub-arrays of the plurality of DRAM memory strips are further arranged in a first plurality of columns of DRAM sub-arrays; and
a plurality of primary single-ended sense amplifier circuits, wherein each of the plurality of DRAM sub-arrays is coupled to a corresponding pair of the plurality of primary single-ended sense amplifier circuits;
a first plurality of global bit line sets, wherein each of the first plurality of global bit line sets is coupled to a corresponding one of the first plurality of columns of DRAM sub-arrays through the primary single-ended sense amplifier circuits coupled to the DRAM sub-arrays in the corresponding one of the first plurality of columns of DRAM sub-arrays;
a first multiplexer circuit coupled to each of the first plurality of global bit line sets, wherein the first multiplexer circuit selectively couples one of the first plurality of global bit line sets to a first set of global input/output lines;
a first secondary sense amplifier circuit coupled to the first set of global input/output lines; and
a first set of through silicon vias coupled to the first secondary sense amplifier circuit.

2. The integrated circuit chip of claim 1, wherein the DRAM sub-arrays of the plurality of DRAM memory strips are further arranged in a second plurality of columns of DRAM sub-arrays, wherein each of the unit cells further comprises:
a second plurality of global bit line sets, wherein each of the second plurality of global bit line sets is coupled to a corresponding one of the second plurality of columns of DRAM sub-arrays through the primary single-ended sense amplifier circuits coupled to the DRAM sub-arrays in the corresponding one of the second plurality of columns of DRAM sub-arrays;
a second multiplexer circuit coupled to each of the second plurality of global bit line sets, wherein the second multiplexer circuit selectively couples one of the second plurality of global bit line sets to a second set of global input/output lines;
a second secondary sense amplifier circuit coupled to the second set of global input/output lines; and
a second set of through silicon vias coupled to the second secondary sense amplifier circuit.

3. The integrated circuit chip of claim 1, wherein a first column of unit cells of the plurality of columns of unit cells, and an adjacent second column of unit cells of the plurality of columns of unit cells are oriented such that the first sets of through silicon vias of the unit cells of the first column of unit cells are located immediately adjacent to the first sets of through silicon vias of the unit cells of the second column of unit cells.

4. The integrated circuit chip of claim 1, wherein the first secondary sense amplifier circuit comprises a plurality of write single-ended sense amplifiers, each coupled to a corresponding one of the global input/output lines of the first set of global input/output lines, and a plurality of read single-ended sense amplifiers, each coupled to a corresponding one of the global input/output lines of the first set of global input/output lines.

5. The integrated circuit chip of claim 4, wherein each of the through silicon vias in the first set of through silicon vias is coupled to a corresponding pair of the plurality of write single-ended sense amplifiers and a corresponding pair of the plurality of read single-ended sense amplifiers.

6. The integrated circuit chip of claim 4,
wherein each of the plurality of read single-ended sense amplifiers is controlled to simultaneously sample data on a corresponding one of the global input/output lines of the first set of global input/output lines,
wherein a first half of the plurality of read single-ended sense amplifiers is controlled to simultaneously provide the data sampled on the corresponding one of the global input/output lines of the first set of global input/output lines to the first set of through silicon vias during a first time period, and
wherein a second half of the plurality of read single-ended sense amplifiers is controlled to simultaneously provide the data sampled on the corresponding one of the global input/output lines of the first set of global input/output lines to the first set of through silicon vias during a second time period.

7. The integrated circuit chip of claim 4,
wherein a first half of the plurality of write single-ended sense amplifiers are controlled to sample a first set of data on the first set of through silicon vias during a first time period and hold the first set of data during a second time period,
wherein a second half of the plurality of write single-ended sense amplifiers are controlled to sample a second set of data on the first set of through silicon vias during the second time period, and
wherein the plurality of write single-ended sense amplifiers are controlled to simultaneously provide the first and second sets of data on the first set of global input/output lines during a third time period.

8. The integrated circuit chip of claim 1, wherein each of the DRAM memory strips includes a plurality of main word lines, each extending through all of the plurality of DRAM sub-arrays of the DRAM memory strip.

9. The integrated circuit chip of claim 8, wherein each of the plurality of DRAM memory strips further comprises a main word line driver that activates one of the corresponding plurality of main word lines when the DRAM memory strip is accessed.

10. The integrated circuit chip of claim 8, wherein each of the plurality of DRAM sub-arrays includes a dedicated plurality of sub-word lines, each coupled to a corresponding one of the rows of DRAM cells of the array of DRAM cells.

11. The integrated circuit chip of claim 10, wherein each of the plurality of DRAM sub-arrays includes a plurality of sub-word line driver circuits, each coupled to a corresponding one of the dedicated plurality of sub-word lines of the DRAM sub-array.

12. The integrated circuit chip of claim 11, wherein each of the main word lines is coupled to a corresponding plurality of the sub-word line driver circuits within each of the plurality of DRAM sub-arrays.

13. The integrated circuit chip of claim 12, wherein each of the main word lines is coupled to eight of the sub-word line driver circuits within each of the plurality of DRAM sub-arrays.

14. The integrated circuit chip of claim 11, wherein each of the plurality of DRAM sub-arrays receives a corresponding sub-array enable signal, wherein each of the sub-word line driver circuits of each of the plurality of DRAM sub-arrays is coupled to receive the corresponding sub-array enable signal.

15. The integrated circuit chip of claim 14, wherein adjacent DRAM sub-arrays in each of the first plurality of columns of DRAM sub-arrays share one of the plurality of primary single-ended sense amplifier circuits.

16. The integrated circuit chip of claim 15, wherein each of the primary single-ended sense amplifier circuits is coupled to half of the plurality of columns of DRAM bit cells in the corresponding DRAM sub-array.

17. The integrated circuit chip of claim 15, wherein each of the primary single-ended sense amplifier circuits comprises a plurality of single-ended sense amplifiers.

18. The integrated circuit chip of claim 17 wherein each of the first plurality of global bit line sets comprises a plurality of global bit lines, each coupled to a plurality of the single-ended sense amplifiers in the primary single-ended sense amplifier circuits coupled to the DRAM sub-arrays in a column of the first plurality of columns of DRAM sub-arrays.

19. The integrated circuit chip of claim 15, wherein each of the primary single-ended sense amplifier circuits comprises a primary sense amplifier driver circuit (PSAD_{1,0}), coupled to receive the sub-array enable signal (EN_SUBA_{0,0}, EN_SUBA_{1,0}) of the corresponding DRAM sub-array.

20. The integrated circuit chip of claim 1, wherein the global bit lines of each of the first plurality of global bit line sets are evenly distributed across the first multiplexer circuit.

21. The integrated circuit chip of claim 2, wherein each of the unit cells further comprises a third set of through silicon vias for receiving an access instruction to the unit cell.

22. The integrated circuit chip of claim 21, wherein the access instruction to the unit cell comprises:
a unit cell address for selecting the unit cell;
a strip address for selecting one of the plurality of DRAM memory strips;
a first DRAM sub-array column address for selecting one of the first plurality of columns of DRAM sub-arrays; and
a second DRAM sub-array column address for selecting one of the second plurality of columns of DRAM sub-arrays.

23. The integrated circuit chip of claim 22, wherein each of the DRAM memory strips includes a plurality of main word lines, each extending through all of the plurality of DRAM sub-arrays of the DRAM memory strip, wherein the access instruction to the unit cell further comprises a main word line address for selecting one of the plurality of main word lines.

24. The integrated circuit of claim 23, wherein each of the plurality of DRAM sub-arrays includes a dedicated plurality of sub-word lines, each coupled to a corresponding one of the rows of DRAM cells of the DRAM sub-array, wherein the access instruction to the unit cell further comprises:
a first sub-word line address for selecting one of the plurality of sub-word lines of the first plurality of columns of DRAM sub-arrays; and
a second sub-word line address for selecting one of the plurality of sub-word lines of the second plurality of columns of DRAM sub-arrays.

25. The integrated circuit chip of claim 21, wherein each row of DRAM memory strips extends from a first edge of the unit cell to an opposing second edge of unit cell, wherein the first, second and third sets of through silicon vias are sparsely populated near the first and second edges of the unit cell, enabling a plurality of metal lines to pass between the through silicon vias of the first, second and third sets of through silicon vias near the first and second edges of the unit cell.

26. The integrated circuit chip of claim 2, wherein each of the plurality of DRAM memory strips further comprises a sub-array decoder circuit that selectively enables up to one of the DRAM sub-arrays of the DRAM memory strip included in the first plurality of columns of DRAM sub-arrays and up to one of the DRAM sub-arrays of the DRAM memory strip included in the second plurality of columns of DRAM sub-arrays.

27. A multi-threaded dynamic random access memory (MTDRAM) processor system comprising:
a first integrated circuit chip comprising at least 2048 processor blocks arranged in a first array; and
a second integrated circuit chip comprising at least 2048 independent dynamic random access memory (DRAM) unit cells arranged in a second array, wherein each of the at least 2048 processor blocks is coupled to a corresponding one of the at least 2048 independent DRAM unit cells of the second array of DRAM unit cells by through silicon via (TSV) structures.

28. The MTDRAM processor system of claim 27, further comprising: a third integrated circuit chip comprising at least 2048 independent DRAM unit cells arranged in a third array, wherein each of the at least 2048 processor blocks is coupled to a corresponding one of the at least 2048 independent DRAM unit cells of the third array by through silicon via (TSV) structures.
